(19) United States
(12) Patent Application Publication
(10) Pub. No.: US 2024/0023437 A1
(43) Pub. Date: Jan. 18, 2024

(54) ORGANIC ELECTROLUMINESCENCE ELEMENT, AND DESIGN METHOD AND PROGRAM FOR LIGHT EMITTING COMPOSITION

(71) Applicant: KYULUX, INC., Fukuoka-shi, Fukuoka (JP)

(72) Inventors: YiTing LEE, Fukuoka-shi, Fukuoka (JP); Masaki TANAKA, Fukuoka-shi, Fukuoka (JP); Chin-Yiu CHAN, Fukuoka-shi, Fukuoka (JP); Youichi TSUCHIYA, Fukuoka-shi, Fukuoka (JP); Hajime NAKANOTANI, Fukuoka-shi, Fukuoka (JP); Chihaya ADACHI, Fukuoka-shi, Fukuoka (JP); Yu INADA, Fukuoka-shi, Fukuoka (JP)

(21) Appl. No.: 18/252,740

(22) PCT Filed: Nov. 17, 2021
(86) PCT No.: PCT/JP2021/042205

§ 371 Date: May 12, 2023

(30) Foreign Application Priority Data
Nov. 17, 2020 (JP) 2020-190698
May 28, 2021 (JP) 2021-090608

(51) Int. Cl. H10K 85/60; H10K 85/20; C09K 11/06

(52) U.S. Cl. CPC H10K 85/6574; H10K 85/6572; H10K 85/654; H10K 85/6576; H10K 85/615; H10K 85/658; H10K 85/622; H10K 85/20; H10K 85/623; C09K 11/06; H10K 2101/20

(57) ABSTRACT

Provided is an organic electroluminescent device that has a long device lifetime and is stable. The organic electroluminescent device has a light emitting layer containing first to third compounds satisfying the following formulae. E_{S1} is a lowest excited singlet energy and E_{HOMO}(n) is a HOMO energy.

E_{S1}(1)>E_{S1}(2)>E_{S1}(3)

0 eV<E_{HOMO}(3)-E_{HOMO}(2)<0.65 eV

### TECHNICAL FIELD

The present invention relates to an organic electroluminescent device characterized by the light emitting layer thereof, and to a design method and a program for a light emitting composition.

### BACKGROUND ART

Studies for enhancing the light emission efficiency of light emitting devices such as organic electroluminescent devices (organic EL devices) are being made actively. In particular, various kinds of efforts have been made for increasing light emission efficiency by newly developing and combining an electron transporting material, a hole transporting material and a light emitting material to constitute an organic electroluminescent device. Among them, there is seen a study of an organic electroluminescent device that utilizes a delayed fluorescent material.

A delayed fluorescent material is a material which, in an excited state, after having undergone reverse intersystem crossing from an excited triplet state to an excited singlet state, emits fluorescence when returning back from the excited singlet state to a ground state thereof. Fluorescence through the route is observed later than fluorescence from the excited singlet state directly occurring from the ground state (ordinary fluorescence), and is therefore referred to as delayed fluorescence. Here, for example, in the case where a light emitting compound is excited through carrier injection thereinto, the occurring probability of the excited singlet state and the excited triplet state is statistically 25%/75%, and therefore improvement of light emission efficiency by the fluorescence alone from the directly occurring excited singlet state is limited. On the other hand, in a delayed fluorescent material, not only the excited singlet state thereof but also the excited triplet state can be utilized for fluorescent emission through the route via the above-mentioned reverse intersystem crossing, and therefore as compared with an ordinary fluorescent material, a delayed fluorescent material can realize a higher emission efficiency.

After the characteristics of such a delayed fluorescent material have been clarified, various methods of effectively utilizing a delayed fluorescent material for an organic electroluminescent device have been further investigated. For example, PTL 1 describes adding, to a light emitting layer containing a light emitting material and a host material, a delayed fluorescent material whose lowest excited singlet energy is lower than that of the host material and higher than that of the light emitting material. By adding such a delayed fluorescent material, the lowest excited singlet energy of the delayed fluorescent material transfers to the light emitting material to enhance the light emission efficiency of the light emitting material.

### CITATION LIST

### Patent Literature

PTL 1: JP 5669163B

### SUMMARY OF INVENTION

### Technical Problem

By adding, to the light emitting layer containing a light emitting material and a host material, a delayed fluorescent material whose lowest excited singlet energy is lower than that of the host material and higher than that of the light emitting material, the light emission efficiency of the organic electroluminescent device sure improves. However, the organic electroluminescent material in which a delayed fluorescent material is added to the light emitting layer tends to have a shortened device lifetime and has room for improvement in point of practicability. Consequently, it is needed to provide an organic electroluminescent device having an enhanced device lifetime.

### Solution to Problem

As a result of having advanced assiduous studies for solving the problems in the prior art, the present inventors have found that, by combining the compounds to be added to the light emitting layer of an organic electroluminescent device so as to satisfy specific requirements, the device lifetime can be enhanced. The present invention has been proposed on the basis of such findings, and specifically has the following constitution.
[1] An organic electroluminescent device having an anode, a cathode, and at least one organic layer containing a light emitting layer between the anode and the cathode, wherein:
   the light emitting layer contains a first organic compound, a second organic compound and a third organic compound,
   the second organic compound is a delayed fluorescent material,
   the maximum component of light emission from the device is light emission from the third organic compound, and
   the first organic compound, the second organic compound and the third organic compound satisfy the following formula (a) and the following formula (b).

E_{S1}(1)>E_{S1}(2)>E_{S1}(3) Formula (a)

0 eV<E_{HOMO}(3)-E_{HOMO}(2)<0.65 eV Formula (b)
wherein:
   E_{S1}(1) represents the lowest excited singlet energy of the first organic compound,
   E_{S1}(2) represents the lowest excited singlet energy of the second organic compound,
   E_{S1}(3) represents the lowest excited singlet energy of the third organic compound,
   E_{HOMO}(2) represents the HOMO energy of the second organic compound, and
   E_{HOMO}(3) represents the HOMO energy of the third organic compound.
[2] The organic electroluminescent device according to [1], wherein the lowest excited triplet energy of the third organic compound is larger than 1.90 eV.
[3] The organic electroluminescent device according to [1] or [2], wherein the maximum emission wavelength of the device falls within a range of 380 to 780 nm.
[4] The organic electroluminescent device according to any one of [1] to [3], wherein the maximum emission wavelength of the third organic compound is shorter than the maximum emission wavelength of the second organic compound.
[5] The organic electroluminescent device according to any one of [1] to [4], wherein the concentration of the third organic compound in the light emitting layer falls within a range of 0.01 to 5% by weight.
[6] The organic electroluminescent device according to any one of [1] to [5], wherein the difference between the excited singlet energy and the excited triplet energy (ΔE_{ST}) of the second organic compound is less than 0.3 eV.
[7] The organic electroluminescent device according to any one of [1] to [6], wherein the ionization energy of the third organic compound is larger than the ionization energy of the second organic compound.
[8] The organic electroluminescent device according to any one of [1] to [7], wherein the third organic compound is a compound represented by the following general formula (15).

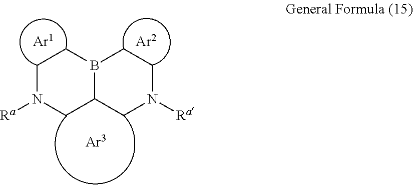

In the general formula (15), Ar¹ to Ar³ each independently represent an aryl ring or a heteroaryl ring, at least one hydrogen atom in these rings can be substituted, or the ring can be condensed. R^{a} and R^{a}′ each independently represent a substituent. R^{a} and Ar¹, Ar¹ and Ar², Ar² and R^{a}′, R^{a}′ and Ar³, and Ar³ and R^{a} each can bond to each other to form a cyclic structure.
[9] The organic electroluminescent device according to any one of [1] to [8], wherein the second organic compound has a structure such that one or two cyano groups and at least one donor group bond to the benzene ring.
[10] The organic electroluminescent device according to [9], wherein the donor group is a substituted or unsubstituted carbazol-9-yl group.
[11] The organic electroluminescent device according to [10], wherein three or more substituted or unsubstituted carbazol-9-yl groups bond to the benzene ring.
[12] The organic electroluminescent device according to [10] or [11], wherein at least one of the two benzene rings constituting at least one carbazol-9-yl group existing in the second organic compound is condensed with the 5-membered ring that constitutes a substituted or unsubstituted benzofuran ring, a substituted or unsubstituted benzothiophene ring, a substituted or unsubstituted indole ring, a substituted or unsubstituted indene ring, or a substituted or unsubstituted silaindene ring.
[13] The organic electroluminescent device according to any one of [1] to [12], wherein the light emitting layer contains a carbon atom, a hydrogen atom, a nitrogen atom, a boron atom and an oxygen atom, and does not contain any other element.
[14] A design method for a light emitting composition, including:
   <1> evaluating the emission lifetime of a composition containing a first organic compound, a second organic compound of a delayed fluorescent material and a third organic compound, and satisfying the above-mentioned formula (a) and formula (b),
   <2> carrying out at least once evaluating the emission lifetime of a composition prepared by changing at least one of the first organic compound, the second organic compound of a delayed fluorescent material and the third organic compound within the range satisfying the above-mentioned formula (a) and formula (b), and
   <3> selecting a combination of compounds providing the best emission lifetime evaluated.
[15] A program of carrying out the method of [14].

### Advantageous Effects of Invention

The organic electroluminescent device of the present invention has an enhanced device lifetime. According to the design method for a light emitting composition of the present invention, there can be provided a light emitting composition capable of realizing a light emitting device having a long device lifetime.

### BRIEF DESCRIPTION OF DRAWINGS

FIG. 1 This is a schematic cross-sectional view showing a layer configuration example of an organic electroluminescent device.

FIG. 2 This is a graph showing a relationship between the ratio R_{HM} of a hole mobility, and the energy difference ΔE_{HOMO} of HOMO between a third organic compound and a second organic compound.

FIG. 3 This shows a transient decay curve of emission intensity of EL device 3 using Compound 2 (1.0 wt %) as a light emitting material, at the time when a reverse bias current is supplied after driving and the current is cut.

FIG. 4 This shows a transient decay curve of emission intensity of EL device 4 using Compound 2 (0.5 wt %) as a light emitting material, at the time when a reverse bias current is supplied after driving and the current is cut.

FIG. 5 This shows a transient decay curve of emission intensity of EL devices 1 to 6, at the time when a reverse bias current is supplied after driving and the current is cut.

### DESCRIPTION OF EMBODIMENTS

The contents of the invention will be described in detail below. The constitutional elements may be described below with reference to representative embodiments and specific examples of the invention, but the invention is not limited to the embodiments and the examples. In the description herein, a numerical range expressed as “to” means a range that includes the numerical values described before and after “to” as the lower limit and the upper limit. Also in the description, the phrase “consisting of” means that the phrase “consisting of” is composed of only those described before the phrase “consisting of” and does not include the others. A part or all of hydrogen atoms that are present in the molecule of the compound used in the invention can be substituted with a heavy hydrogen atom (²H, deuterium D). In the chemical structural formulae in the present description, hydrogen atom is expressed as H, or its expression is omitted. For example, when expression of an atom bonding to the ring skeleton constituting carbon atom of a benzene ring is omitted, H bonds to the ring skeleton constituting carbon atom at the site where the expression is omitted. In the present description, the term “substituent” means an atom or atomic group other than a hydrogen atom and a deuterium atom. On the other hand, the expression “substituted or unsubstituted” or “optionally substituted” means the hydrogen atom can be substituted with a deuterium atom or a substituent.

### (Organic Electroluminescent Device)

The organic electroluminescent device of the present invention has an anode, a cathode and at least one organic layer containing a light emitting layer between the anode and the cathode. The light emitting layer contains a first organic compound, a second organic compound and a third organic compound, the second organic compound is a delayed fluorescent material, the maximum component of light emission from the organic electroluminescent device is light emission from the third organic compound. The first organic compound, the second organic compound and the third organic compound satisfy the following formula (a) and the following formula (b).

E_{S1}(1)>E_{S1}(2)>E_{S1}(3) Formula (a)

0 eV<E_{HOMO}(3)-E_{HOMO}(2)<0.65 eV Formula (b)

In the formula (a), E_{S1}(1) represents the lowest excited singlet energy of the first organic compound, E_{S1}(2) represents the lowest excited singlet energy of the second organic compound, E_{S1}(3) represents the lowest excited singlet energy of the third organic compound.

In the present invention, eV is employed as the unit. The lowest excited singlet energy can be determined by preparing a thin film or a toluene solution (concentration: 10⁻⁵ mol/L) of the targeted compound and measuring the fluorescent spectrum thereof at room temperature (300 K). For the details thereof, referred to is the measurement method for lowest excited singlet energy in the section of description of the second organic compound.

The present invention satisfies the relationship of the formula (a), and therefore, among the first organic compound, the second organic compound and the third organic compound contained in the light emitting layer, the lowest excited singlet energy of the first organic compound is the largest, that of the second organic compound is the next largest, and that of the third organic compound is the smallest. E_{S1}(1)-E_{S1}(2) can be, for example, within a range of 0.20 eV or more, or within a range of 0.40 eV or more, or within a range of 0.60 eV or more. It can also be within a range of 1.50 eV or less, or within a range of 1.20 eV or less, or within a range of 0.80 eV or less. E_{S1}(2)-E_{S1}(3) can be, for example, within a range of 0.05 eV or more, or within a range of 0.10 eV or more, or within a range of 0.15 eV or more. It can also be within a range of 0.50 eV or less, or within a range of 0.30 eV or less, or within a range of 0.20 eV or less. E_{S1}(1)-E_{S1}(3) can be, for example, within a range of 0.25 eV or more, or within a range of 0.45 eV or more, or within a range of 0.65 eV or more. It can also be within a range of 2.00 eV or less, or within a range of 1.70 eV or less, or within a range of 1.30 eV or less.

In the formula (b), E_{HOMO}(2) represents the HOMO energy of the second organic compound, and E_{HOMO}(3) represents the HOMO energy of the third organic compound. HOMO is an abbreviation for Highest Occupied Molecular Orbital, and can be determined in according to air photoelectron spectroscopy (e.g., AC-3, by Riken Instruments, Inc.).

The present invention satisfies the relationship of the formula (b), and therefore the HOMO energy of the second organic compound contained in the light emitting layer is lower than the HOMO energy of the third organic compound therein. The HOMO energy difference [E_{HOMO}(3)-E_{HOMO}(2)] is more than 0 eV, and less than 0.65 eV. The lower limit is preferably 0.05 eV or more. The upper limit is preferably 0.60 eV or less, more preferably 0.50 eV or less, even more preferably 0.40 eV or less, or can be 0.30 eV or less. In addition, for example, it can be selected from the range of 0.40 eV or more, or from the range of 0.30 eV or more, or from the range of 0.20 eV or less. In one embodiment of the present invention, [E_{HOMO}(3)-E_{HOMO}(2)] is selected from the range of more than 0.30 eV and less than 0.60 eV. In another embodiment of the present invention, [E_{HOMO}(3)-E_{HOMO}(2)] is selected from the range of 0.05 eV or more and 0.30 eV or less. For example, it can be selected from the range of 0.10 eV or more and 0.30 eV or less, or can be selected from the range of 0.20 eV or more and 0.30 eV or less. In one embodiment of the present invention, [E_{HOMO}(3)-E_{HOMO}(2)] can be selected from the range of 0.01 eV or more and less than 0.20 eV. For example, it can be selected from the range of 0.01 eV or more and less than 0.10 eV, or can be selected from the range of 0.01 eV or more and 0.05 eV or less, or can be selected from the range of 0.10 eV or more and less than 0.20 eV. In one embodiment of the present invention, as the second organic compound, a compound whose HOMO energy falls within a range of −5.20 to −5.90 eV, or a compound whose HOMO energy falls within a range of −5.30 to −5.80 eV can be employed. For example, a compound whose HOMO energy falls within a range of −5.60 to −5.90 eV, or a compound whose HOMO energy falls within a range of −5.20 to −5.40 eV can be selected.

When the content of the first organic compound, the second organic compound and the third organic compound in the light emitting layer of the organic electroluminescent device of the present invention is represented by Conc(1), Conc(2) and Conc(3), respectively, the device preferably satisfies the relationship of the following formula (d).

Conc(1)>Conc(2)>Conc(3) Formula (d)

Conc(1) is preferably 30% by weight or more, and can be within a range of 50% by weight or more, or can be within a range of 60% by weight or more, or can be within a range of 99% by weight or less, or can be within a range of 85% by weight or less, or can be within a range of 70% by weight or less.

Conc(2) is preferably 5% by weight or more, and can be within a range of 15% by weight or more, or can be within a range of 20% by weight or more, or can be within a range of 30% by weight or more, and can be within a range of 45% by weight or less, or can be within a range of 40% by weight or less, or can be within a range of 35% by weight or less. It can also be within a range of 25% by weight or less, or can be within a range of 20% by weight or less.

Conc(3) is preferably 5% by weight or less, more preferably 3% by weight or less. Conc(3) can be within a range of 0.01% by weight or more, or can be within a range of 0.1% by weight or more, or can be within a range of 0.3% by weight or more, or can also be within a range of 2% by weight or less, or can be within a range of 1% by weight or less.

Conc(1)/Conc(3) can be within a range of 10 or more, or can be within a range of 50 or more, or can be within a range of 90 or more, and can also be within a range of 10000 or less, or can be within a range of 1000 or less, or can be within a range of 200 or less, or can be within a range of 100 or less.

Conc(2)/Conc(3) can be within a range of 5 or more, or can be within a range of 10 or more, or can be within a range of 20 or more, or can be within a range of 30 or more, and can also be within a range of 500 or less, or can be within a range of 300 or less, or can be within a range of 100 or less, or can be within a range of 40 or less.

Preferably, the light emitting layer of the organic electroluminescent device of the present invention does not contain a metal element other than boron. For example, the light emitting layer cam be composed of a compound consisting of atoms selected from the group consisting of a carbon atom, a hydrogen atom, a nitrogen atom, an oxygen atom, a sulfur atom and a boron atom. For example, the light emitting layer can be composed of a compound consisting of atoms selected from the group consisting of a carbon atom, a hydrogen atom, a nitrogen atom, an oxygen atom and a boron atom.

### (First Organic Compound)

The first organic compound used in the light emitting layer of the organic electroluminescent device of the present invention is selected from compounds having a larger lowest excited singlet energy than the second organic compound and the third organic compound. Preferably, the first organic compound has a function as a host material responsible for carrier transport. Also preferably, the first organic compound has a function of confining the energy of the third organic compound in the compound. With that, the third organic compound can efficiently convert the energy generated by recombination of holes and electrons in the molecule and the energy received from the first organic compound and the second organic compound into light emission.

The first organic compound is preferably an organic compound having a hole transport function and an electron transport function, capable of preventing the wavelength of the light emitted from being prolonged, and having a high glass transition temperature. In one preferred embodiment of the present invention, the first organic compound is selected from compounds not radiating delayed fluorescence. The light emission from the first organic compound is preferably less than 1% of the light emission from the organic electroluminescent device of the present invention, and can be, for example, less than 0.01%, or less than detection limit.

Preferably, the first organic compound does not contain a metal atom. For example, as the first organic compound, a compound composed of atoms selected from the group consisting of a carbon atom, a hydrogen atom, a nitrogen atom, an oxygen atom and a sulfur atom can be selected. For example, as the first organic compound, a compound composed of atoms selected from the group consisting of a carbon atom, a hydrogen atom, a nitrogen atom and an oxygen atom can be selected. For example, as the first organic compound, a compound composed of a carbon atom, a hydrogen atom, and a nitrogen atom can be selected.

Hereinunder shown are preferred compounds for use as the first organic compound.

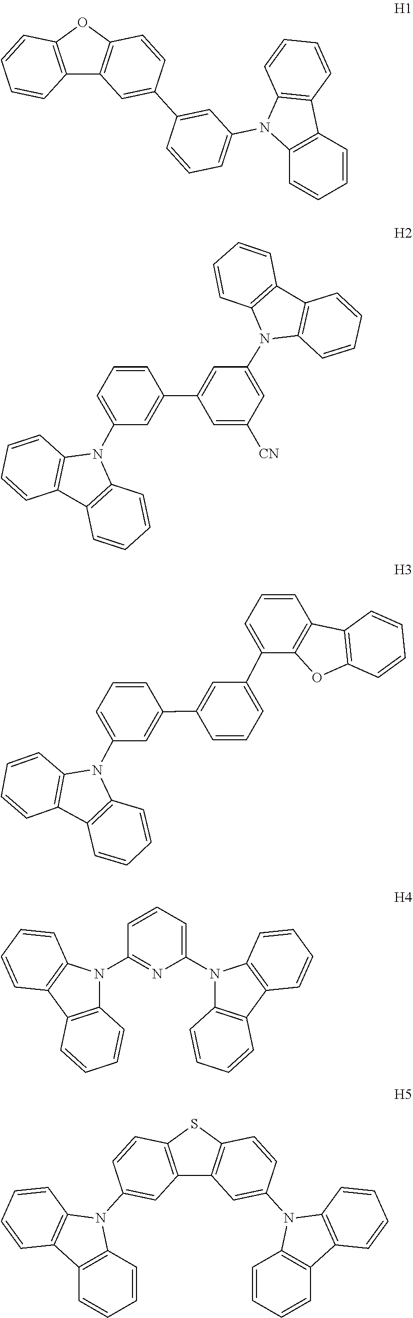 [SMILES: c1cc(-c2ccc3oc4ccccc4c3c2)cc(-n2c3ccccc3c3ccccc32)c1 ; N#Cc1cc(-c2cccc(-n3c4ccccc4c4ccccc43)c2)cc(-n2c3ccccc3c3ccccc32)c1 ; c1cc(-c2cccc(-n3c4ccccc4c4ccccc43)c2)cc(-c2cccc3c2oc2ccccc23)c1 ; c1cc(-n2c3ccccc3c3ccccc32)nc(-n2c3ccccc3c3ccccc32)c1 ; c1ccc2c(c1)c1ccccc1n2-c1ccc2sc3ccc(-n4c5ccccc5c5ccccc54)cc3c2c1]

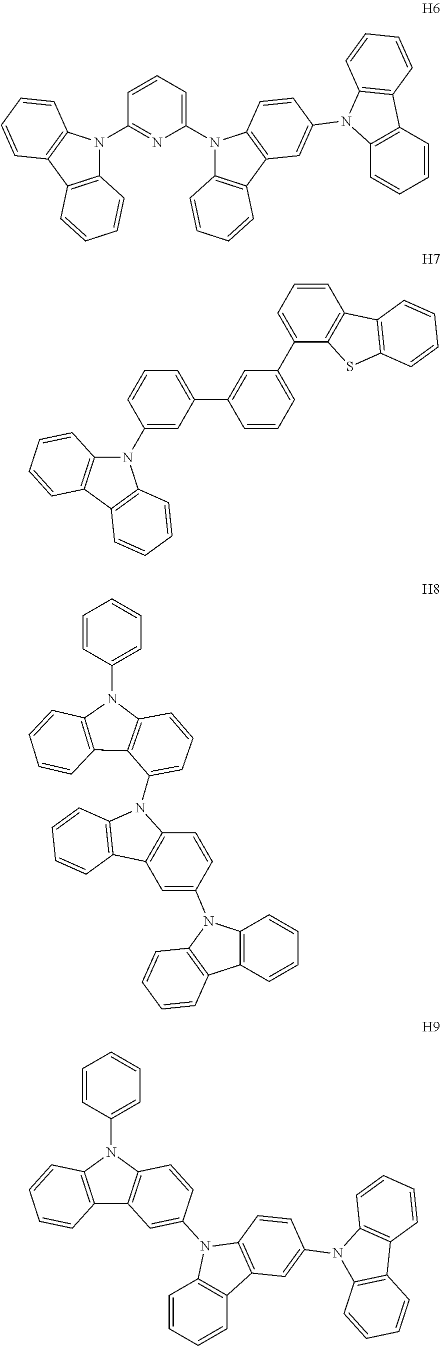 [SMILES: c1cc(-n2c3ccccc3c3ccccc32)nc(-n2c3ccccc3c3cc(-n4c5ccccc5c5ccccc54)ccc32)c1 ; c1cc(-c2cccc(-n3c4ccccc4c4ccccc43)c2)cc(-c2cccc3c2sc2ccccc23)c1 ; c1ccc(-n2c3ccccc3c3c(-n4c5ccccc5c5cc(-n6c7ccccc7c7ccccc76)ccc54)cccc32)cc1 ; c1ccc(-n2c3ccccc3c3cc(-n4c5ccccc5c5cc(-n6c7ccccc7c7ccccc76)ccc54)ccc32)cc1]

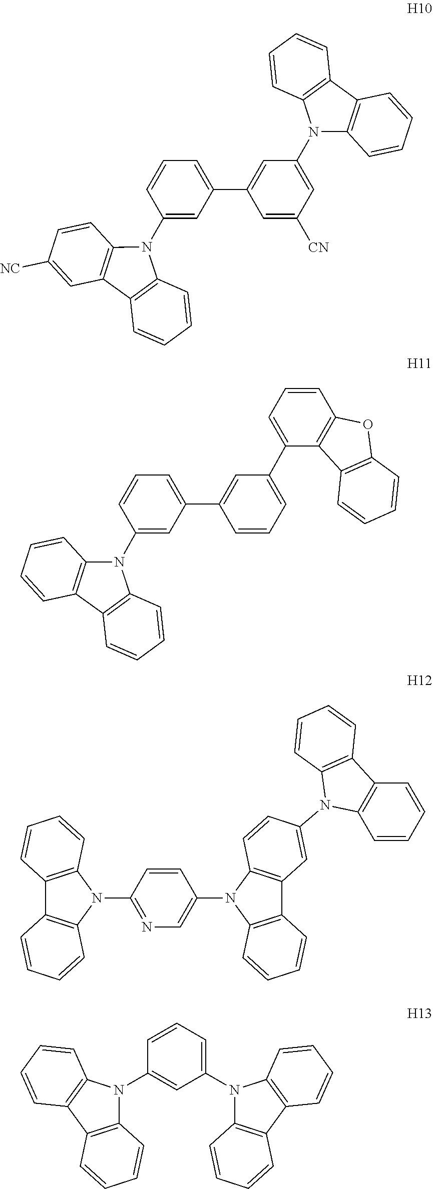 [SMILES: N#Cc1cc(-c2cccc(-n3c4ccccc4c4cc(C#N)ccc43)c2)cc(-n2c3ccccc3c3ccccc32)c1 ; c1cc(-c2cccc(-n3c4ccccc4c4ccccc43)c2)cc(-c2cccc3oc4ccccc4c23)c1 ; c1ccc2c(c1)c1ccccc1n2-c1ccc2c(c1)c1ccccc1n2-c1ccc(-n2c3ccccc3c3ccccc32)nc1 ; c1cc(-n2c3ccccc3c3ccccc32)cc(-n2c3ccccc3c3ccccc32)c1]

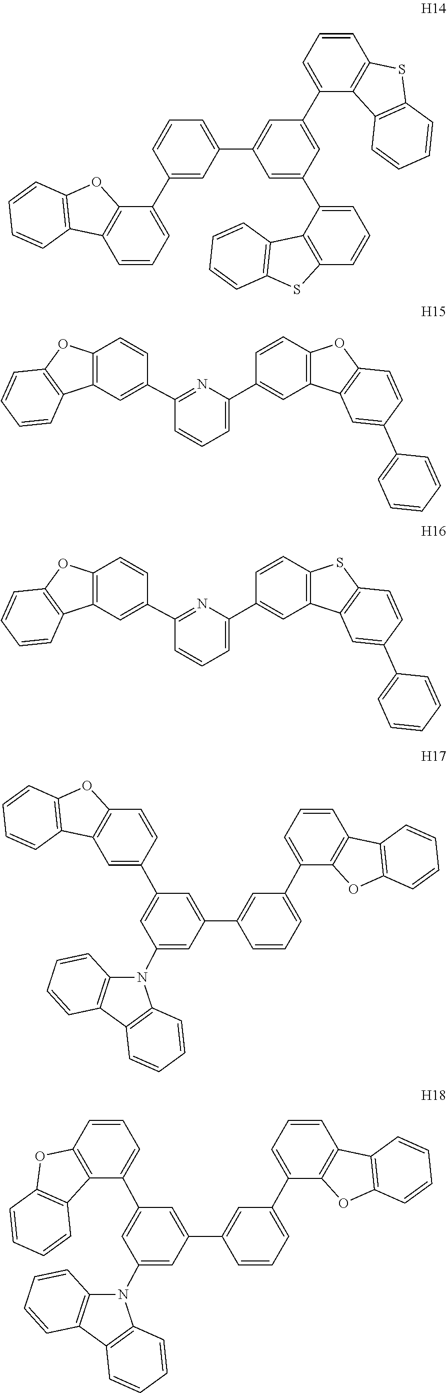 [SMILES: c1cc(-c2cc(-c3cccc4sc5ccccc5c34)cc(-c3cccc4sc5ccccc5c34)c2)cc(-c2cccc3c2oc2ccccc23)c1 ; c1ccc(-c2ccc3oc4ccc(-c5cccc(-c6ccc7oc8ccccc8c7c6)n5)cc4c3c2)cc1 ; c1ccc(-c2ccc3sc4ccc(-c5cccc(-c6ccc7oc8ccccc8c7c6)n5)cc4c3c2)cc1 ; c1cc(-c2cc(-c3ccc4oc5ccccc5c4c3)cc(-n3c4ccccc4c4ccccc43)c2)cc(-c2cccc3c2oc2ccccc23)c1 ; c1cc(-c2cc(-c3cccc4oc5ccccc5c34)cc(-n3c4ccccc4c4ccccc43)c2)cc(-c2cccc3c2oc2ccccc23)c1]

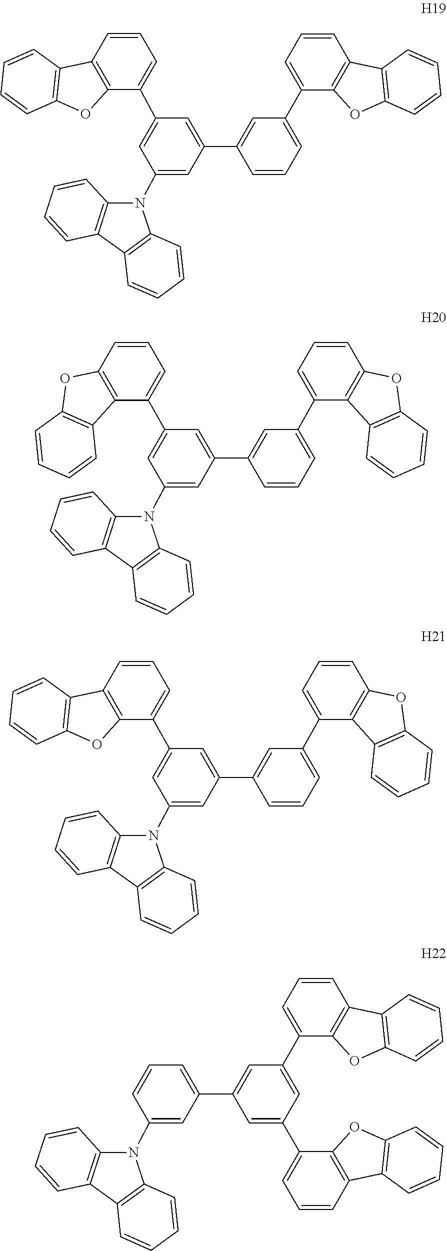

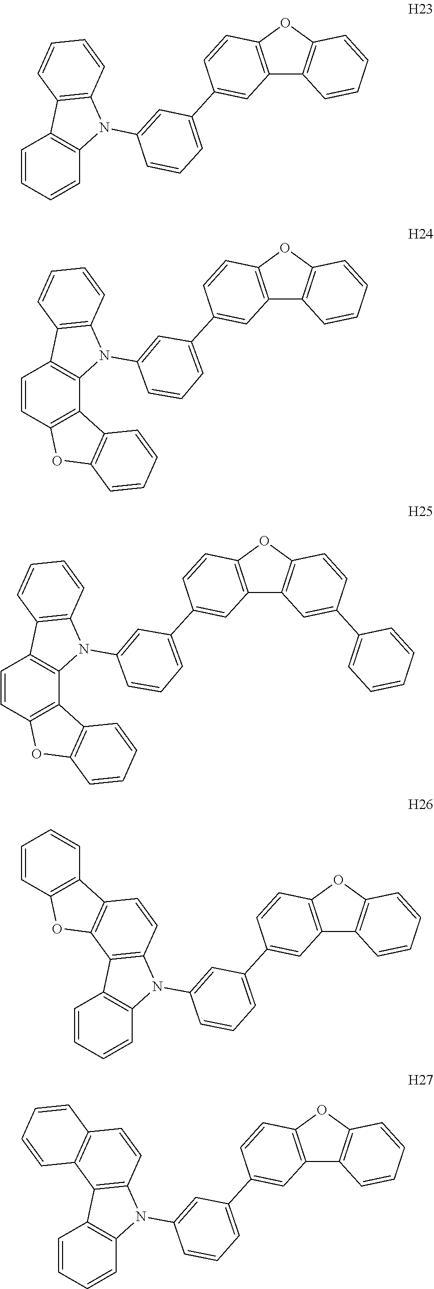 [SMILES: c1cc(-c2ccc3oc4ccccc4c3c2)cc(-n2c3ccccc3c3ccccc32)c1 ; c1cc(-c2ccc3oc4ccccc4c3c2)cc(-n2c3ccccc3c3ccc4oc5ccccc5c4c32)c1 ; c1ccc(-c2ccc3oc4ccc(-c5cccc(-n6c7ccccc7c7ccc8oc9ccccc9c8c76)c5)cc4c3c2)cc1 ; c1cc(-c2ccc3oc4ccccc4c3c2)cc(-n2c3ccccc3c3c4oc5ccccc5c4ccc32)c1 ; c1cc(-c2ccc3oc4ccccc4c3c2)cc(-n2c3ccccc3c3c4ccccc4ccc32)c1]

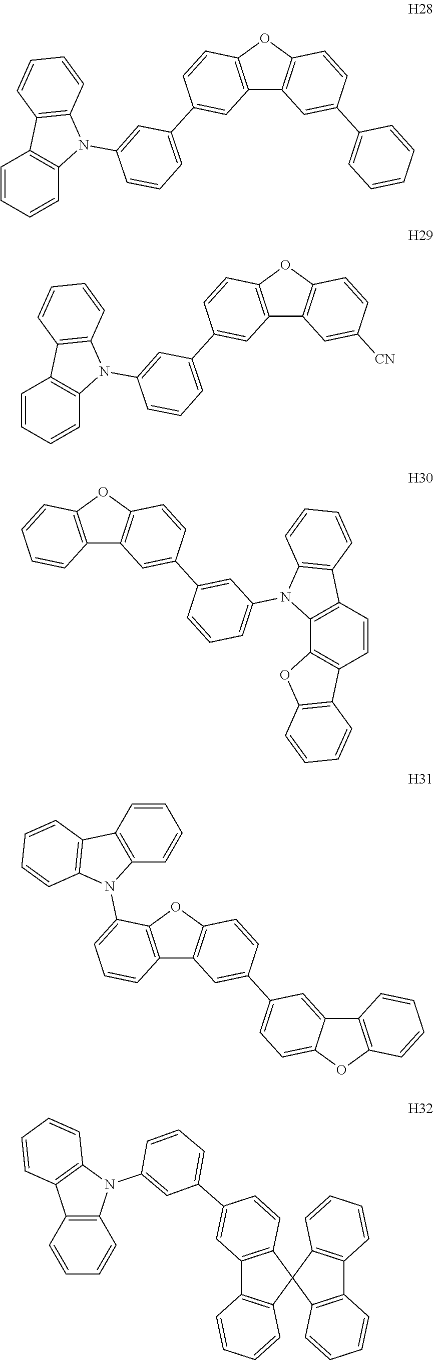 [SMILES: c1ccc(-c2ccc3oc4ccc(-c5cccc(-n6c7ccccc7c7ccccc76)c5)cc4c3c2)cc1 ; N#Cc1ccc2oc3ccc(-c4cccc(-n5c6ccccc6c6ccccc65)c4)cc3c2c1 ; c1cc(-c2ccc3oc4ccccc4c3c2)cc(-n2c3ccccc3c3ccc4c5ccccc5oc4c32)c1 ; c1ccc2c(c1)oc1ccc(-c3ccc4oc5c(-n6c7ccccc7c7ccccc76)cccc5c4c3)cc12 ; c1cc(-c2ccc3c(c2)-c2ccccc2C32c3ccccc3-c3ccccc32)cc(-n2c3ccccc3c3ccccc32)c1]

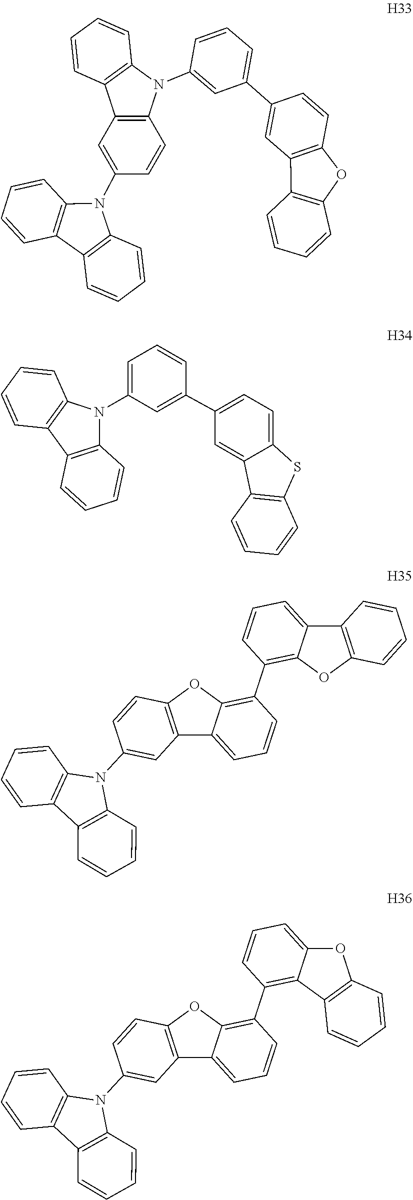 [SMILES: c1cc(-c2ccc3oc4ccccc4c3c2)cc(-n2c3ccccc3c3cc(-n4c5ccccc5c5ccccc54)ccc32)c1 ; c1cc(-c2ccc3sc4ccccc4c3c2)cc(-n2c3ccccc3c3ccccc32)c1 ; c1ccc2c(c1)oc1c(-c3cccc4c3oc3ccc(-n5c6ccccc6c6ccccc65)cc34)cccc12 ; c1ccc2c(c1)oc1cccc(-c3cccc4c3oc3ccc(-n5c6ccccc6c6ccccc65)cc34)c12]

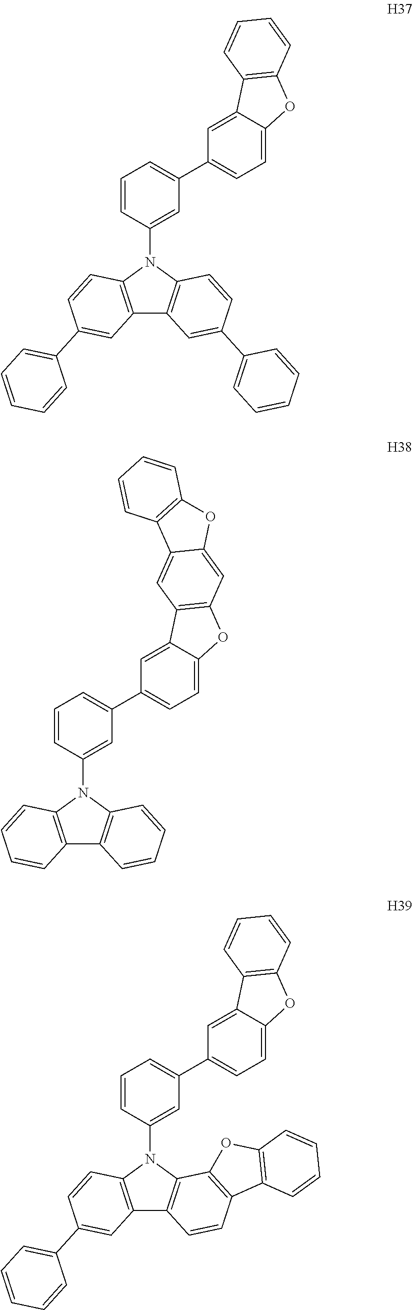 [SMILES: c1ccc(-c2ccc3c(c2)c2cc(-c4ccccc4)ccc2n3-c2cccc(-c3ccc4oc5ccccc5c4c3)c2)cc1 ; c1cc(-c2ccc3oc4cc5oc6ccccc6c5cc4c3c2)cc(-n2c3ccccc3c3ccccc32)c1 ; c1ccc(-c2ccc3c(c2)c2ccc4c5ccccc5oc4c2n3-c2cccc(-c3ccc4oc5ccccc5c4c3)c2)cc1]

### (Second Organic Compound)

The second organic compound used in the light emitting layer of the organic electroluminescent device of the present invention is a delayed fluorescent material having a lowest excited singlet energy smaller than that of the first organic compound and larger than that of the third organic compound, and having a HOMO energy smaller than that of the third organic compound. In the present invention, “delayed fluorescent material” is an organic compound which, in an excited state, undergoes reverse intersystem crossing from an excited triplet state to an excited singlet state, and which emits fluorescence (delayed fluorescence) in returning back from the excited singlet state to a ground state. In the invention, a compound which gives fluorescence having an emission lifetime of 100 ns (nanoseconds) or longer, when the emission lifetime is measured with a fluorescence lifetime measuring system (e.g., streak camera system by Hamamatsu Photonics KK), is referred to as a delayed fluorescent material. The second organic compound is a material capable of radiating delayed fluorescence, but radiation of delayed fluorescence derived from the second organic compound when used in the organic electroluminescent device of the present invention is not indispensable. Light emission from the second organic compound is preferably less than 10% of the light emission from the organic electroluminescent device of the present invention, and can be, for example, less than 1%, or less than 0.1%, or less than 0.01%, or less than detection limit.

In the organic electroluminescent device of the present invention, the second organic compound receives the energy from the first organic compound in an excited singlet state to transition into an excited singlet state. Also the second organic compound can receive the energy from the first organic compound in an excited triplet state to transition into an excited triplet state. Since the difference between the excited singlet energy and the excited triplet energy (ΔE_{ST}) of the second organic compound is small, the second organic compound in an excited triplet state can readily undergo reverse intersystem crossing to be the second organic compound in an excited singlet state. The second organic compound in the excited singlet state formed through the route gives the energy to the third organic compound to make the third organic compound transition into an excited singlet state.

The second organic compound is preferably such that the difference between the lowest excited singlet energy and the lowest excited triplet energy at 77 K, ΔE_{ST} is 0.3 eV or less, more preferably 0.25 eV or less, even more preferably 0.2 eV or less, further more preferably 0.15 eV or less, further more preferably 0.1 eV or less, further more preferably 0.07 eV or less, further more preferably 0.05 eV or less, further more preferably 0.03 eV or less, especially more preferably 0.01 eV or less.

When ΔE_{ST} is small, reverse intersystem crossing from an excited triplet state to an excited singlet state can more readily occur through thermal energy absorption, and therefore the second organic compound can function as a thermal activation type delayed fluorescent material. A thermal activation type delayed fluorescent material can absorb heat generated by a device to relatively readily undergo reverse intersystem crossing from an excited triplet state to an excited singlet state, and can make the excited triplet energy efficiently contribute toward light emission.

In the invention, a lowest excited singlet energy (E_{S1}) and a lowest excited triplet energy (E_{T1}) of a compound is determined according to the following process. ΔE_{ST} is a value determined by calculating E_{S1}-E_{S1}.

### (1) Lowest Excited Singlet Energy (E_{S1})

A thin film or a toluene solution (concentration: 10⁻⁵ mol/L) of the targeted compound is prepared as a measurement sample. The fluorescent spectrum of the sample is measured at room temperature (300 K). For the fluorescent spectrum, the emission intensity is on the vertical axis and the wavelength is on the horizontal axis. A tangent line is drawn to the rising of the emission spectrum on the short wavelength side, and the wavelength value kedge [nm] at the intersection between the tangent line and the horizontal axis is read. The wavelength value is converted into an energy value according to the following conversion expression to calculate E_{S1}.

Conversion Expression: E_{S1} [eV]=1239.85/λedge

For the measurement of the emission spectrum in Examples given below, an LED light source (by Thorlabs Corporation, M300L4) was used as an excitation light source along with a detector (by Hamamatsu Photonics K.K., PMA-12 Multichannel Spectroscope C10027-01).

### (2) Lowest Excited Triplet Energy (E_{T1})

The same sample as that for measurement of the lowest excited singlet energy (E_{S1}) is cooled to 77 [K] with liquid nitrogen, and the sample for phosphorescence measurement is irradiated with excitation light (300 nm), and using a detector, the phosphorescence thereof is measured. The emission after 100 milliseconds from irradiation with the excitation light is drawn as a phosphorescent spectrum. A tangent line is drawn to the rising of the phosphorescent spectrum on the short wavelength side, and the wavelength value λedge [nm] at the intersection between the tangent line and the horizontal axis is read. The wavelength value is converted into an energy value according to the following conversion expression to calculate E_{T1}.

Conversion Expression: E_{T1} [eV]=1239.85/λedge

The tangent line to the rising of the phosphorescent spectrum on the short wavelength side is drawn as follows. While moving on the spectral curve from the short wavelength side of the phosphorescent spectrum toward the maximum value on the shortest wavelength side among the maximum values of the spectrum, a tangent line at each point on the curve toward the long wavelength side is taken into consideration. With rising thereof (that is, with increase in the vertical axis), the inclination of the tangent line increases. The tangent line drawn at the point at which the inclination value has a maximum value is referred to as the tangent line to the rising on the short wavelength side of the phosphorescent spectrum.

The maximum point having a peak intensity of 10% or less of the maximum peak intensity of the spectrum is not included in the maximum value on the above-mentioned shortest wavelength side, and the tangent line drawn at the point which is closest to the maximum value on the shortest wavelength side and at which the inclination value has a maximum value is referred to as the tangent line to the rising on the short wavelength side of the phosphorescent spectrum.

Preferably, the second organic compound does not contain a metal atom. For example, as the second organic compound, a compound composed of atoms selected from the group consisting of a carbon atom, a hydrogen atom, a nitrogen atom, an oxygen atom and a sulfur atom can be selected. For example, as the second organic compound, a compound composed of atoms selected from the group consisting of a carbon atom, a hydrogen atom, a nitrogen atom and an oxygen atom can be selected. For example, as the second organic compound, a compound composed of a carbon atom, a hydrogen atom and a nitrogen atom can be selected.

As a typical second organic compound, there can be mentioned a compound having a structure in which one or two cyano groups and at least one donor group bond to a benzene ring. Preferred examples of the donor group include a substituted or unsubstituted carbazol-9-yl group. Examples of the compound include a compound having at least three substituted or unsubstituted carbazol-9-yl groups bonding to a benzene ring, and a compound in which at least one of the two benzene rings constituting a carbazol-9-yl group existing is condensed with the 5-membered ring moiety of a substituted or unsubstituted benzofuran ring, a substituted or unsubstituted benzothiophene ring, a substituted or unsubstituted indole ring, a substituted or unsubstituted indene ring, or a substituted or unsubstituted silaindene ring.

A compound represented by the following general formula (1) and capable of emitting delayed fluorescence is preferably employed as the second organic compound.

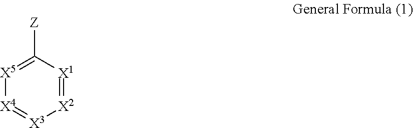

In the general formula (1), X¹ to X⁵ each represent N or C—R. R represents a hydrogen atom, a deuterium atom or a substituent. When at least two of X¹ to X⁵ are (C—R)'s, these (C—R)'s can be the same as or different from each other. However, at least one of X¹ to X⁵ is C-D (where D represents a donor group). When all X¹ to X⁵ are (C—R)'s, Z represents an acceptor group.

Of the compound represented by the general formula (1), especially preferred is a compound represented by the following general formula (2).

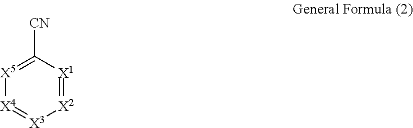

In the general formula (2), X¹ to X⁵ each represent N or C—R. R represents a hydrogen atom, a deuterium atom or a substituent. When at least two of X¹ to X⁵ are (C—R)'s, these (C—R)'s can be the same as or different from each other. However, at least one of X¹ to X⁵ is C-D (where D represents a donor group).

In one preferred embodiment of the present invention, all X¹ to X⁵ are not C—CN.

Namely, the compound has a structure in which one or two cyano groups and at least one donor group bond to the benzene ring. In another preferred embodiment of the present invention, X² alone is C—CN, and X¹ and X³ to X⁵ are not C—CN. Namely, the compound has a structure in which at least one donor group bonds to the benzene ring of isophthalonitrile. In another embodiment of the present invention, X³ alone is C—CN, and X¹, X², X⁴, and X⁵ are not C—CN. Namely, the compound has a structure in which at least one donor group bonds to the benzene ring of terephthalonitrile.

The acceptor group that Z in the general formula (1) represents is a group having a property of donating an electron to the ring to which Z bonds, and can be selected from, for example, a group having a positive Hammett's σₚ value. The donor group that D in the general formula (1) and the general formula (2) represents is a group having a property of attracting an electron from the ring to which D bonds, and can be selected from, for example, a group having a negative Hammett's σₚ value. Hereinafter an acceptor group can be referred to as A.

Here, “Hammett's σₚ value” is one propounded by L. P. Hammett, and is one to quantify the influence of a substituent on the reaction rate or the equilibrium of a para-substituted benzene derivative. Specifically, the value is a constant (σₚ) peculiar to the substituent in the following equation that is established between a substituent and a reaction rate constant or an equilibrium constant in a para-substituted benzene derivative:

log(k/k₀)=pσₚ

or

log(K/K₀)=pσₚ

In the above equations, k represents a rate constant of a benzene derivative not having a substituent; k₀ represents a rate constant of a benzene derivative substituted with a substituent; K represents an equilibrium constant of a benzene derivative not having a substituent; K₀ represents an equilibrium constant of a benzene derivative substituted with a substituent; p represents a reaction constant to be determined by the kind and the condition of reaction. Regarding the description relating to the “Hammett's σₚ value” and the numerical value of each substituent, reference may be made to the description relating to σₚ value in Hansch, C. et. al., Chem. Rev., 91, 165-195 (1991).

Specific examples of the acceptor group include a cyano group and the acceptor groups for the acceptor group, reference can be made to the preferred examples of the acceptor group for A in the general formulae (12) to (14) given below. In addition, for specific examples of the donor group, reference can be made to the preferred examples of the donor group for D in the general formulae (12) to (14) given below.

In the general formula (1) and the general formula (2), X¹ to X⁵ each represent N or C—R and at least one of them is C-D. The number of N's of X¹ to X⁵ is 0 to 4, and for example, a case where X¹ and X³ and X⁵, X¹ and X³, X¹ and X⁴, X² and X³, X¹ and X⁵, X² and X⁴, X¹ alone, X² alone, or X³ alone are/is N('s) can be exemplified. The number of (C-D)'s of X¹ to X⁵ is 1 to 5, and is preferably 2 to 5. For example, a case where X¹ and X² and X³ and X⁴ and X⁵, X¹ and X² and X⁴ and X⁵, X¹ and X² and X³ and X⁴, X¹ and X³ and X⁴ and X⁵, X¹ and X³ and X⁵, X¹ and X² and X⁵, X¹ and X² and X⁴, X¹ and X³ and X⁴, X¹ and X³, X¹ and X⁴, X² and X³, X¹ and X⁵, X² and X⁴, X¹ alone, X² alone, or X³ alone are/is (C-D)('s) can be exemplified. At least one of X¹ to X⁵ can be C-A. Here, A represents an acceptor group. The number of (C-A)'s of X¹ to X⁵ is preferably 0 to 2, more preferably 0 or 1. A of C-A is preferably a cyano group, or an unsaturated, nitrogen atom-having heterocyclic aromatic group. X¹ to X⁵ each can be independently C-D or C-A.

When the neighboring two of X¹ to X⁵ are (C—R)'s, the two R's can bond to each other to form a cyclic structure. The cyclic structure to be formed by bonding can be an aromatic ring or an aliphatic ring, or can contain a hetero atom, and further, the cyclic structure can also be a condensed ring of two or more rings. Here the hetero atom is preferably selected from the group consisting of a nitrogen atom, an oxygen atom and a sulfur atom. Examples of the cyclic structure to be formed include a benzene ring, a naphthalene ring, a pyridine ring, a pyridazine ring, a pyrimidine ring, a pyrazine ring, a pyrrole ring, an imidazole ring, a pyrazole ring, an imidazoline ring, an oxazole ring, an isoxazole ring, a thiazole ring, an isothiazole ring, a cyclohexadiene ring, a cyclohexene ring, a cyclopentaene ring, a cycloheptatriene ring, a cycloheptadiene ring, a cycloheptaene ring, a furan ring, a thiophene ring, a naphthyridine ring, a quinoxaline ring, and a quinoline ring. Many rings can be condensed to form a ring such as a phenanthrene ring or a triphenylene ring.

The donor group D in the general formula (1) and the general formula (2) is preferably a group represented by, for example, the following general formula (3).

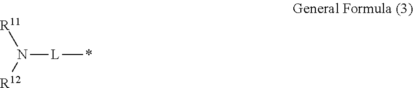

In the general formula (3), R¹¹ and R¹² each independently represent a substituted or unsubstituted alkyl group, a substituted or unsubstituted alkenyl group, a substituted or unsubstituted aryl group, or a substituted or unsubstituted heteroaryl group. R¹¹ and R¹² can bond to each other to form a cyclic structure. L represents a single bond, a substituted or unsubstituted arylene group, or a substituted or unsubstituted heteroarylene group. The substituent that can be introduced into the arylene group or the heteroarylene group of L can be the group represented by the general formula (1) or the general formula (2), or cab be a group represented by the general formulae (3) to (6) to be mentioned hereinunder. The groups represented by these (1) to (6) can be introduced in an amount up to the maximum number of the substituents capable of being introduced into L. In the case where plural groups of the general formulae (1) to (6) are introduced, these substituents can be the same as or different from each other. * indicates the bonding position to the carbon atom (C) that constitutes the ring skeleton of the ring in the general formula (1) or the general formula (2).

In the present description, “alkyl group” can be linear, branched or cyclic. Two or more of a linear moiety, a cyclic moiety and a branched moiety can be in the group as mixed.

The carbon number of the alkyl group can be, for example, 1 or more, 2 or more, or 4 or more. The carbon number can also be 30 or less, 20 or less, 10 or less, 6 or less, or 4 or less. Specific examples of the alkyl group include a methyl group, an ethyl group, an n-propyl group, an isopropyl group, an n-butyl group, an isobutyl group, a tert-butyl group, an n-pentyl group, an isopentyl group, an n-hexyl group, an isohexyl group, a 2-ethylhexyl group, an n-heptyl group, an isoheptyl group, an n-octyl group, an isooctyl group, an n-nonyl group, an isononyl group, an n-decanyl group, an isodecanyl group, a cyclopentyl group, a cyclohexyl group, and a cycloheptyl group. The alkyl group to be a substituent can be further substituted with an aryl group.

“Alkenyl group” can be linear, branched or cyclic. Two or more of a linear moiety, a cyclic moiety and a branched moiety can be in the group as mixed. The carbon number of the alkenyl group can be, for example, 2 or more, or 4 or more. The carbon number can also be 30 or less, 20 or less, 10 or less, 6 or less, or 4 or less. Specific examples of the alkenyl group include an ethenyl group, an n-propenyl group, an isopropenyl group, an n-butenyl group, an isobutenyl group, an n-pentenyl group, an isopentenyl group, an n-hexenyl group, an isohexenyl group, and a 2-ethylhexenyl group. The alkenyl group to be a substituent can be further substituted with a substituent.

“Aryl group” and “Heteroaryl group” each can be a single ring or can be a condensed ring of two or more kinds of rings. In the case of a condensed ring, the number of the rings that are condensed is preferably 2 to 6, and, for example, can be selected from 2 to 4. Specific examples of the ring include a benzene ring, a pyridine ring, a pyrimidine ring, a triazine ring, a naphthalene ring, an anthracene ring, a phenanthrene ring, a triphenylene ring, a quinoline ring, a pyrazine ring, a quinoxaline ring, and a naphthyridine ring. Specific examples of the aryl group or the heteroaryl group include a phenyl group, a 1-naphthyl group, a 2-naphthyl group, a 1-anthracenyl group, a 2-anthracenyl group, a 9-anthracenyl group, a 2-pyridyl group, a 3-pyridyl group, and a 4-pyridyl group. For “arylene group” and “heteroarylene group”, the valance of the aryl group and the heteroaryl group is exchanged from 1 to 2, and the thus-exchanged description can be referred to.

The substituent means a monovalent group that can substitute for a hydrogen atom, and does not mean a concept of condensation. Regarding the description and the preferred range of the substituent, reference can be made to the description and the preferred range of the substituent in the general formula (7) to be mentioned hereinunder.

The compound represented by the general formula (3) is preferably a compound represented by any of the following general formulae (4) to (6).

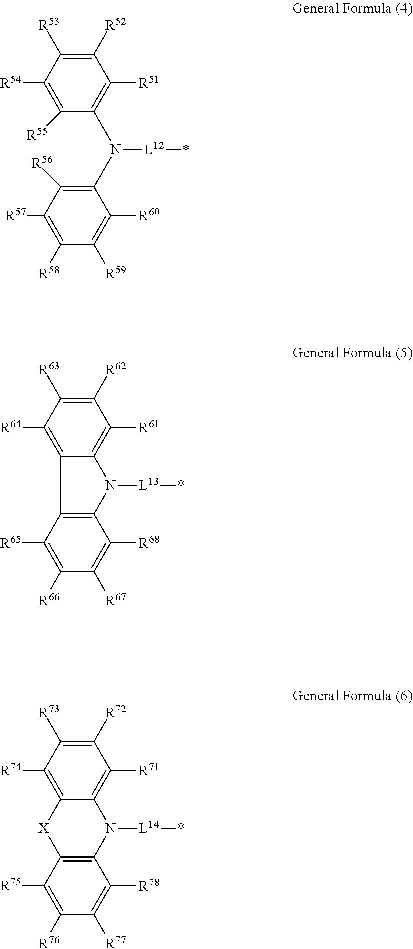

In the general formulae (4) to (6), R⁵¹ to R⁶⁰, R⁶¹ to R⁶⁸, and R⁷¹ to R⁷⁸ each independently represent a hydrogen atom, a deuterium atom or a substituent. Regarding the description and the preferred range of the substituent as referred to herein, reference can be made to the description and the preferred range of the substituent in the general formula (7) to be mentioned hereinunder. R⁵¹ to R⁶⁰ R⁶¹ to R⁶⁸, and R⁷¹ to R⁷⁸ each are also preferably a group represented by any of the above-mentioned general formulae (4) to (6). The number of the substituents in the general formulae (4) to (6) is not specifically limited. Cases where all are unsubstituted (that is, all are hydrogen atoms or deuterium atoms) are also preferred. In the case where each of the general formulae (4) to (6) has two or more substituents, these substituents can be the same or different. When the general formulae (4) to (6) have substituents, the substituents are preferably any of R⁵² to R⁵⁹ in the case of the general formula (4), or any of R⁶² to R⁶⁷ in the case of the general formula (5), or any of R⁷² to R⁷⁷ in the case of the general formula (6).

In the general formula (6), X represents an oxygen atom, a sulfur atom, a substituted or unsubstituted nitrogen atom, a substituted or unsubstituted carbon atom, a substituted or unsubstituted silicon atom or a carbonyl group that is divalent and has a linking chain length of one atom, or represents a substituted or unsubstituted ethylene group, a substituted or unsubstituted vinylene group, a substituted or unsubstituted o-arylene group or a substituted or unsubstituted o-heteroarylene group that is divalent and has a linking chain length of two atoms. Regarding the specific examples and the preferred range of the substituents, reference can be made to the description of the substituents in the general formula (1) and the general formula (2).

In the general formulae (4) to (6), L¹² to L¹⁴ each represent a single bond, a substituted or unsubstituted arylene group or a substituted or unsubstituted heteroarylene group. Regarding the description and the preferred range of the arylene group and the heteroarylene group that L¹² to L¹⁴ represent, reference can be made to the description and the preferred range of the arylene group and the heteroarylene group that L represents. L¹² to L¹⁴ each are preferably a single bond, or a substituted or unsubstituted arylene group. Here the substituent for the arylene group and the heteroarylene group can be the group represented by the general formulae (1) to (6). The group represented by the general formulae (1) to (6) can be introduced into L¹² to L¹⁴ in an amount up to the maximum number of the substituents that can be introduced thereinto. In the case where plural groups of the general formulae (1) to (6) are introduced, these substituents can be the same as or different from each other. * indicates the bonding position to the carbon atom (C) that constitutes the ring skeleton of the ring in the general formula (1) or the general formula (2).

In the general formulae (4) to (6), R⁵¹ and R⁵², R⁵² and R⁵³ R⁵³ and R⁵⁴ R⁵⁴ and R⁵⁵, R⁵⁵ and R⁵⁶ R⁵⁶ and R⁵⁷, R⁵⁷ and R⁵⁸, R⁵⁸ and R⁵⁹, R⁵⁹ and R⁶⁰, R⁶¹ and R⁶², R⁶² and R⁶³ R⁶³ and R⁶⁴ R⁶⁵ and R⁶⁶ R⁶⁶ and R⁶⁷, R⁶⁷ and R⁶⁸, R⁷¹ and R⁷², R⁷² and R⁷³, R⁷³ and R⁷⁴, R⁷⁵ and R⁷⁶, R⁷⁶ and R⁷⁷, and R⁷⁷ and R⁷⁸ each can bond to each other to form a cyclic structure. Regarding the description and the preferred examples of the cyclic structure, reference can be made to the description and the preferred examples of the cyclic structure for X¹ to X⁵ in the above-mentioned general formula (1) and general formula (2).

Of the cyclic structure, preferred is a structure in which at least one benzene ring of the general formulae (4) to (6) is condensed with a substituted or unsubstituted benzofuran ring, a substituted or unsubstituted benzothiophene ring, a substituted or unsubstituted indole ring, a substituted or unsubstituted indene ring or a substituted or unsubstituted silaindene ring. More preferred is a group represented by the following general formulae (5a) to (50 condensed with the general formula (5).

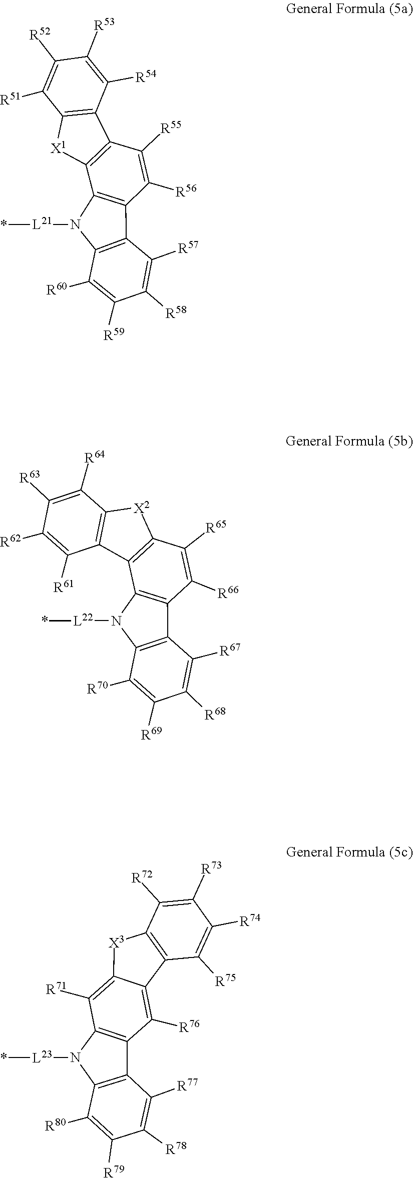

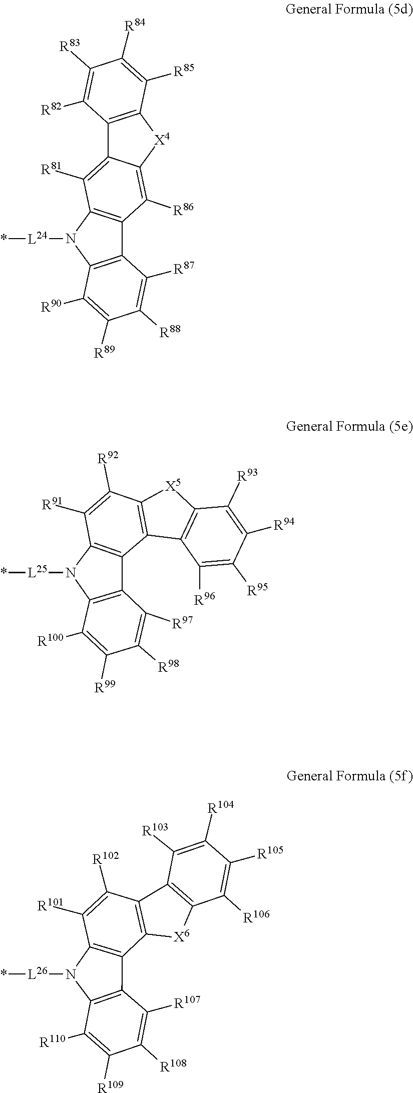

In the general formulae (5a) to (50, L¹¹ and L²¹ to L²⁶ each represent a single bond or a divalent linking group. Regarding the description and the preferred range of L¹¹ and L²¹ to L²⁶, reference can be made to the description and the preferred range of L² mentioned above.

In the general formulae (5a) to (5f, R⁴¹ to R¹¹⁰ each independently represent a hydrogen atom or a substituent. R⁴¹ and R⁴², R⁴² and R⁴³ R⁴³ and R⁴⁴, R⁴⁴ and R⁴⁵ R⁴⁵ and R⁴⁶, R⁴⁶ and R⁴⁷, R⁴⁷ and R⁴⁸, R⁵¹ and R⁵², R⁵² and R⁵³ R⁵³ and R⁵⁴ R⁵⁴ and R⁵⁵ R⁵⁵ and R⁵⁶, R⁵⁶ and R⁵⁷, R⁵⁷ and R⁵⁸, R⁵⁸ and R⁵⁹, R⁵⁹ and Rho R⁶¹ and R⁶², R⁶² and R⁶³, R⁶³ and R⁶⁴, R⁶⁵ and R⁶⁶ R⁶⁶ and R⁶⁷, R⁶⁷ and R⁶⁸, R⁶⁸ and R⁶⁹, R⁶⁹ and R⁷⁰, R⁷² and R⁷³, R⁷³ and R⁷⁴, R⁷⁴ and R⁷⁵, R⁷⁵ and R⁷⁶, R⁷⁶ and R⁷⁷, R⁷⁷ and R⁷⁸, R⁷⁸ and R⁷⁹, R⁷⁹ and R⁸⁰, R⁸¹ and R⁸², R⁸² and R⁸³, R⁸³ and R⁸⁴, R⁸⁴ and R⁸⁵, R⁸⁶ and R⁸⁷, R⁸⁷ and R⁸⁸, R⁸⁸ and R⁸⁹, R⁸⁹ and R⁹⁰, R⁹¹ and R⁹², R⁹³ and R⁹⁴, R⁹⁴ and R⁹⁵, R⁹⁵ and R⁹⁶, R⁹⁶ and R⁹⁷, R⁹⁷ and R⁹⁸, R⁹⁹ and R¹⁰⁰, R¹⁰¹ and R¹⁰², R¹⁰² and R¹⁰³, R¹⁰³ and R¹⁰⁴, R¹⁰⁴ and R¹⁰⁵, R¹⁰⁵ and R¹⁰⁶, R¹⁰⁷ and R¹⁰⁸, R¹⁰⁸ and R¹⁰⁹, and R¹⁰⁹ and R¹¹⁰ each can bond to each other to form a cyclic structure. The cyclic structure to be formed by bonding can be an aromatic ring or an aliphatic ring, or can contain a hetero atom. Further, the cyclic structure can be a condensed ring of two or more rings. Hetero atom as referred to herein is preferably selected from the group consisting of a nitrogen atom, an oxygen atom and a sulfur atom. Examples of the cyclic structure to be formed include a benzene ring, a naphthalene ring, a pyridine ring, a pyridazine ring, a pyrimidine ring, a pyrazine ring, a pyrrole ring, an imidazole ring, a pyrazole ring, an imidazoline ring, an oxazole ring, an isoxazole ring, a thiazole ring, an isothiazole ring, a cyclohexadiene ring, a cyclohexene ring, a cyclopentaene ring, a cycloheptatriene ring, a cycloheptadiene ring, a cycloheptaene ring, a furan ring, a thiophene ring, a naphthyridine ring, a quinoxaline ring and a quinoline ring. The cyclic structure also includes a ring formed by condensation of many rings, such as a phenanthrene ring and a triphenylene ring. The number of the rings contained in the group represented by the general formula (6) can be selected from the range of 3 to 5, or can be selected from the range of 5 to 7. The number of the rings contained in the group represented by the general formulae (5a) to (5f) can be selected from the range of 5 to 7, or can be 5.

The substituent that R⁴¹ to R¹¹⁰ can have includes the groups of the below-mentioned substituent group A, and is preferably an unsubstituted alkyl group having 1 to 10 carbon atoms, or an aryl group having 6 to 10 carbon atoms and optionally substituted with an unsubstituted alkyl group having 1 to 10 carbon atoms. In one preferred embodiment of the present invention, R⁴¹ to R¹¹⁰ each are a hydrogen atom or an unsubstituted alkyl group having 1 to 10 carbon atoms. In one preferred embodiment of the present invention, R⁴¹ to R¹¹⁰ each are a hydrogen atom or an unsubstituted aryl group having 6 to 10 carbon atoms. In one preferred embodiment of the present invention, R⁴¹ to R¹⁰⁰ are all hydrogen atoms.

The carbon atom (ring skeleton constituting carbon atom) to which R⁴¹ to R¹⁰⁰ bond in the general formulae (5a) to (50 can be each independently substituted with a nitrogen atom. Namely, C—R⁴¹ to C—R¹⁰⁰ in the general formulae (5a) to (50 each independently can be substituted with N. The number of the carbon atoms substituted with a nitrogen atom is preferably 0 to 4 in the groups represented by the general formulae (5a) to (50, more preferably 1 or 2. In one embodiment of the present invention, the number substituted with a nitrogen atom is 0. In the case where two or more are substituted with a nitrogen atom, preferably, the number of the nitrogen atom substituted in one ring is one.

In the general formulae (5a) to (5f), X¹ to X⁶ each represent an oxygen atom, a sulfur atom or N—R. In one embodiment of the present invention, X¹ to X⁶ are oxygen atoms. In one embodiment of the present invention, X¹ to X⁶ are sulfur atoms. In one embodiment of the present invention, X¹ to X⁶ are N—R. R represents a hydrogen atom or a substituent, and is preferably a substituent. As the substituent, there can be exemplified the substituents selected from the below-mentioned substituent group A. For example, an unsubstituted phenyl group, or a phenyl group substituted with one group selected from the group consisting of an alkyl group and an aryl group or substituted with a combination of two or more of the groups is preferably employed.

In the general formulae (5a) to (5f), * indicates a bonding position.

A compound represented by the following general formula (7) and capable of emitting delayed fluorescence can be especially favorably used as the delayed fluorescent material in the present invention. In a preferred embodiment of the present invention, the compound represented by the general formula (7) can be employed as the second organic compound.

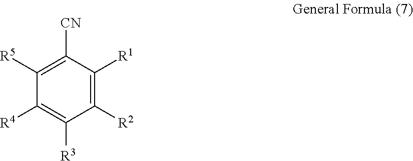

In the general formula (7), 0 to 4 of R¹ to R⁵ each represent a cyano group, at least one of R¹ to R⁵ represents a substituted amino group, and the remaining R¹ to R⁵ are hydrogen atoms or deuterium atoms, or represent any other substituent than a cyano group and a substituted amino group.

Here the substituted amino group is preferably a substituted or unsubstituted diarylamino group, and the two aryl groups constituting the substituted or unsubstituted diarylamino group can bond to each other. The bonding can be made via a single bond (in such a case, a carbazole ring is formed), or via a linking group such as —O—, —S—, —N(R⁶)—, —C(R⁷)(R⁸)—, or —Si(R⁹)(R¹⁰)—. Here, R⁶ to R¹⁰ each represent a hydrogen atom, a deuterium atom or a substituent, and R⁷ and R⁸, and R⁹ and R¹⁰ each can bond to each other to form a cyclic structure.

A substituted amino group can be any of R¹ to R⁵, and for example, R¹ and R², R¹ and R³, R¹ and R⁴, R¹ and R⁵, R² and R³, R² and R⁴, R¹ and R² and R³, R¹ and R² and R⁴, R¹ and R² and R⁵, R¹ and R³ and R⁴, R¹ and R³ and R⁵, R² and R³ and R⁴, R¹ and R² and R³ and R⁴, R¹ and R² and R³ and R⁵, R¹ and R² and R⁴ and R⁵, and R¹ and R² and R³ and R⁴ and R⁵ each can be a substituted amino group. A cyano group can also be any of R¹ to R⁵, and for example, R¹, R², R³, R¹ and R², R¹ and R³, R¹ and R⁴, R¹ and R⁵, R² and R³, R² and R⁴, R¹ and R² and R³, R¹ and R² and R⁴, R¹ and R² and R⁵, R¹ and R³ and R⁴, R¹ and R³ and R⁵, and R² and R³ and R⁴ each can be a cyano group.

R¹ to R⁵ that are neither a cyano group nor a substituted amino group each represent a hydrogen atom, a deuterium atom or a substituent. Examples of the substituent referred to herein include a substituent group A that contains a hydroxy group, a halogen atom (e.g., fluorine atom, chlorine atom, bromine atom, iodine atom), an alkyl group (for example, having 1 to 40 carbon atoms), an alkoxy group (for example, having 1 to 40 carbon atoms), an alkylthio group (for example, having 1 to 40 carbon atoms), an aryl group (for example, having 6 to 30 carbon atoms), an aryloxy group (for example, having 6 to 30 carbon atoms), an arylthio group (for example, having 6 to 30 carbon atoms), a heteroaryl group (for example, having 5 to 30 ring skeleton constituting atoms), a heteroaryloxy group (for example, having 5 to 30 ring skeleton constituting atoms), a heteroarylthio group (for example, having 5 to 30 ring skeleton constituting atoms), an acyl group (for example, having 1 to 40 carbon atoms), an alkenyl group (for example, having 1 to 40 carbon atoms), an alkynyl group (for example, having 1 to 40 carbon atoms), an alkoxycarbonyl group (for example, having 1 to 40 carbon atoms), an aryloxycarbonyl group (for example, having 1 to 40 carbon atoms), a heteroaryloxycarbonyl group (for example, having 1 to 40 carbon atoms), a silyl group (for example, trialkylsilyl group having 1 to 40 carbon atoms), a nitro group, and groups listed herein and substituted with one or more groups also listed herein. Preferred examples of the substituent of the diarylamino group in which the aryl group is substituted also include the substituents of the substituent group A, and further include a cyano group and a substituted amino group.

Regarding the compound group included in the general formula (7) and specific examples of the compounds, reference can be made to WO2013/154064, paragraphs 0008 to 0048; WO2015/080183, paragraphs 0009 to 0030; WO2015/129715, paragraphs 0006 to 0019; JP2017-119663A, paragraphs 0013 to 0025; JP2017-119664A, paragraphs 0013 to 0026; which are hereby incorporated by reference as a part of the present specification.

Further a compound represented by the following general formula (8) and capable of emitting delayed fluorescence can also be especially preferably used as the delayed fluorescent material in the present invention. In a preferred embodiment of the present invention, the compound represented by the general formula (8) can be employed as the second organic compound.

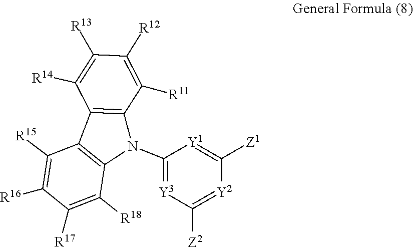

In the general formula (8), any two of Y¹, Y² and Y³ are nitrogen atoms and the remaining one is a methine group, or all of Y¹, Y² and Y³ are nitrogen atoms. Z¹ and Z² each independently represent a hydrogen atom, a deuterium atom or a substituent. R^{a}′ to R¹² each independently represent a hydrogen atom, a deuterium atom or a substituent, and at least one of R^{a}′ to R¹² is preferably a substituted or unsubstituted arylamino group or a substituted or unsubstituted carbazolyl group. The benzene ring to constitute the arylamino group and the benzene ring to constitute the carbazolyl group each can form a single bond or a linking group together with any of R¹¹ to R¹². The compound represented by the general formula (8) contains at least two carbazole structures in the molecule. Examples of the substituent that Z¹ and Z² can take include the substituents in the above-mentioned substituent group A. Specific examples of the substituent that R¹¹ to R¹⁸, the arylamino group and the carbazolyl group can take include the substituents in the substituent group A, and a cyano group, a substituted arylamino group and a substituted alkylamino group. R¹¹ and R¹², R¹² and R¹³ R¹³ and R¹⁴ R¹⁵ and R¹⁶ R¹⁶ and R¹⁷, and R¹⁷ and R¹⁸ each can bond to each other to form a cyclic structure.

Among the compounds represented by the general formula (8), those represented by the following general formula (9) are especially useful.

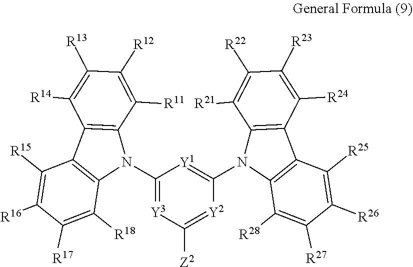

In the general formula (9), any two of Y¹, Y² and Y³ are nitrogen atoms and the remaining one is a methine group, or all of Y¹, Y² and Y³ are nitrogen atoms. Z² represents a hydrogen atom, a deuterium atom or a substituent. R¹¹ to R¹⁸ and R²¹ to R²⁸ each independently represent a hydrogen atom, a deuterium atom or a substituent. At least one of R¹¹ to R¹⁸ and/or at least one of R²¹ to R²⁸ are/is preferably a substituted or unsubstituted arylamino group or a substituted or unsubstituted carbazolyl group. The benzene ring to constitute the arylamino group and the benzene ring to constitute the carbazolyl group each can form a single bond or a linking group together with any of R¹¹ to R¹⁸ or R²¹ to R²⁸. Examples of the substituent that Z² can take include the substituents in the above-mentioned substituent group A. Specific examples of the substituent that R¹¹ to Rib, R²¹ to R²⁸, the arylamino group and the carbazolyl group can take include the substituents in the substituent group A, and a cyano group, a substituted arylamino group and a substituted alkylamino group. R¹¹ and R¹², R¹² and R¹³ R¹³ and R¹⁴ R¹⁵ and, R¹⁶ and R¹⁷, R¹⁷ and R¹⁸, R²¹ and R²², R²² and R²³, R²³ and R²⁴, R²⁵ and R²⁶, R²⁶ and R²⁷, and R²⁷ and R²⁸ each can bond to each other to form a cyclic structure.

Regarding the compound group included in the general formula (9) and specific examples of the compounds, reference can be made to the compounds described in WO2013/081088, paragraphs 0020 to 0062 that is hereby incorporated by reference as a part of the present invention, and in Appl. Phys. Let, 98, 083302 (2011).

Also a compound represented by the following general formula (10) and capable of emitting delayed fluorescence can be especially preferably used as the delayed fluorescent material in the present invention.

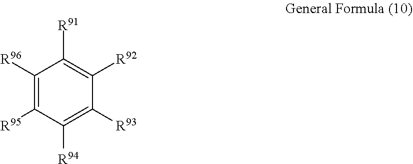

In the general formula (10), R^{9′} to R⁹⁶ each independently represent a hydrogen atom, a deuterium atom, a donor group, or an acceptor group, and at least one of them is a donor group and at least two are acceptor groups. The substitution positions of at least two acceptor groups are not specifically limited, but preferably include two acceptor groups that are in a meta-position relationship. For example, when R^{9′} is a donor group, preferred examples include a structure where at least R⁹² and R⁹⁴ are acceptor groups, or a structure where at least R⁹² and R⁹⁶ are acceptor groups. The acceptor groups existing in the molecule can be all the same as or different from each other, but a structure where all have the same structure can be selected. The number of the acceptor groups is preferably 2 to 3, and for example, 2 can be selected.

Two or more donor groups can exist in the molecule, and in that case, all the donor groups can be the same as or different from each other. The number of the donor groups is preferably 1 to 3, and for example, it can be one only or can be two. Regarding the description and the preferred range of the donor group and the acceptor group, reference can be made to the description and the preferred range of D and Z in the general formula (1). In particular, the donor group in the general formula (10) is preferably represented by the general formula (3), and the acceptor group is preferably a cyano group or is represented by the following general formula (11).

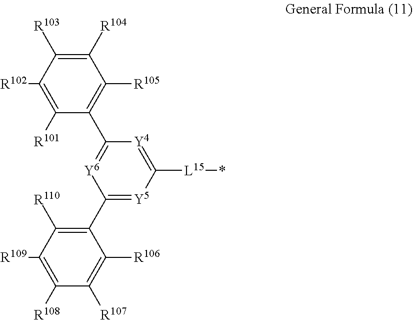

In the general formula (11), Y⁴ to Y⁶ each represent a nitrogen atom or a methine group, and at least one is a nitrogen atom, and preferably all are nitrogen atoms. R¹⁰¹ to R¹¹⁰ each independently represent a hydrogen atom, a deuterium atom or a substituent, and at least one is preferably an alkyl group. Regarding the description and the preferred range of the substituent as referred to herein, reference can be made to the description and the preferred range of the substituent in the general formula (7) mentioned hereinabove. L¹⁵ represents a single bond or a linking group, for which reference can be made to the description and the preferred range of L in the general formula (3) mentioned hereinabove. In one preferred embodiment of the present invention, L¹⁵ in the general formula (11) is a single bond. * indicates a bonding position to the carbon atom (C) that constitutes the ring skeleton of the ring in the general formula (10).

In another preferred embodiment of the present invention, a compound represented by the general formula (12) can be employed as the second organic compound. The compound represented by the general formula (12) includes the compound represented by the general formula (12a).

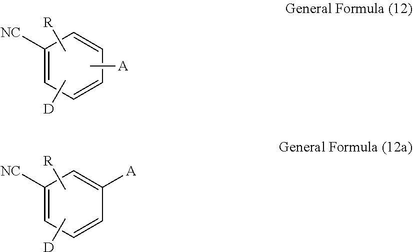

Among the compounds represented by the general formula (12), especially preferred are the compound represented by the following general formula (13) and the compound represented by the following general formula (14).

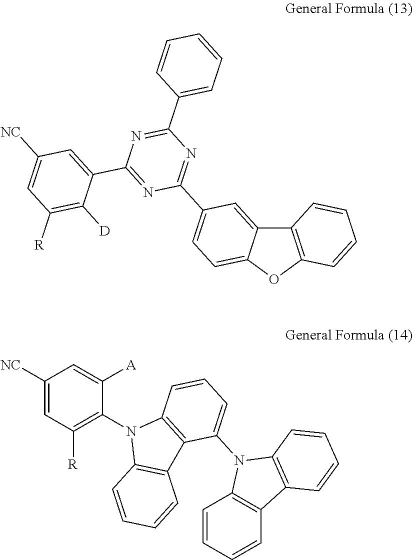

In the general formulae (12) to (14), D represents a donor group, A represents an acceptor group, R represents a hydrogen atom, a deuterium atom or a substituent. Regarding the description and the preferred range of the donor group and the acceptor group, reference can be made to the corresponding description and the preferred range of the general formula (1) mentioned above. Examples of the substituent of R include an alkyl group, and an aryl group optionally substituted with one group or a combination of two or more selected from the group consisting of an alkyl group and an aryl group.

Preferred specific examples of the donor group of D in the general formulae (12) to (14) are shown below. In the following specific examples, * indicates a bonding position, and “D” represents a deuterium atom. In the following specific examples, the hydrogen atom can be substituted with, for example, an alkyl group. In addition, a substituted or unsubstituted benzene ring can be further condensed.

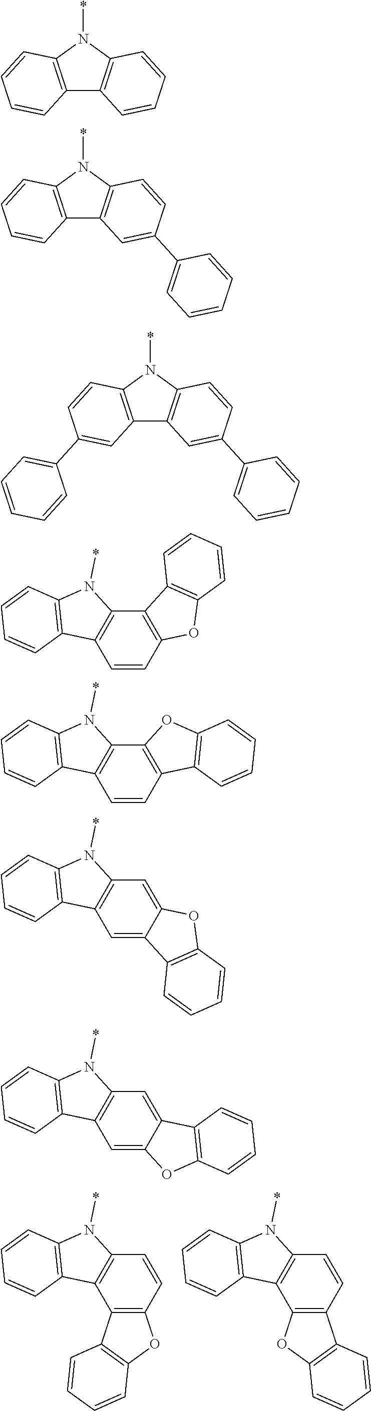

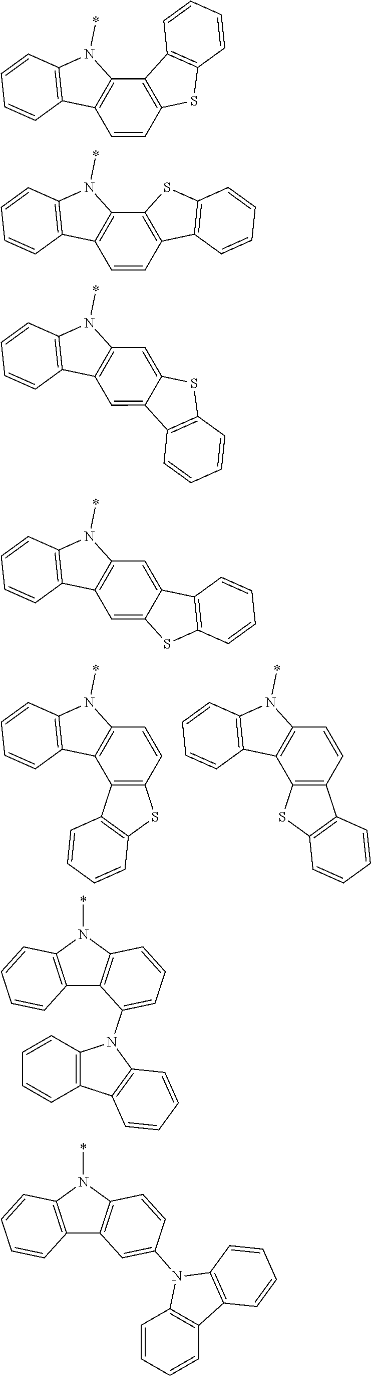

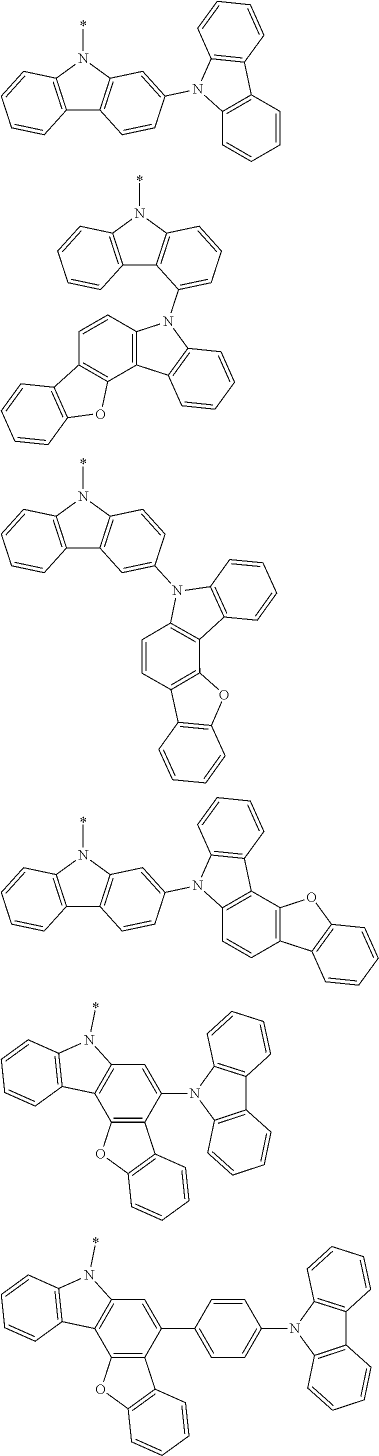

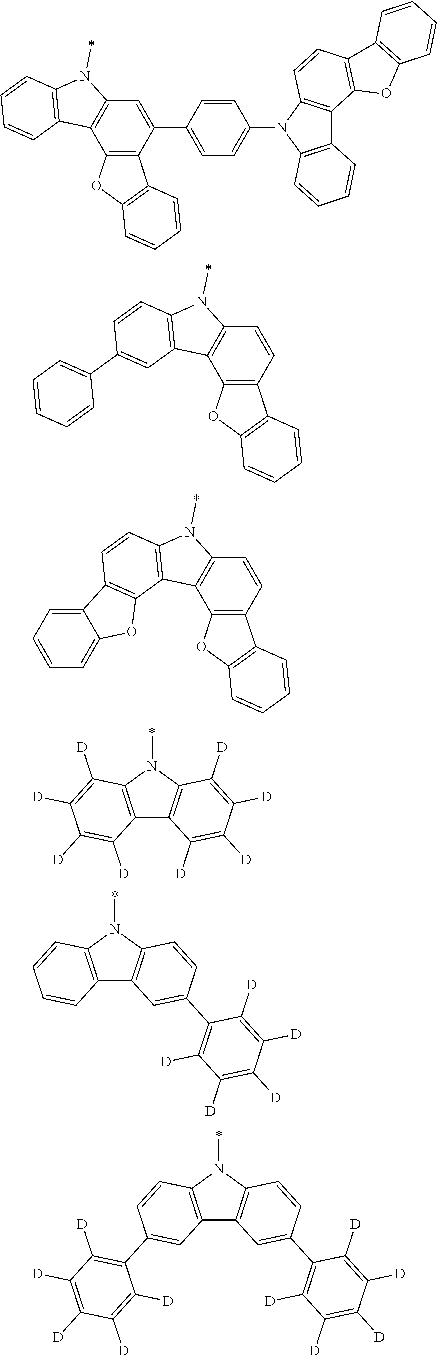

Preferred specific examples of the acceptor group of A in the general formulae (12) to (14) are shown below. In the following examples, * indicates a bonding position, and “D” represents a deuterium atom.

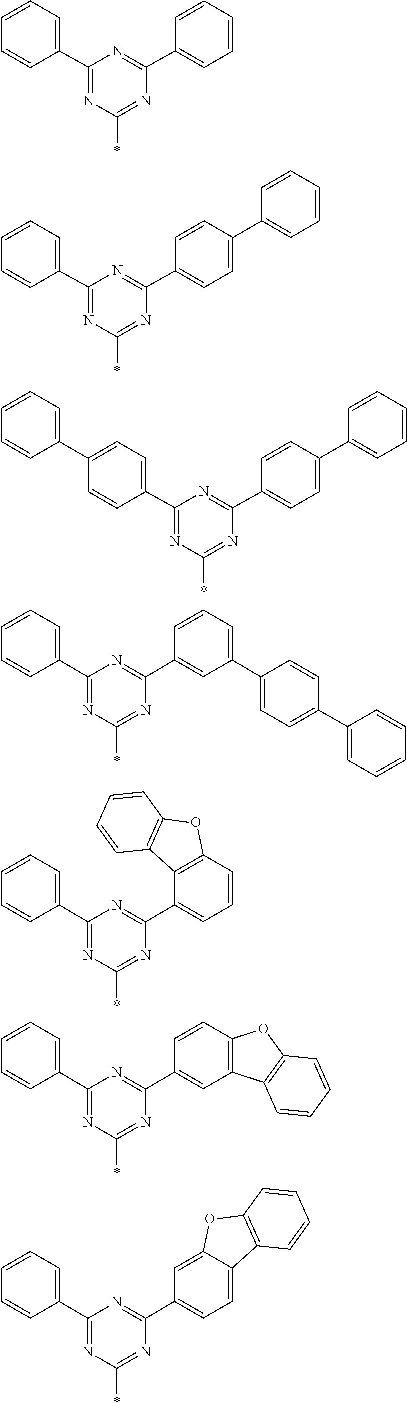

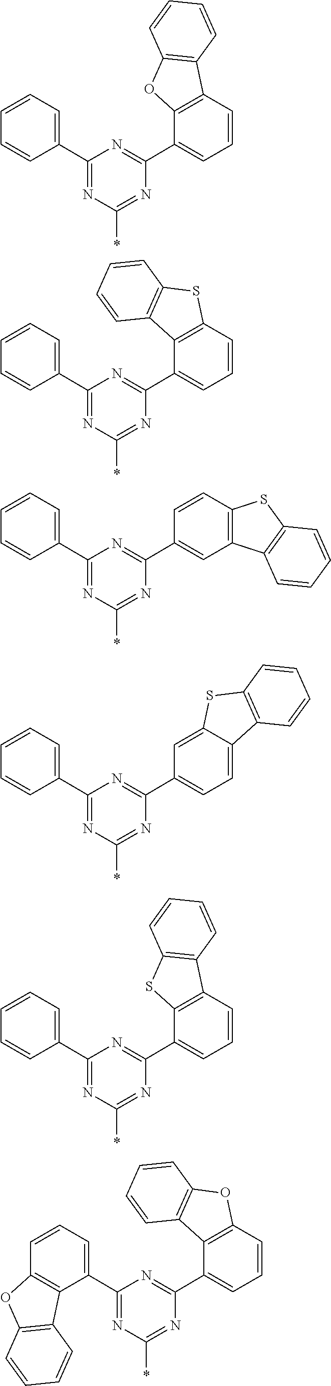

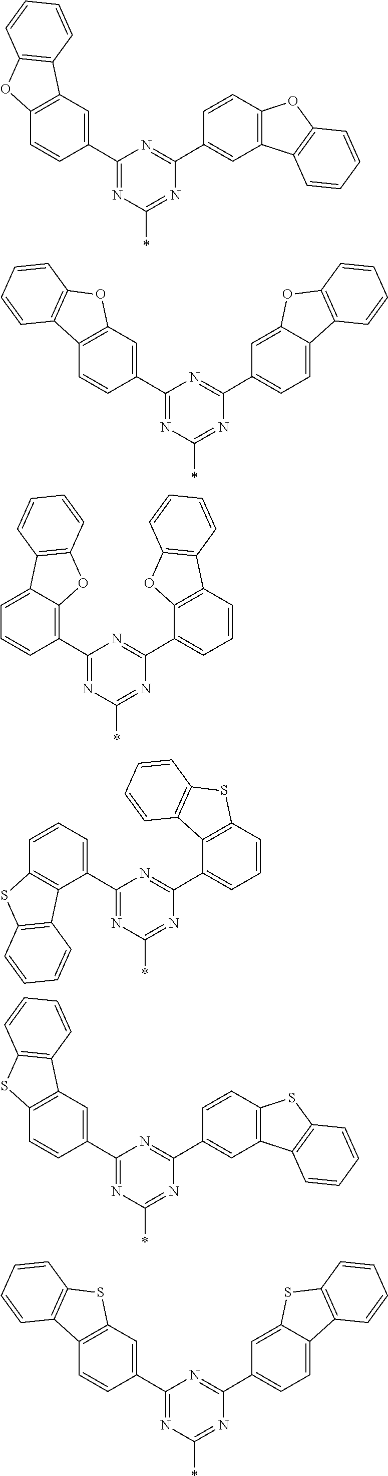

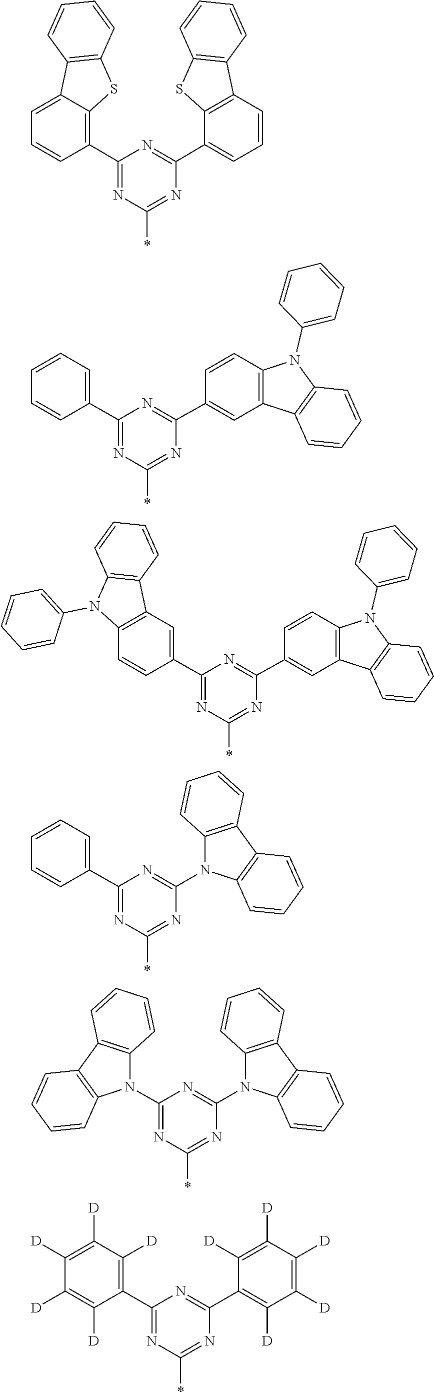

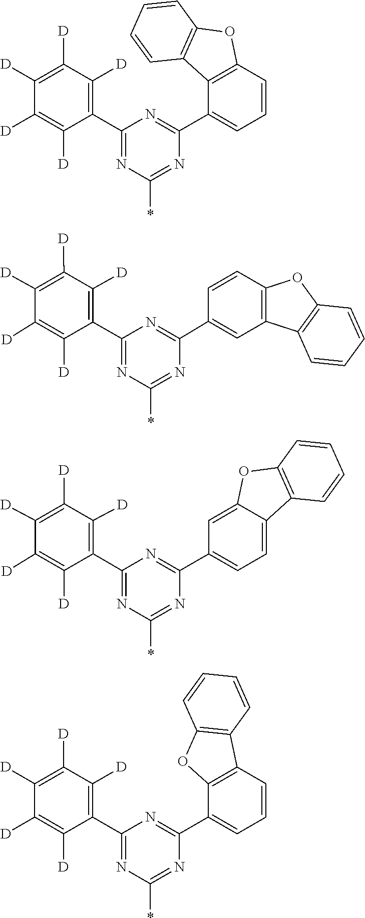

Preferred examples of R in the general formulae (12) to (14) are shown below. In the following specific examples, * indicates a bonding position, and “D” represents a deuterium atom.

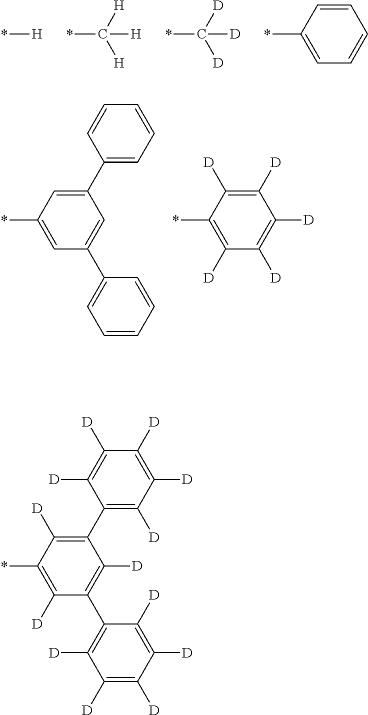

Preferred compounds usable as the second organic compound are shown below. In the structural formulae of the following exemplary compounds, t-Bu represents a tertiary butyl group. Expression of CH₃ for a methyl group is omitted. Therefore, for example, T157 has a structure where two methyl groups bond to the central benzene ring.

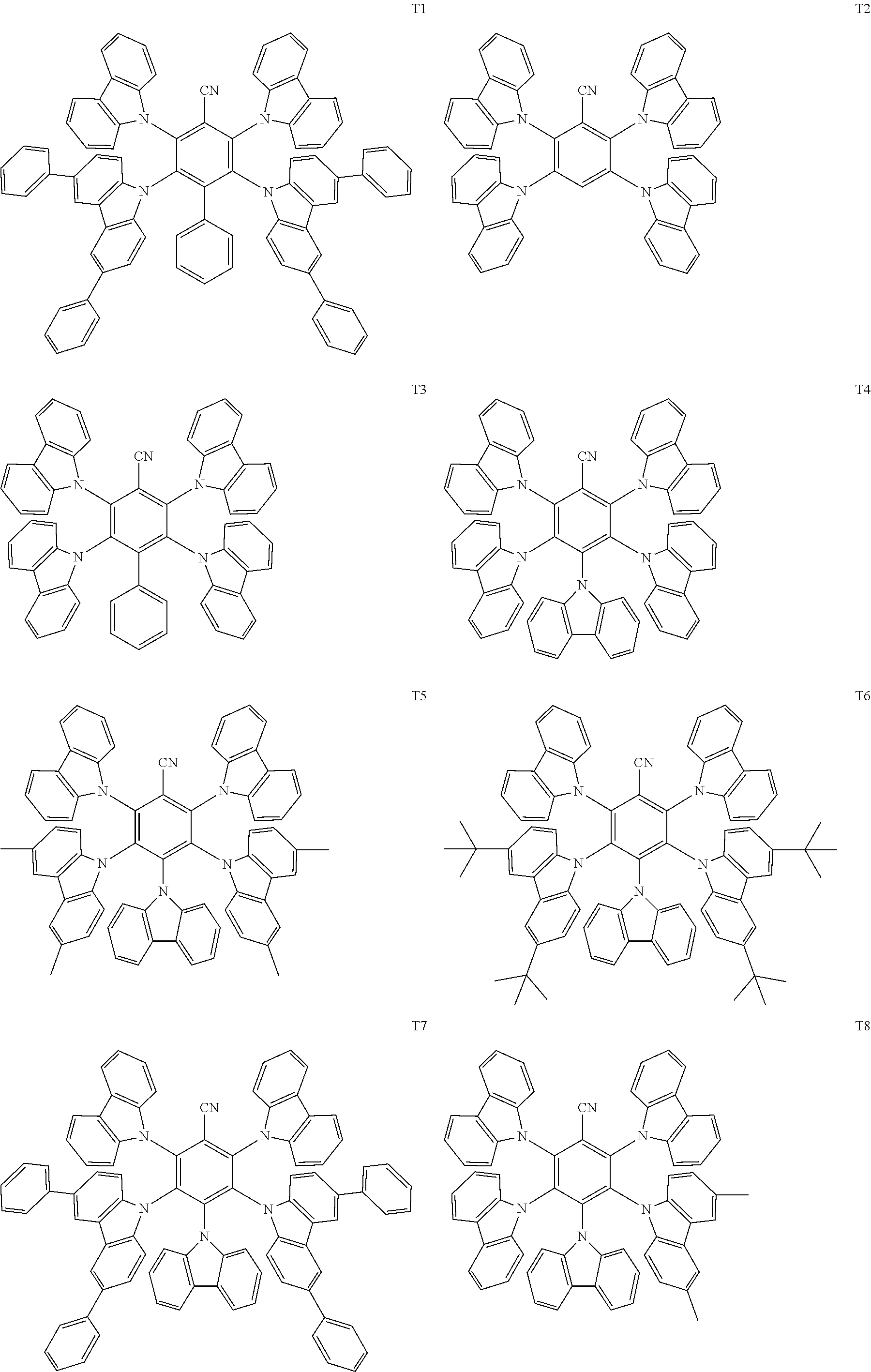

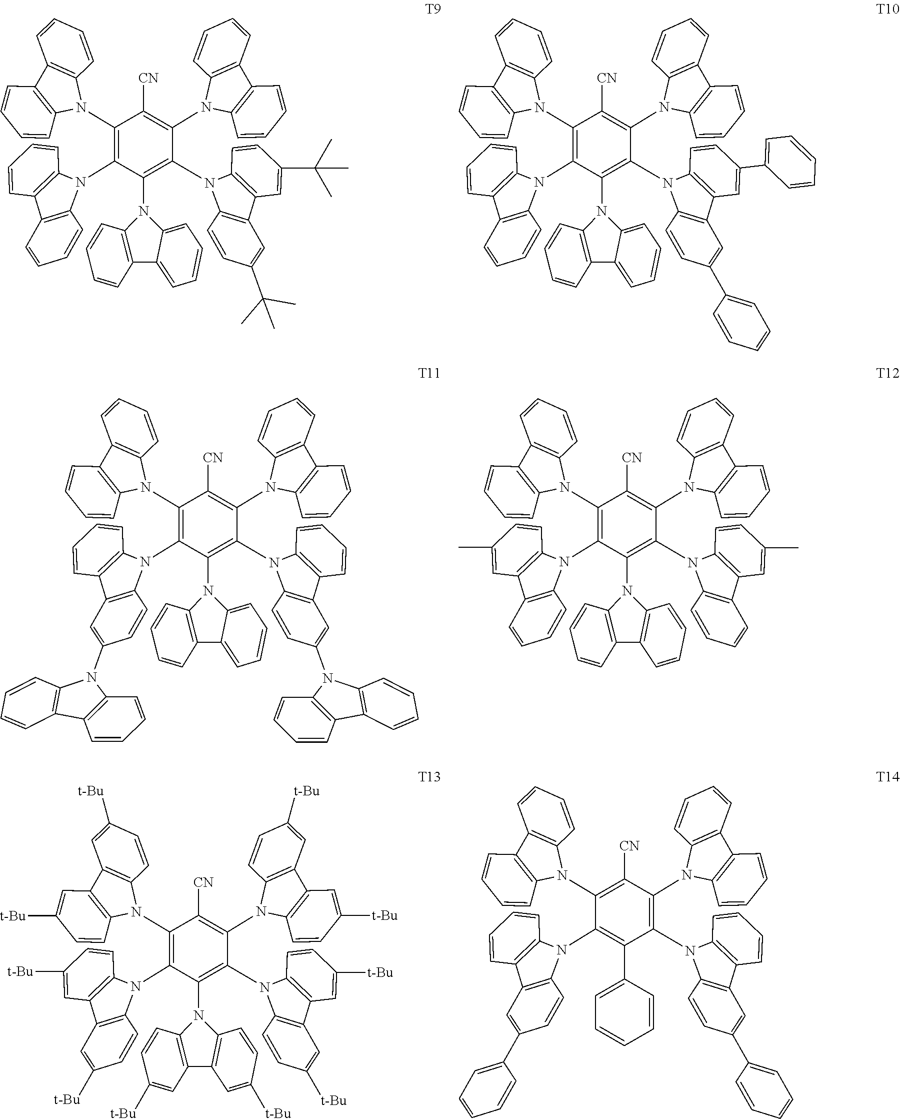

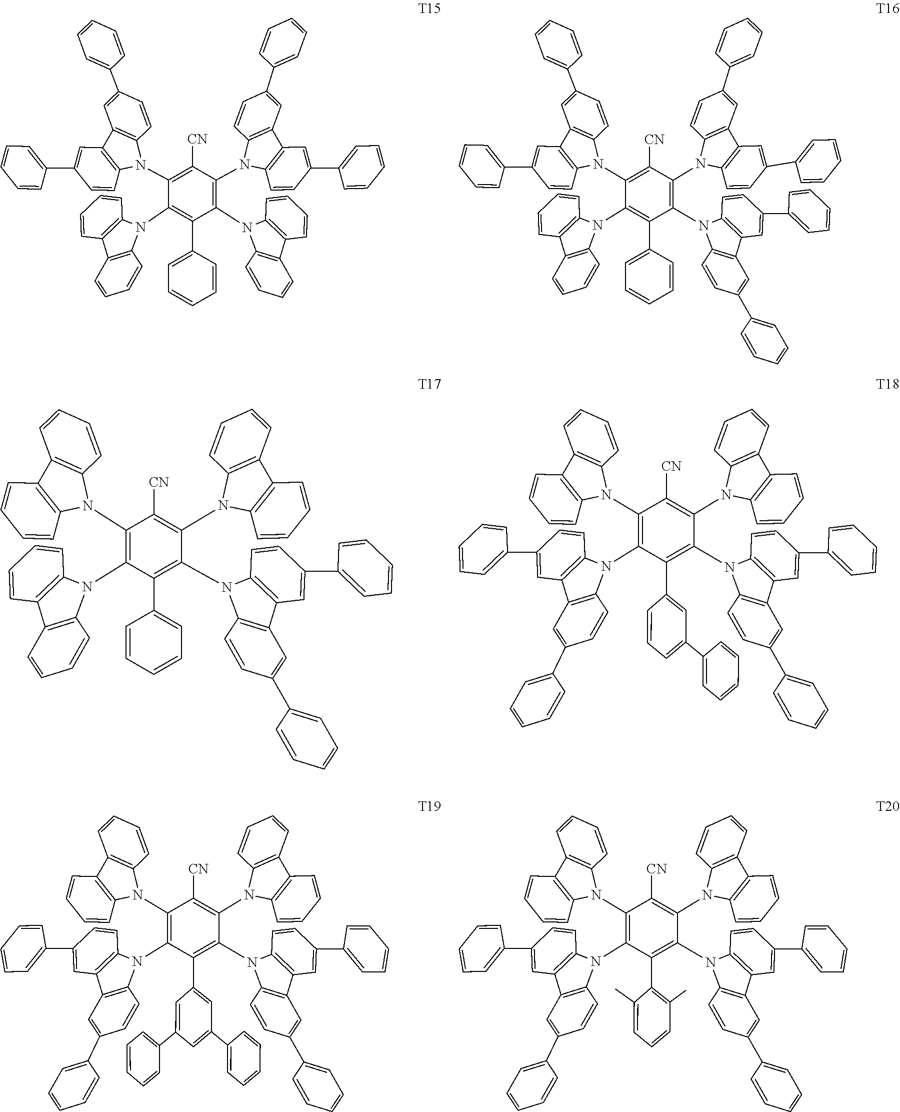

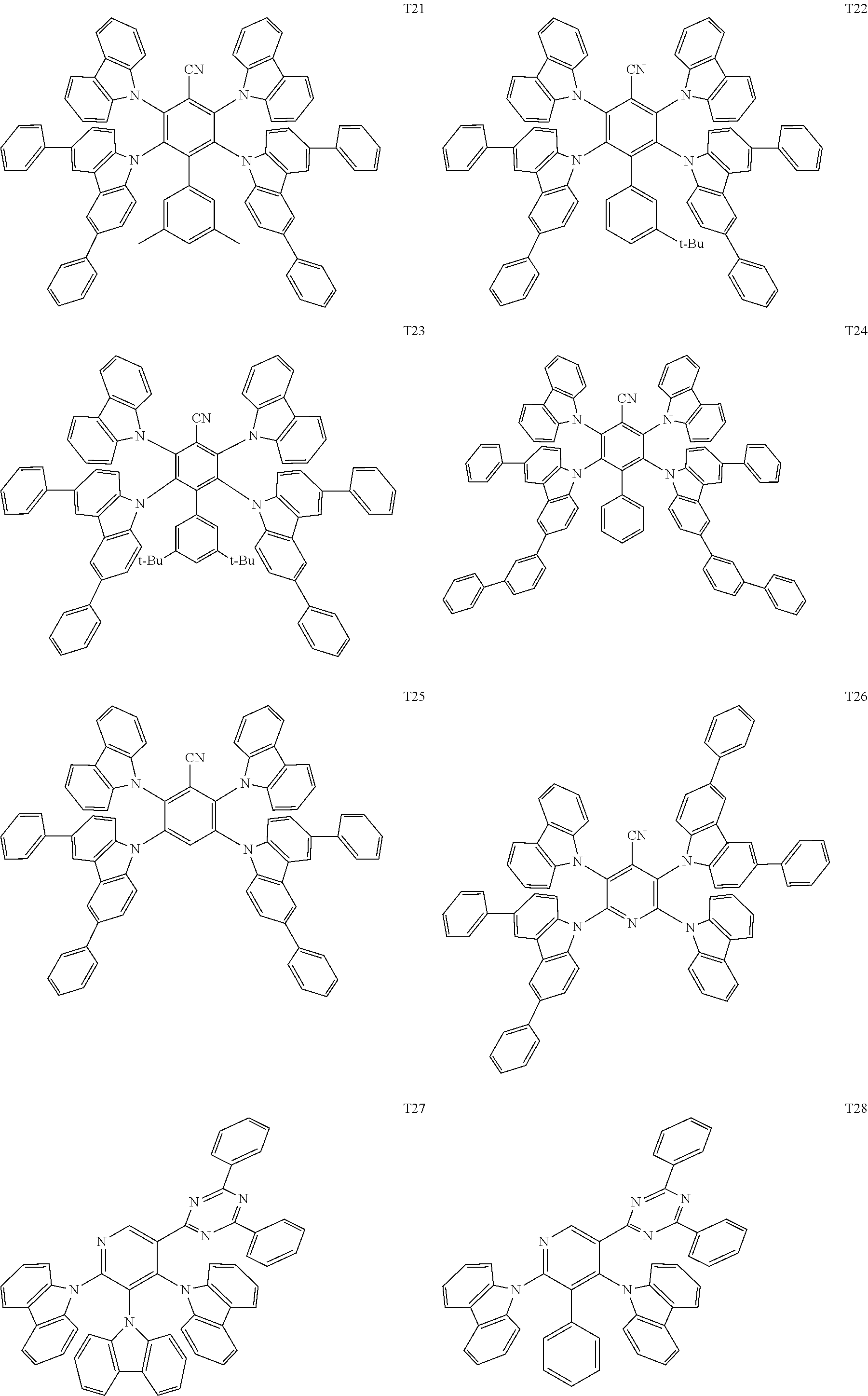

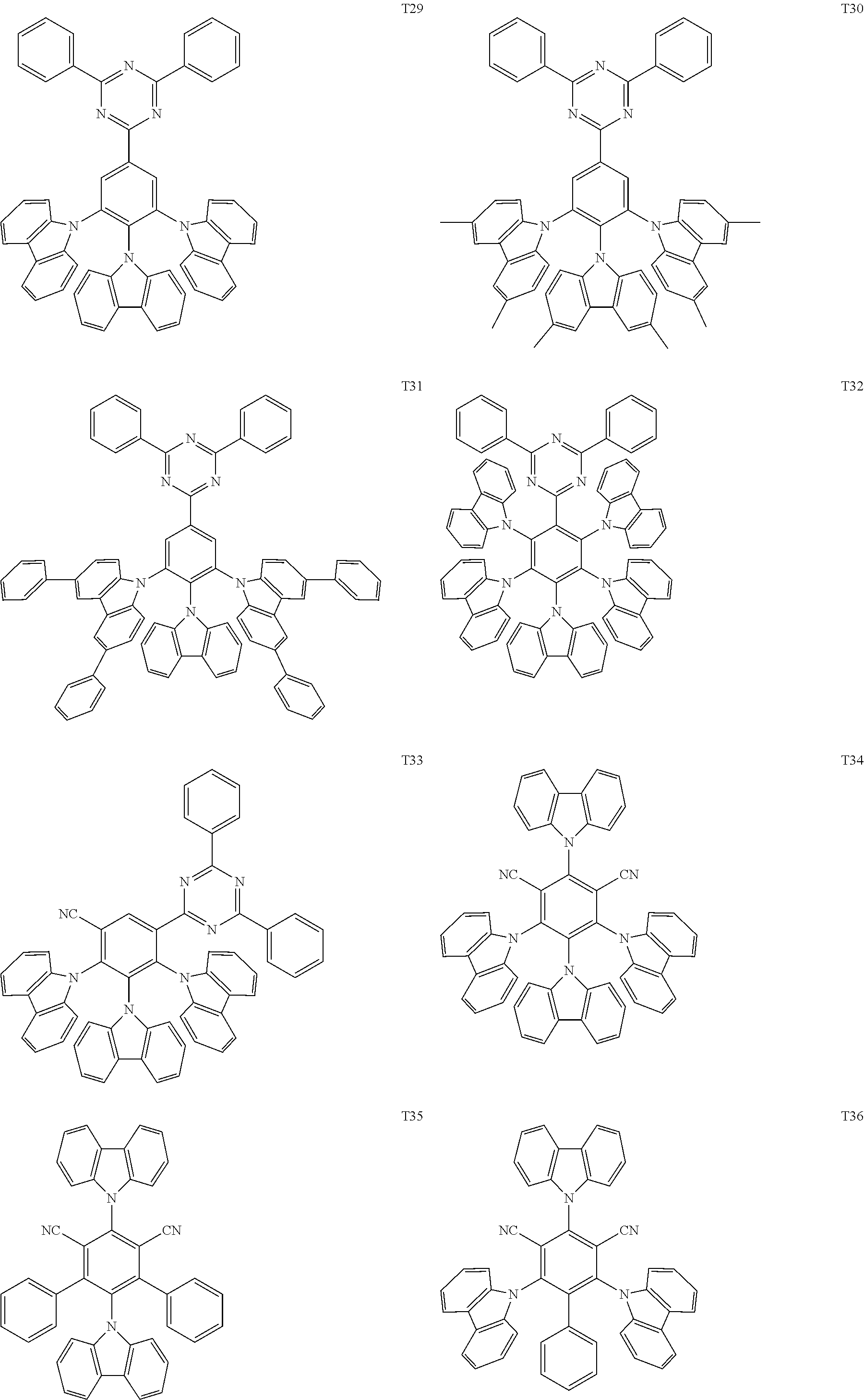

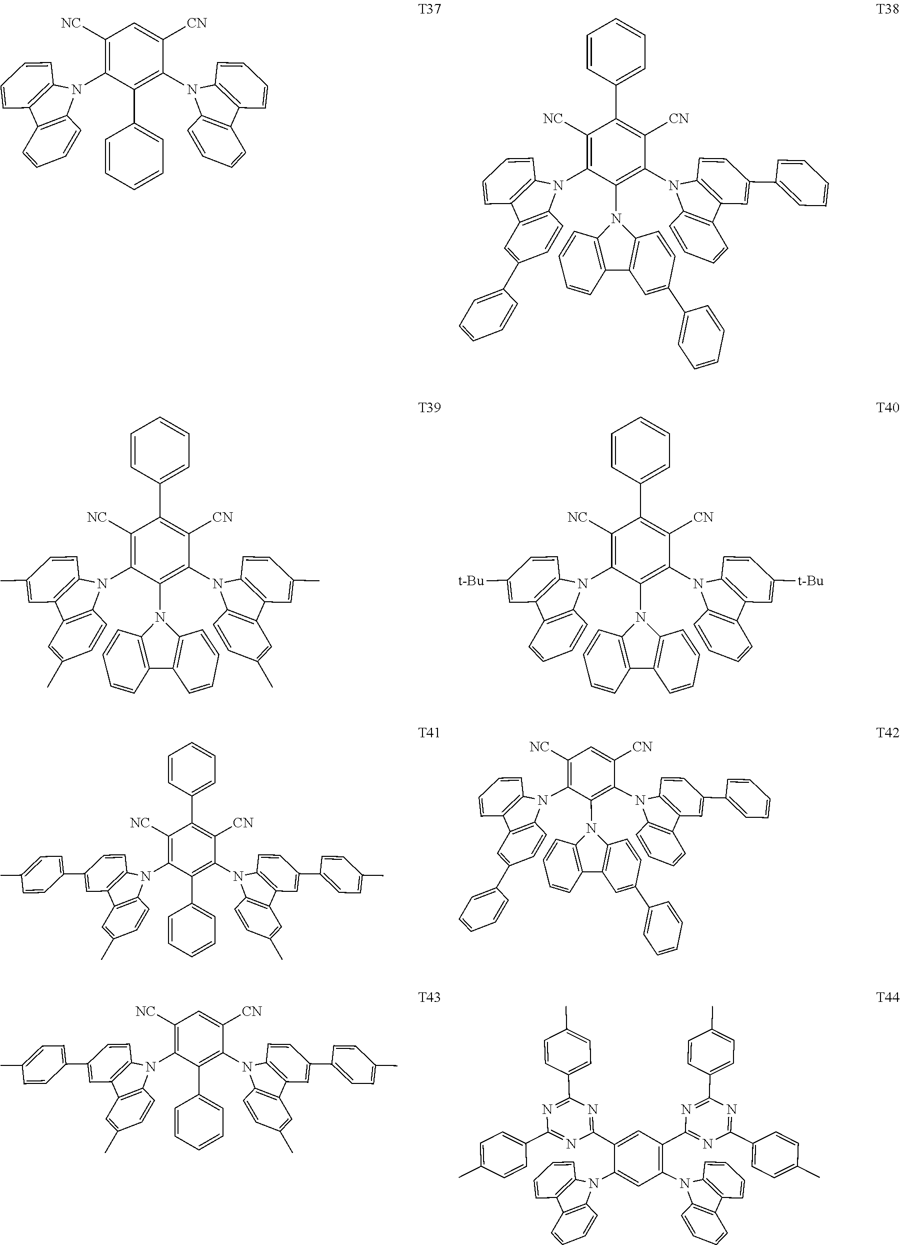

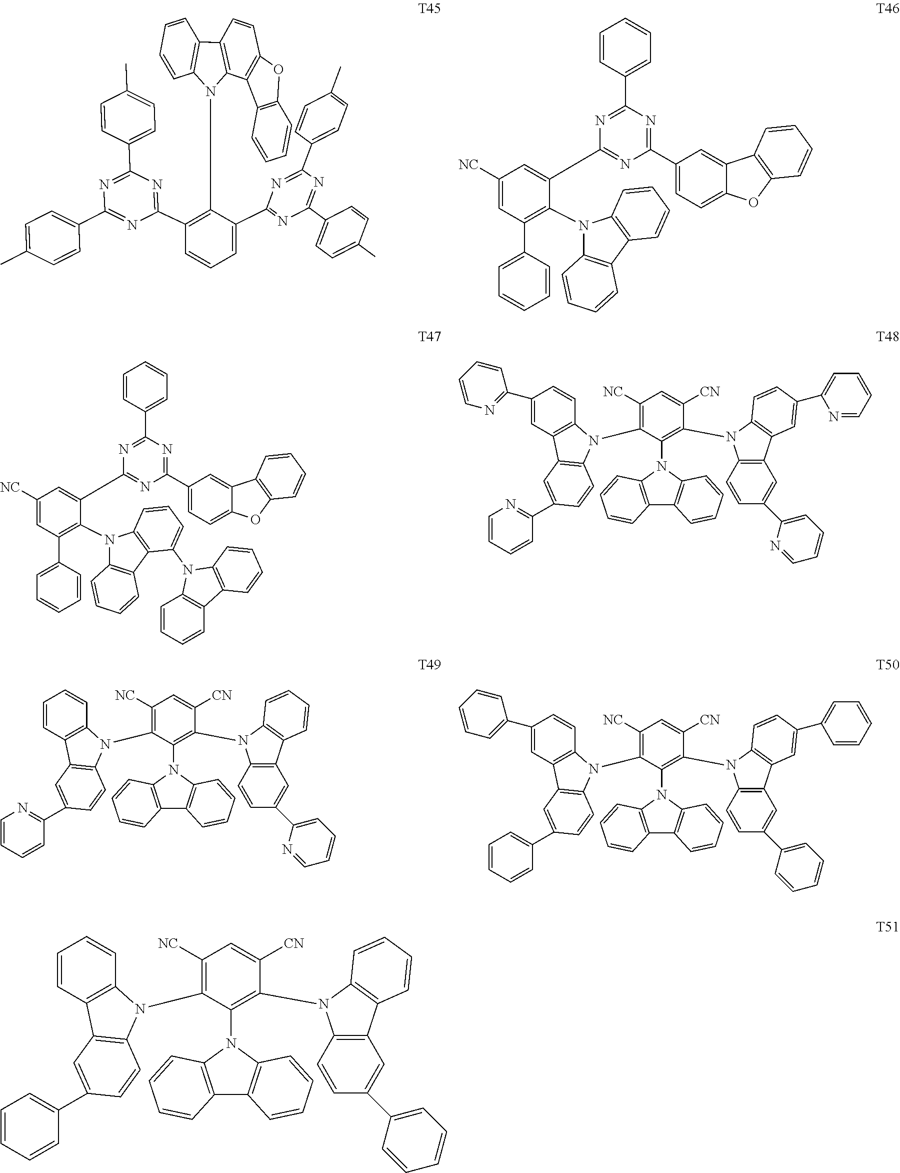

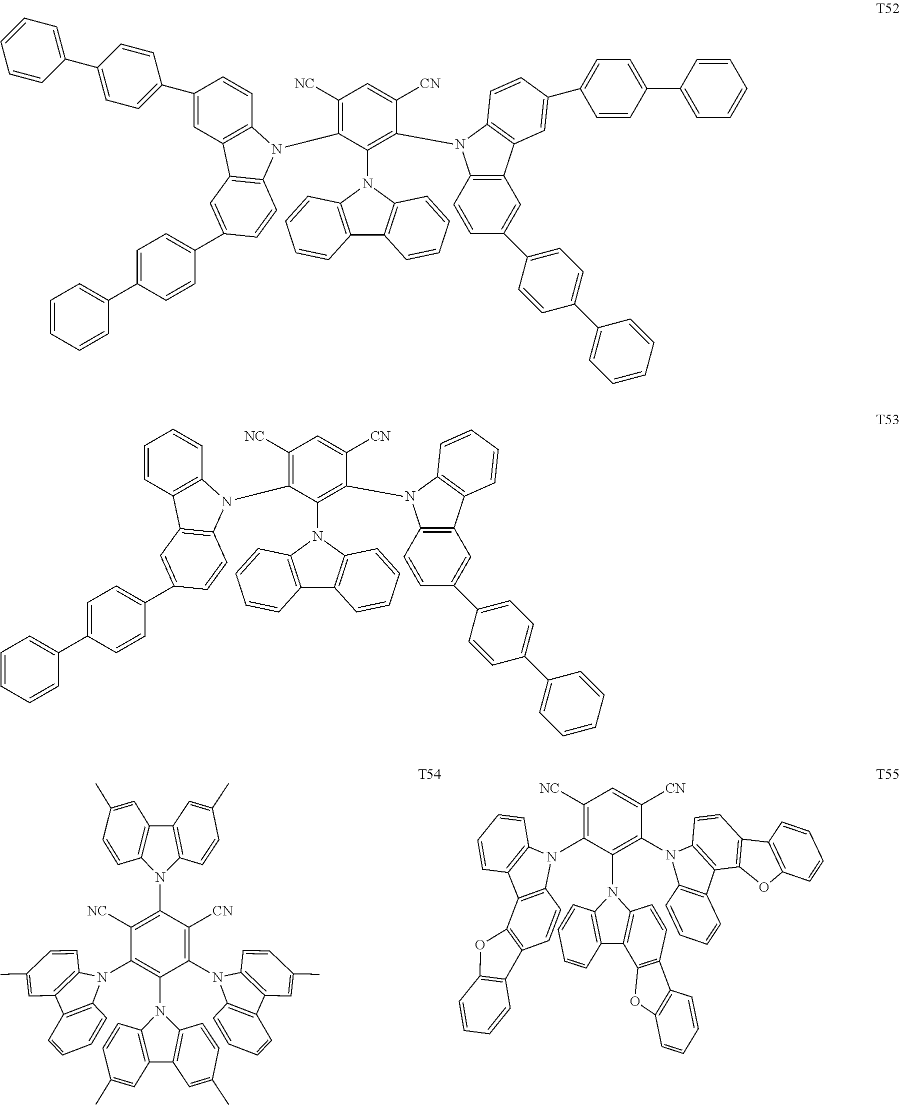

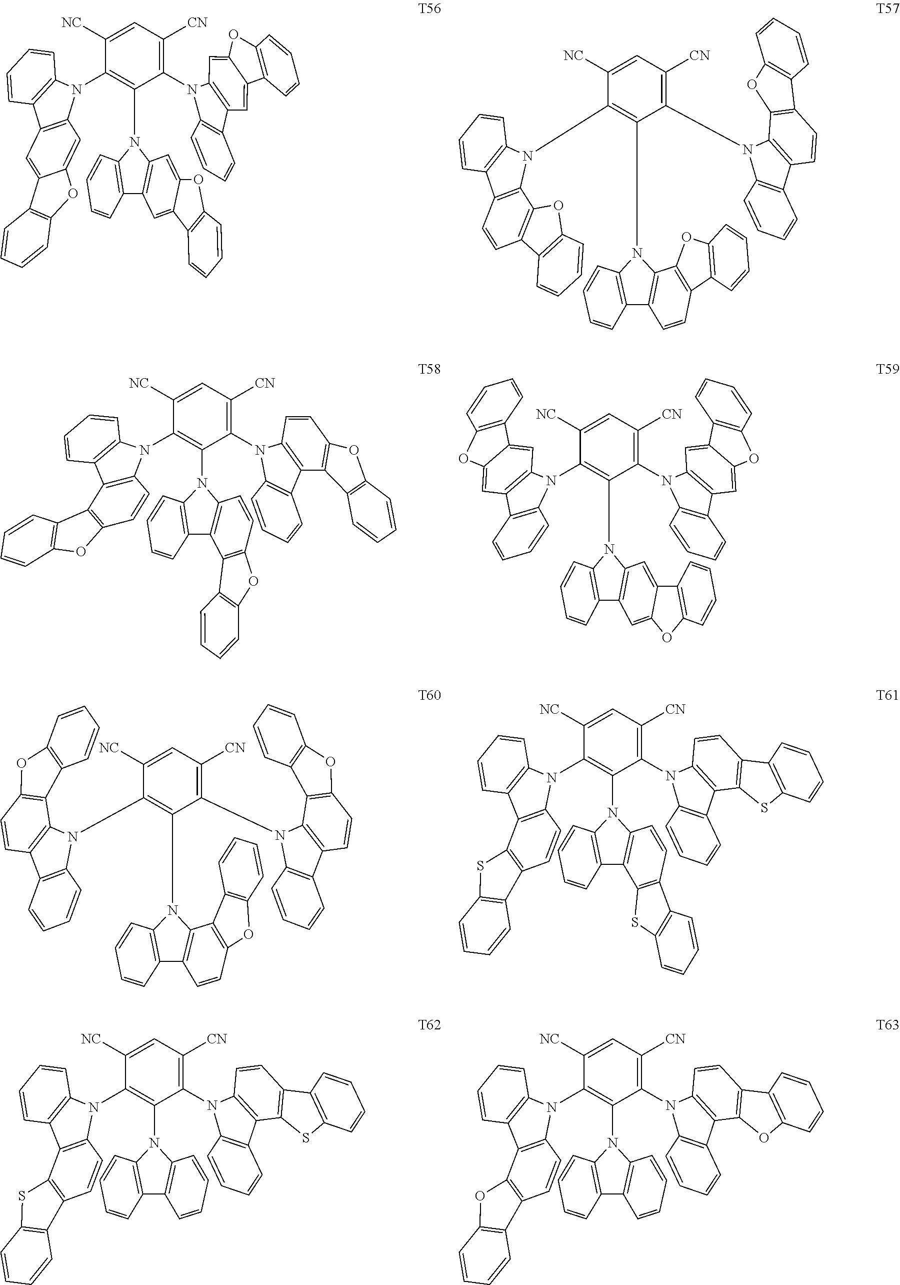

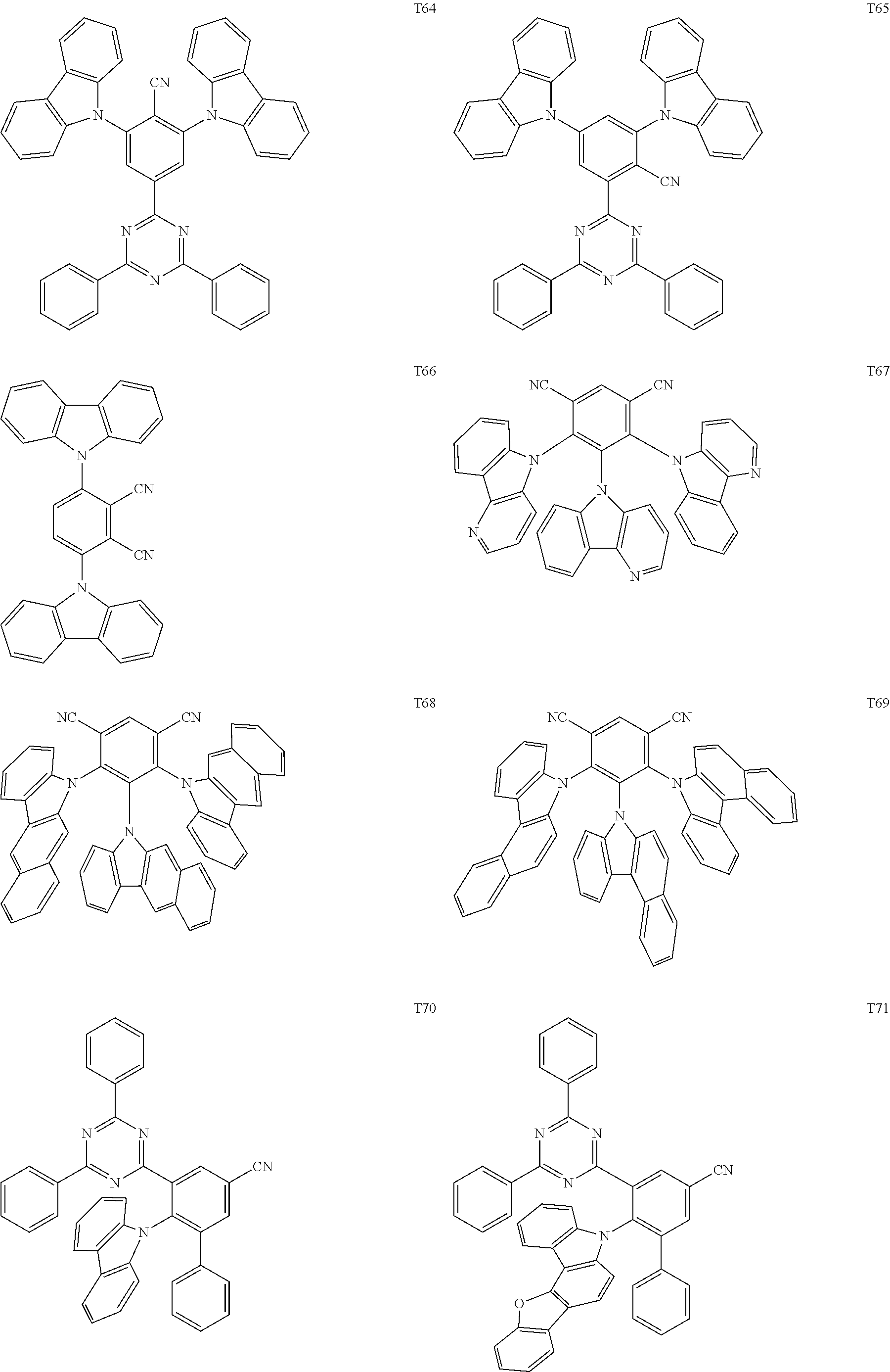

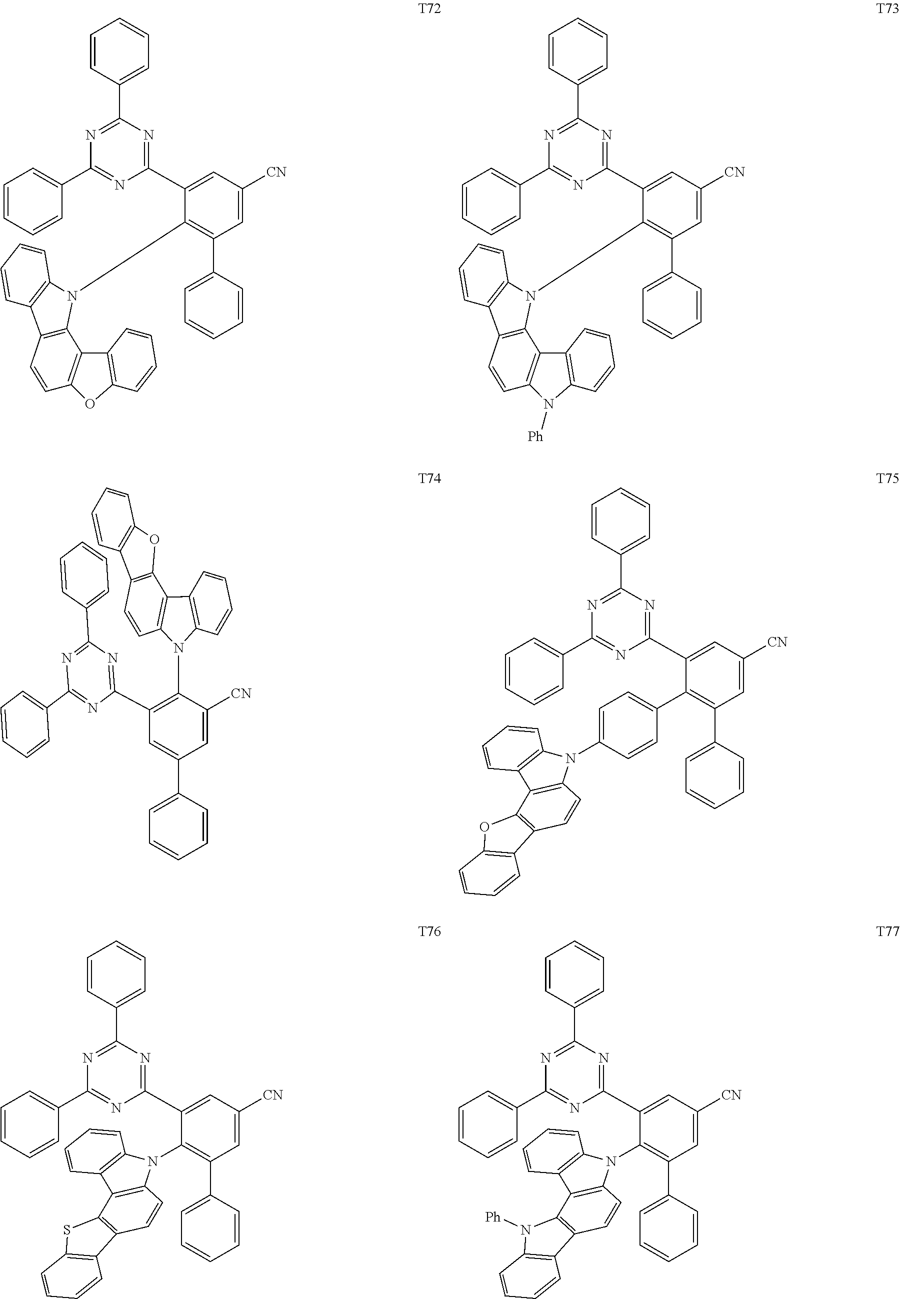

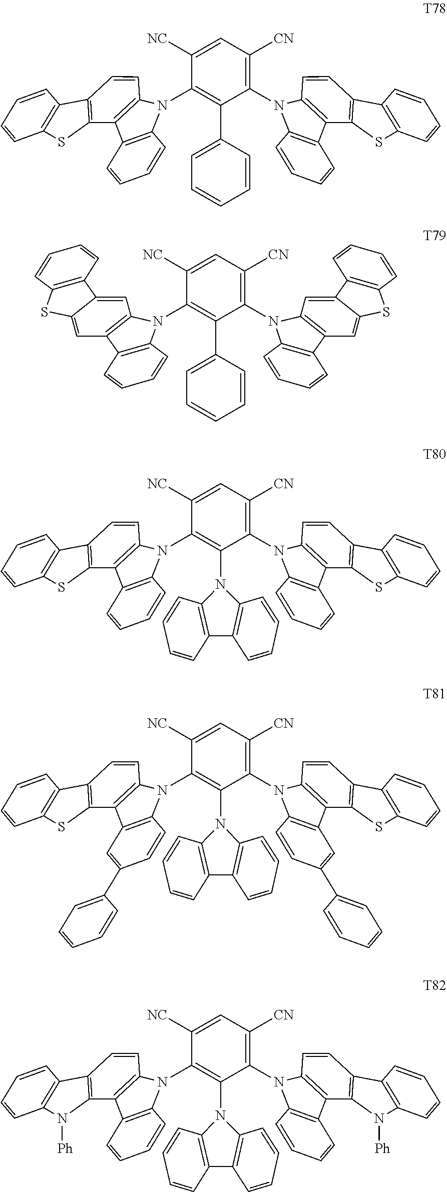

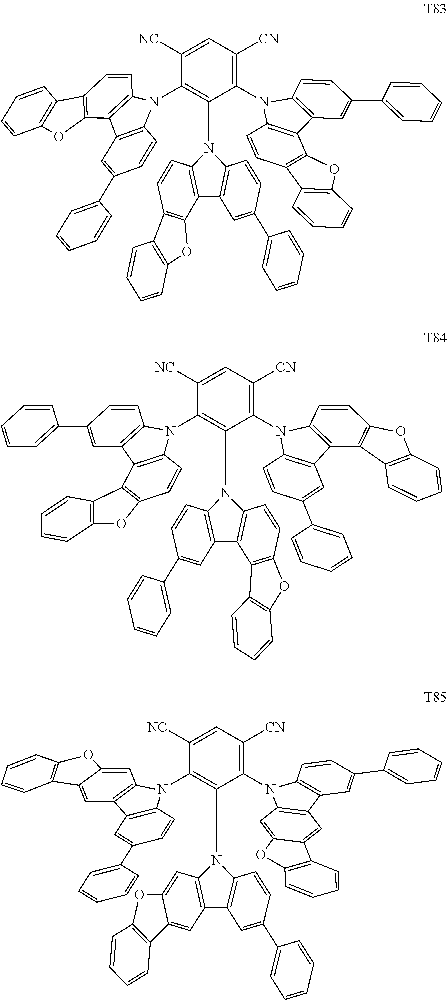 [SMILES: N#Cc1cc(C#N)c(-n2c3ccc(-c4ccccc4)cc3c3c4oc5ccccc5c4ccc32)c(-n2c3ccc(-c4ccccc4)cc3c3c4oc5ccccc5c4ccc32)c1-n1c2ccc(-c3ccccc3)cc2c2c3oc4ccccc4c3ccc21 ; N#Cc1cc(C#N)c(-n2c3ccc(-c4ccccc4)cc3c3c4c(ccc32)oc2ccccc24)c(-n2c3ccc(-c4ccccc4)cc3c3c4c(ccc32)oc2ccccc24)c1-n1c2ccc(-c3ccccc3)cc2c2c3c(ccc21)oc1ccccc13 ; N#Cc1cc(C#N)c(-n2c3ccc(-c4ccccc4)cc3c3cc4c(cc32)oc2ccccc24)c(-n2c3ccc(-c4ccccc4)cc3c3cc4c(cc32)oc2ccccc24)c1-n1c2ccc(-c3ccccc3)cc2c2cc3c(cc21)oc1ccccc13]

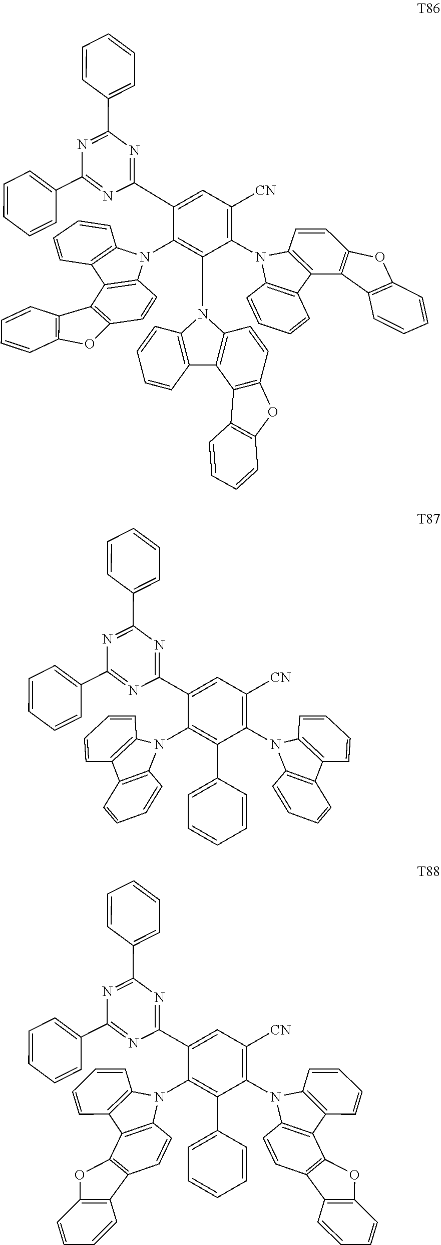

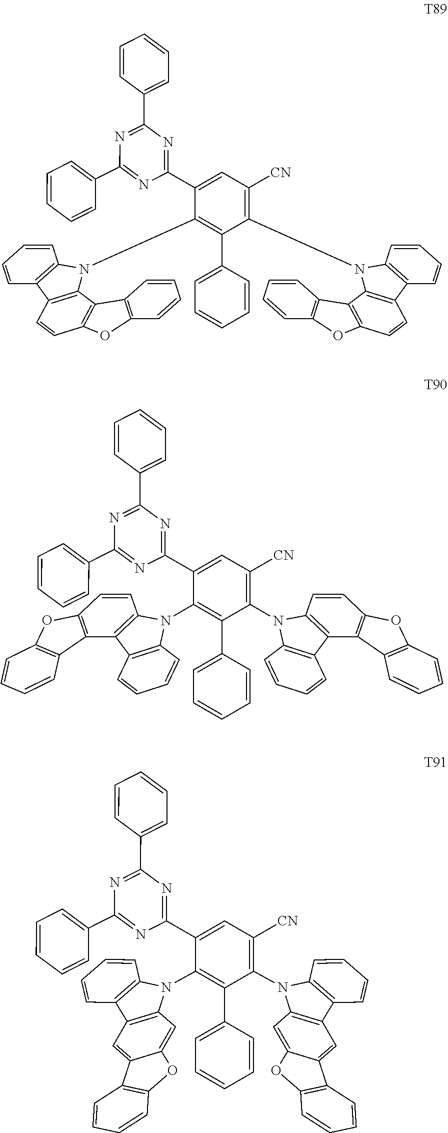 [SMILES: N#Cc1cc(-c2nc(-c3ccccc3)nc(-c3ccccc3)n2)c(-n2c3ccccc3c3ccc4oc5ccccc5c4c32)c(-c2ccccc2)c1-n1c2ccccc2c2ccc3oc4ccccc4c3c21 ; N#Cc1cc(-c2nc(-c3ccccc3)nc(-c3ccccc3)n2)c(-n2c3ccccc3c3c4c(ccc32)oc2ccccc24)c(-c2ccccc2)c1-n1c2ccccc2c2c3c(ccc21)oc1ccccc13 ; N#Cc1cc(-c2nc(-c3ccccc3)nc(-c3ccccc3)n2)c(-n2c3ccccc3c3cc4c(cc32)oc2ccccc24)c(-c2ccccc2)c1-n1c2ccccc2c2cc3c(cc21)oc1ccccc13]

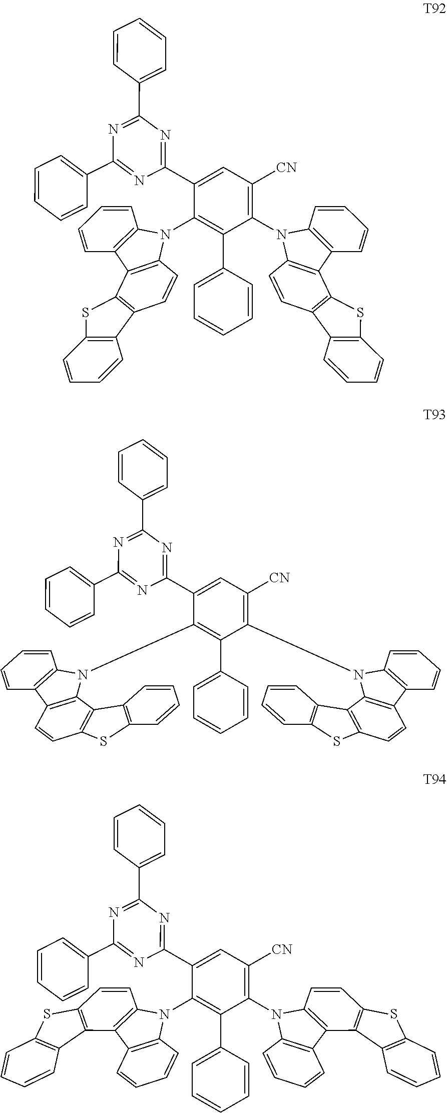

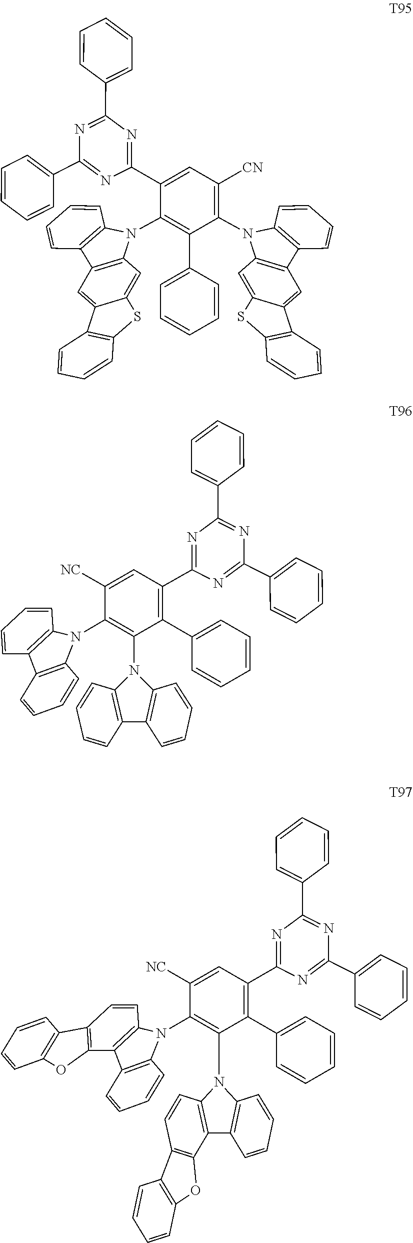 [SMILES: N#Cc1cc(-c2nc(-c3ccccc3)nc(-c3ccccc3)n2)c(-n2c3ccccc3c3cc4c(cc32)sc2ccccc24)c(-c2ccccc2)c1-n1c2ccccc2c2cc3c(cc21)sc1ccccc13 ; N#Cc1cc(-c2nc(-c3ccccc3)nc(-c3ccccc3)n2)c(-c2ccccc2)c(-n2c3ccccc3c3ccccc32)c1-n1c2ccccc2c2ccccc21 ; N#Cc1cc(-c2nc(-c3ccccc3)nc(-c3ccccc3)n2)c(-c2ccccc2)c(-n2c3ccccc3c3c4oc5ccccc5c4ccc32)c1-n1c2ccccc2c2c3oc4ccccc4c3ccc21]

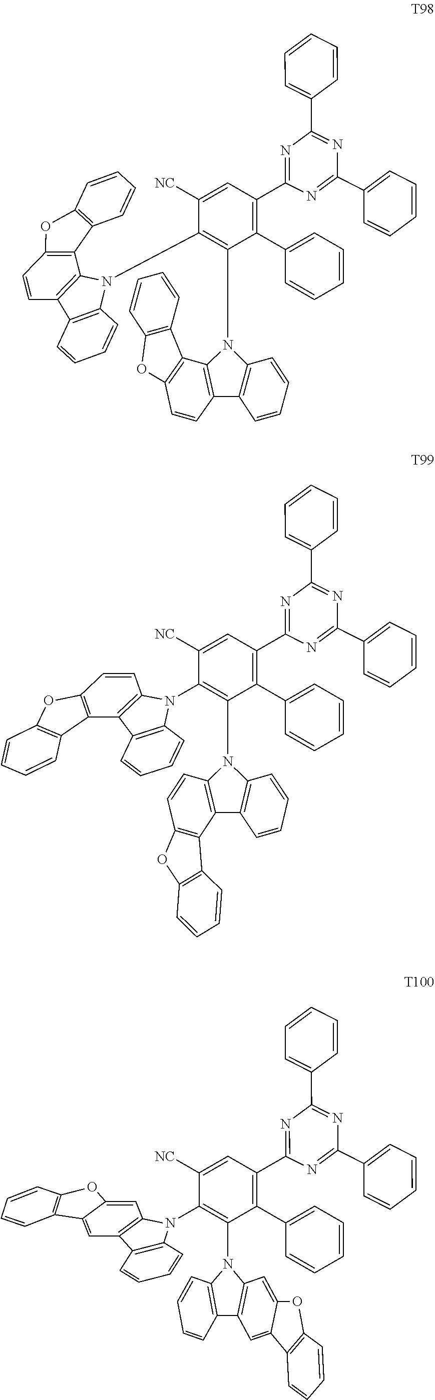 [SMILES: N#Cc1cc(-c2nc(-c3ccccc3)nc(-c3ccccc3)n2)c(-c2ccccc2)c(-n2c3ccccc3c3ccc4oc5ccccc5c4c32)c1-n1c2ccccc2c2ccc3oc4ccccc4c3c21 ; N#Cc1cc(-c2nc(-c3ccccc3)nc(-c3ccccc3)n2)c(-c2ccccc2)c(-n2c3ccccc3c3c4c(ccc32)oc2ccccc24)c1-n1c2ccccc2c2c3c(ccc21)oc1ccccc13 ; N#Cc1cc(-c2nc(-c3ccccc3)nc(-c3ccccc3)n2)c(-c2ccccc2)c(-n2c3ccccc3c3cc4c(cc32)oc2ccccc24)c1-n1c2ccccc2c2cc3c(cc21)oc1ccccc13]

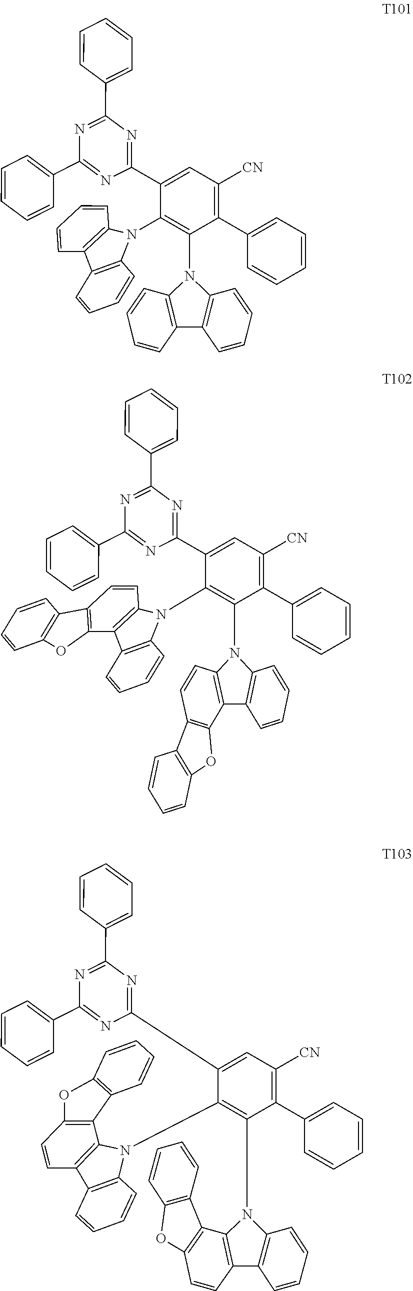

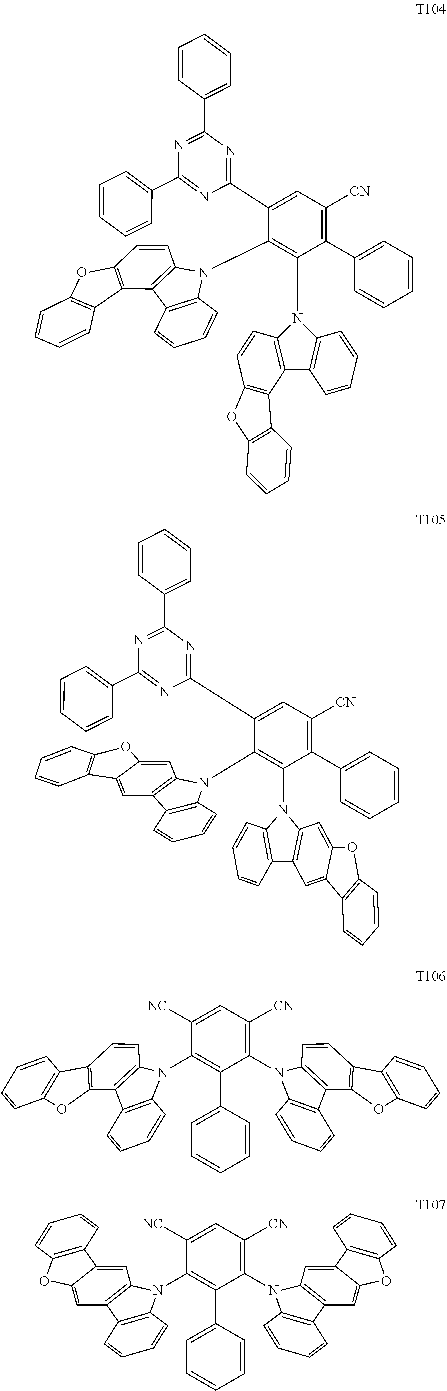 [SMILES: N#Cc1cc(-c2nc(-c3ccccc3)nc(-c3ccccc3)n2)c(-n2c3ccccc3c3c4c(ccc32)oc2ccccc24)c(-n2c3ccccc3c3c4c(ccc32)oc2ccccc24)c1-c1ccccc1 ; N#Cc1cc(-c2nc(-c3ccccc3)nc(-c3ccccc3)n2)c(-n2c3ccccc3c3cc4c(cc32)oc2ccccc24)c(-n2c3ccccc3c3cc4c(cc32)oc2ccccc24)c1-c1ccccc1 ; N#Cc1cc(C#N)c(-n2c3ccccc3c3c4oc5ccccc5c4ccc32)c(-c2ccccc2)c1-n1c2ccccc2c2c3oc4ccccc4c3ccc21 ; N#Cc1cc(C#N)c(-n2c3ccccc3c3cc4oc5ccccc5c4cc32)c(-c2ccccc2)c1-n1c2ccccc2c2cc3oc4ccccc4c3cc21]

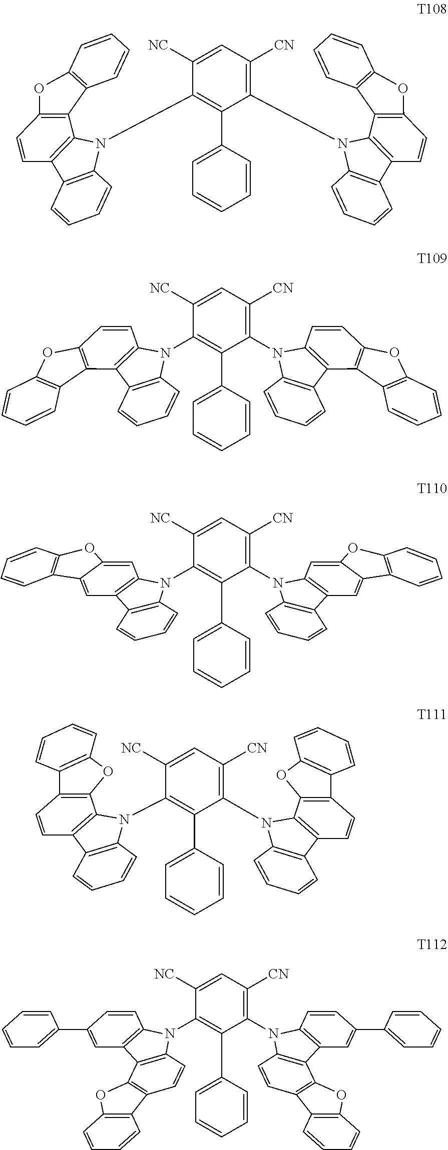 [SMILES: N#Cc1cc(C#N)c(-n2c3ccccc3c3ccc4oc5ccccc5c4c32)c(-c2ccccc2)c1-n1c2ccccc2c2ccc3oc4ccccc4c3c21 ; N#Cc1cc(C#N)c(-n2c3ccccc3c3c4c(ccc32)oc2ccccc24)c(-c2ccccc2)c1-n1c2ccccc2c2c3c(ccc21)oc1ccccc13 ; N#Cc1cc(C#N)c(-n2c3ccccc3c3cc4c(cc32)oc2ccccc24)c(-c2ccccc2)c1-n1c2ccccc2c2cc3c(cc21)oc1ccccc13 ; N#Cc1cc(C#N)c(-n2c3ccccc3c3ccc4c5ccccc5oc4c32)c(-c2ccccc2)c1-n1c2ccccc2c2ccc3c4ccccc4oc3c21 ; N#Cc1cc(C#N)c(-n2c3ccc(-c4ccccc4)cc3c3c4oc5ccccc5c4ccc32)c(-c2ccccc2)c1-n1c2ccc(-c3ccccc3)cc2c2c3oc4ccccc4c3ccc21]

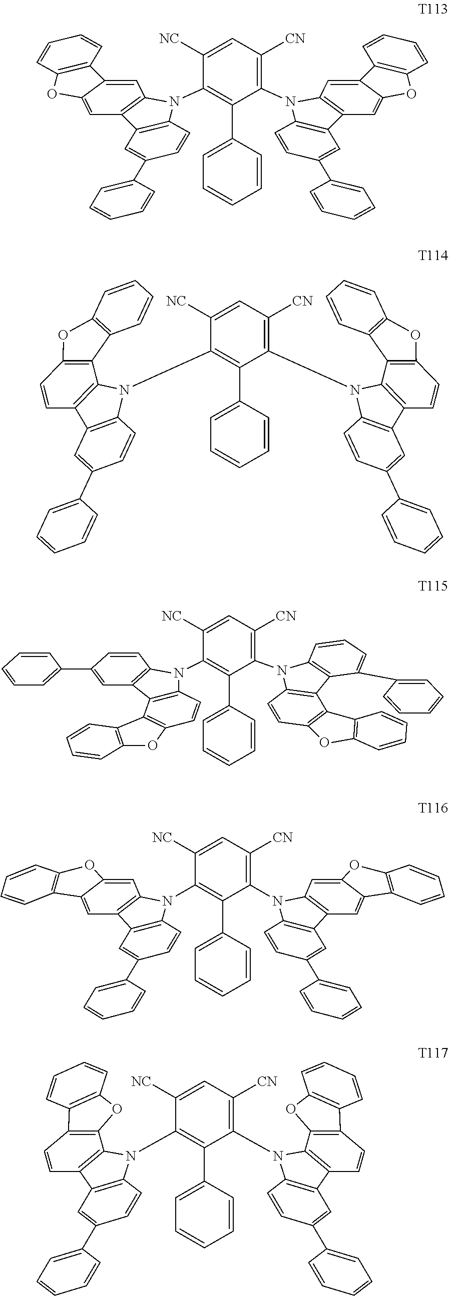

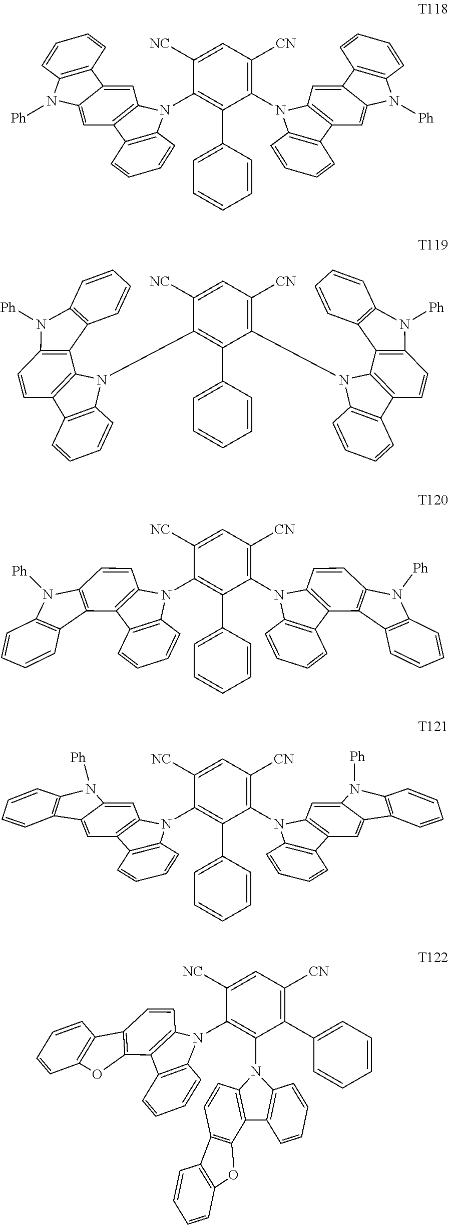

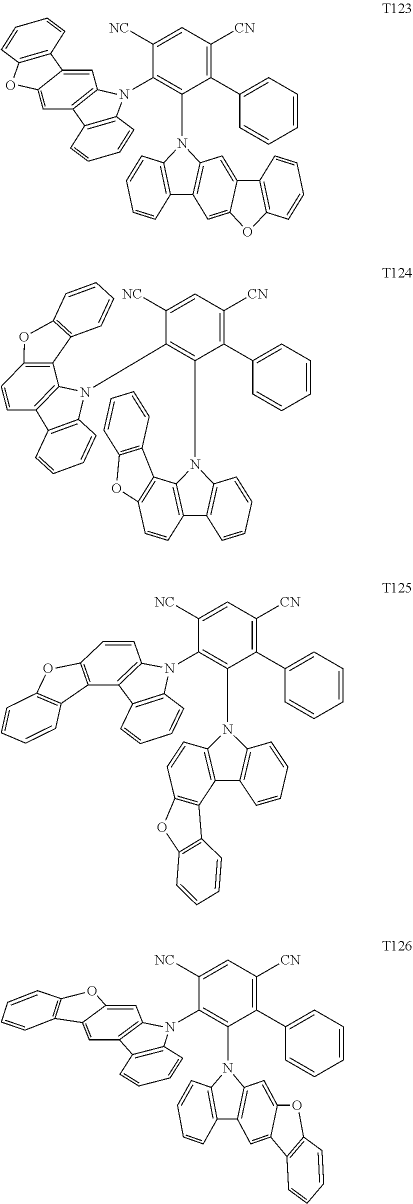 [SMILES: N#Cc1cc(C#N)c(-n2c3ccccc3c3cc4oc5ccccc5c4cc32)c(-n2c3ccccc3c3cc4oc5ccccc5c4cc32)c1-c1ccccc1 ; N#Cc1cc(C#N)c(-n2c3ccccc3c3ccc4oc5ccccc5c4c32)c(-n2c3ccccc3c3ccc4oc5ccccc5c4c32)c1-c1ccccc1 ; N#Cc1cc(C#N)c(-n2c3ccccc3c3c4c(ccc32)oc2ccccc24)c(-n2c3ccccc3c3c4c(ccc32)oc2ccccc24)c1-c1ccccc1 ; N#Cc1cc(C#N)c(-n2c3ccccc3c3cc4c(cc32)oc2ccccc24)c(-n2c3ccccc3c3cc4c(cc32)oc2ccccc24)c1-c1ccccc1]

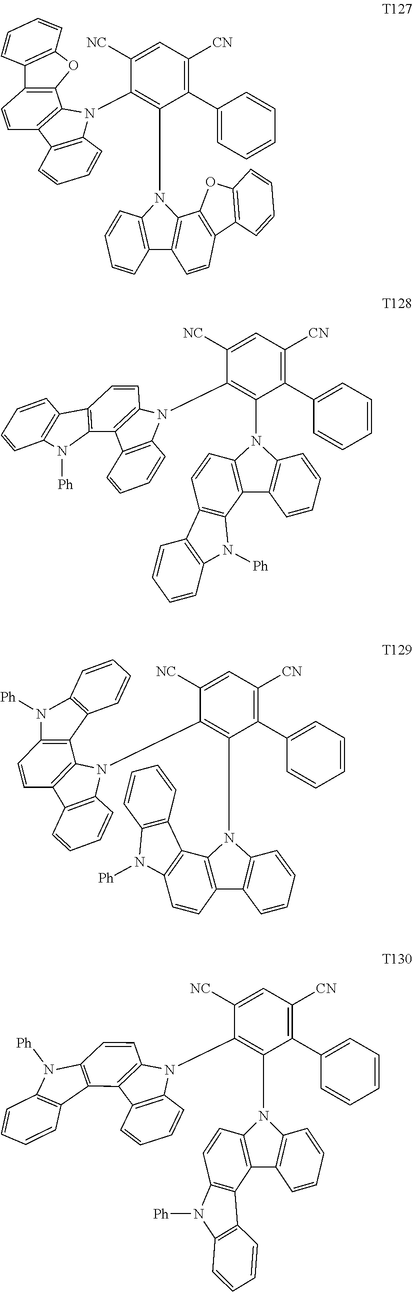 [SMILES: N#Cc1cc(C#N)c(-n2c3ccccc3c3ccc4c5ccccc5oc4c32)c(-n2c3ccccc3c3ccc4c5ccccc5oc4c32)c1-c1ccccc1 ; N#Cc1cc(C#N)c(-n2c3ccccc3c3c2ccc2c4ccccc4n(-c4ccccc4)c23)c(-n2c3ccccc3c3c2ccc2c4ccccc4n(-c4ccccc4)c23)c1-c1ccccc1 ; N#Cc1cc(C#N)c(-n2c3ccccc3c3ccc4c(c5ccccc5n4-c4ccccc4)c32)c(-n2c3ccccc3c3ccc4c(c5ccccc5n4-c4ccccc4)c32)c1-c1ccccc1 ; N#Cc1cc(C#N)c(-n2c3ccccc3c3c4c5ccccc5n(-c5ccccc5)c4ccc32)c(-n2c3ccccc3c3c4c5ccccc5n(-c5ccccc5)c4ccc32)c1-c1ccccc1]

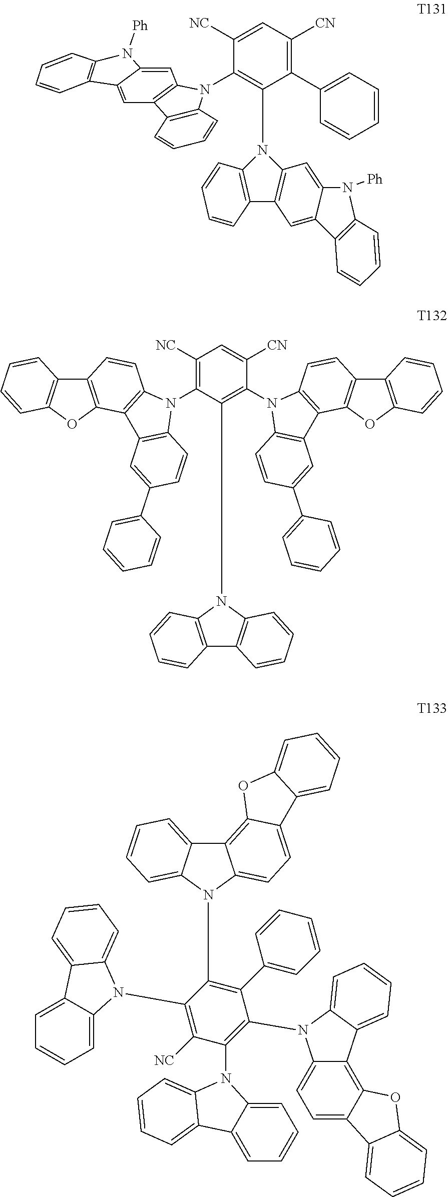 [SMILES: N#Cc1cc(C#N)c(-n2c3ccccc3c3cc4c5ccccc5n(-c5ccccc5)c4cc32)c(-n2c3ccccc3c3cc4c5ccccc5n(-c5ccccc5)c4cc32)c1-c1ccccc1 ; N#Cc1cc(C#N)c(-n2c3ccc(-c4ccccc4)cc3c3c4oc5ccccc5c4ccc32)c(-n2c3ccccc3c3ccccc32)c1-n1c2ccc(-c3ccccc3)cc2c2c3oc4ccccc4c3ccc21 ; N#Cc1c(-n2c3ccccc3c3ccccc32)c(-n2c3ccccc3c3c4oc5ccccc5c4ccc32)c(-c2ccccc2)c(-n2c3ccccc3c3c4oc5ccccc5c4ccc32)c1-n1c2ccccc2c2ccccc21]

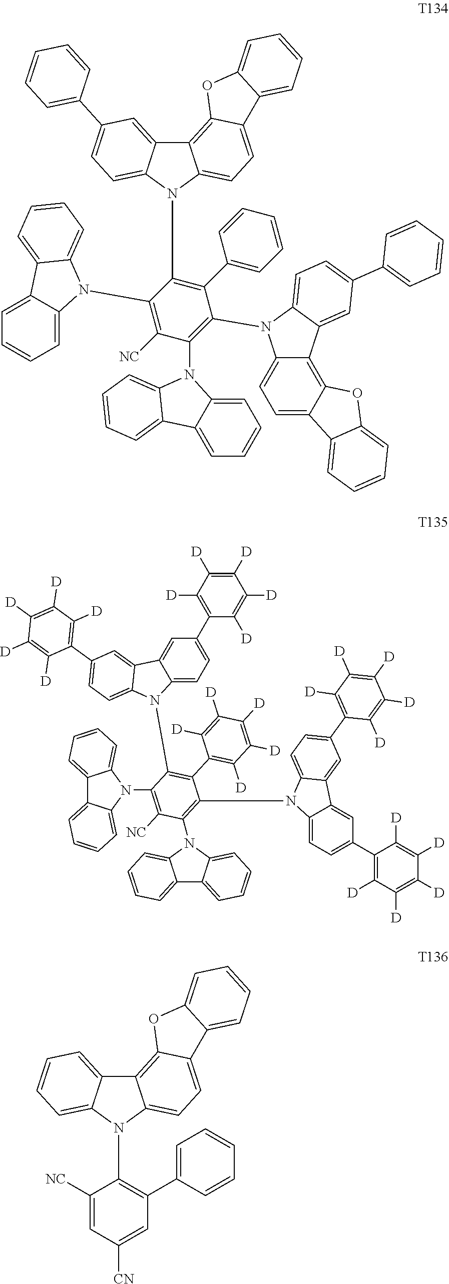

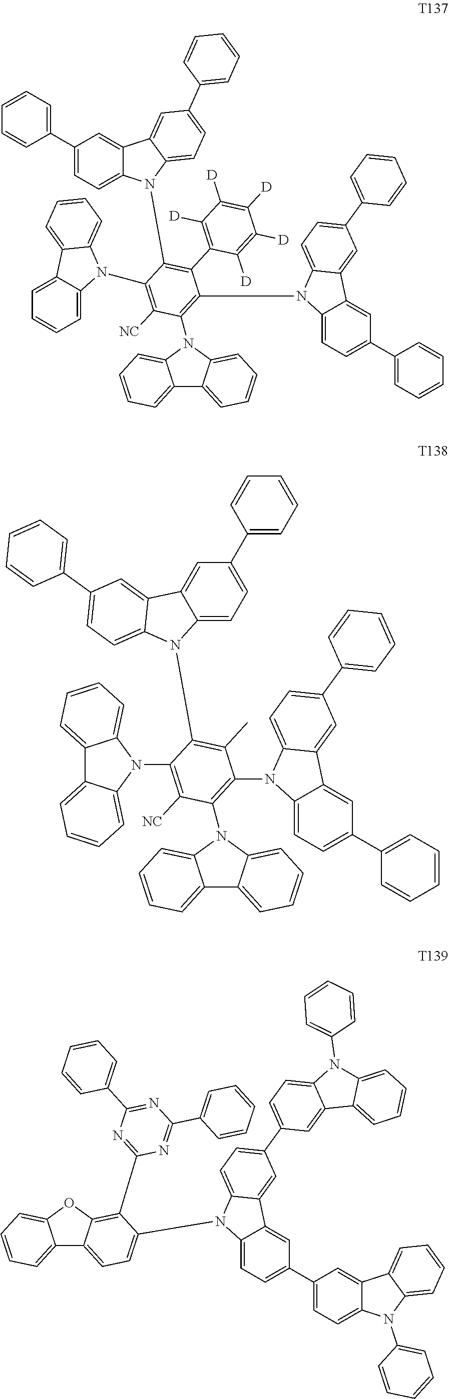 [SMILES: [2H]c1c([2H])c([2H])c(-c2c(-n3c4ccc(-c5ccccc5)cc4c4cc(-c5ccccc5)ccc43)c(-n3c4ccccc4c4ccccc43)c(C#N)c(-n3c4ccccc4c4ccccc43)c2-n2c3ccc(-c4ccccc4)cc3c3cc(-c4ccccc4)ccc32)c([2H])c1[2H] ; Cc1c(-n2c3ccc(-c4ccccc4)cc3c3cc(-c4ccccc4)ccc32)c(-n2c3ccccc3c3ccccc32)c(C#N)c(-n2c3ccccc3c3ccccc32)c1-n1c2ccc(-c3ccccc3)cc2c2cc(-c3ccccc3)ccc21 ; c1ccc(-c2nc(-c3ccccc3)nc(-c3c(-n4c5ccc(-c6ccc7c(c6)c6ccccc6n7-c6ccccc6)cc5c5cc(-c6ccc7c(c6)c6ccccc6n7-c6ccccc6)ccc54)ccc4c3oc3ccccc34)n2)cc1]

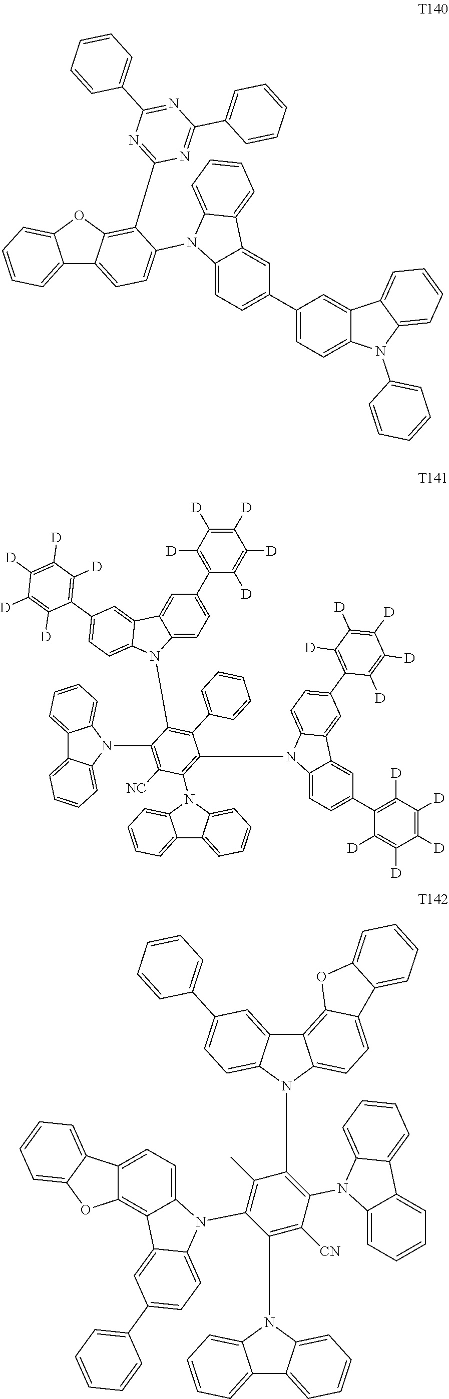

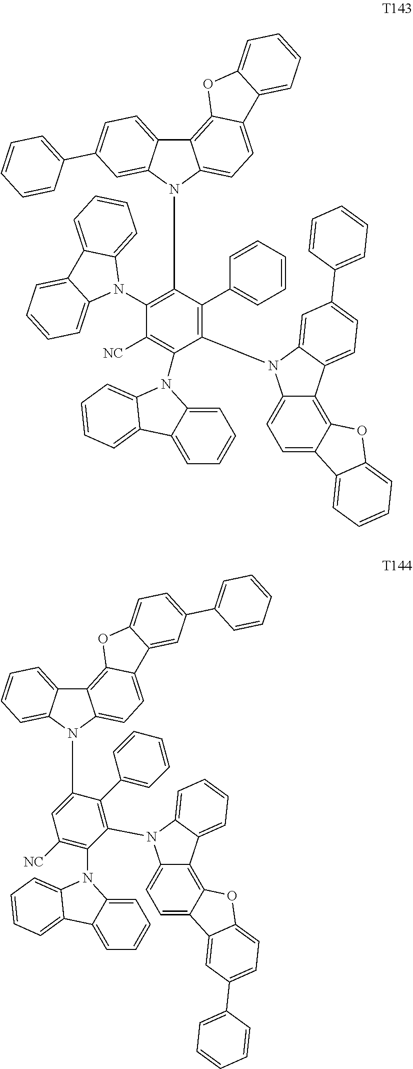 [SMILES: N#Cc1c(-n2c3ccccc3c3ccccc32)c(-n2c3cc(-c4ccccc4)ccc3c3c4oc5ccccc5c4ccc32)c(-c2ccccc2)c(-n2c3cc(-c4ccccc4)ccc3c3c4oc5ccccc5c4ccc32)c1-n1c2ccccc2c2ccccc21 ; N#Cc1cc(-n2c3ccccc3c3c4oc5ccc(-c6ccccc6)cc5c4ccc32)c(-c2ccccc2)c(-n2c3ccccc3c3c4oc5ccc(-c6ccccc6)cc5c4ccc32)c1-n1c2ccccc2c2ccccc21]

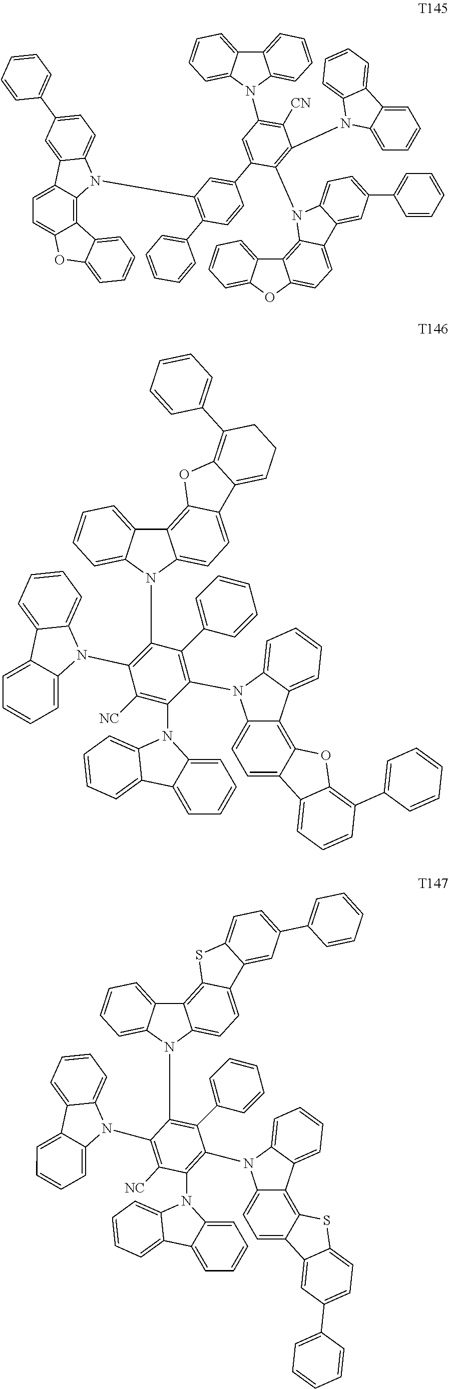 [SMILES: N#Cc1c(-n2c3ccccc3c3ccccc32)cc(-c2ccc(-c3ccccc3)c(-n3c4ccc(-c5ccccc5)cc4c4ccc5oc6ccccc6c5c43)c2)c(-n2c3ccc(-c4ccccc4)cc3c3ccc4oc5ccccc5c4c32)c1-n1c2ccccc2c2ccccc21 ; N#Cc1c(-n2c3ccccc3c3ccccc32)c(-n2c3ccccc3c3c4oc5c(c4ccc32)=CCCC=5c2ccccc2)c(-c2ccccc2)c(-n2c3ccccc3c3c4oc5c(-c6ccccc6)cccc5c4ccc32)c1-n1c2ccccc2c2ccccc21 ; N#Cc1c(-n2c3ccccc3c3ccccc32)c(-n2c3ccccc3c3c4sc5ccc(-c6ccccc6)cc5c4ccc32)c(-c2ccccc2)c(-n2c3ccccc3c3c4sc5ccc(-c6ccccc6)cc5c4ccc32)c1-n1c2ccccc2c2ccccc21]

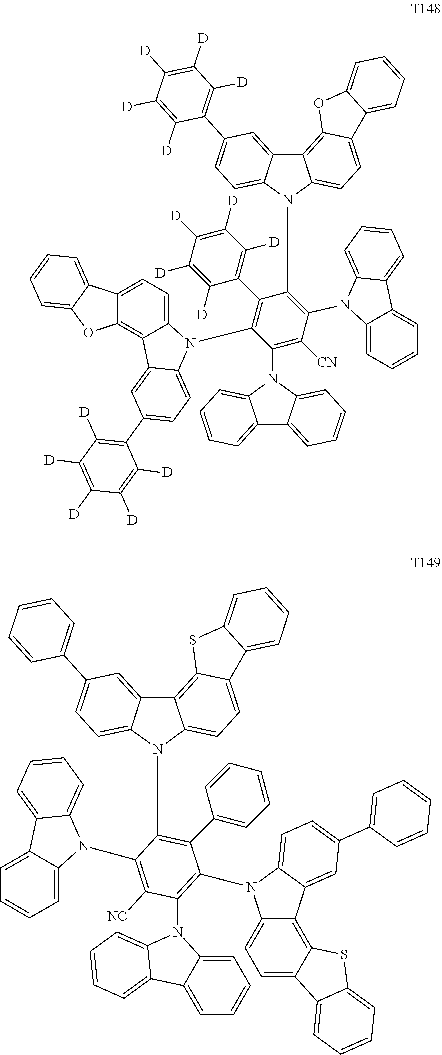 [SMILES: [2H]c1c([2H])c([2H])c(-c2ccc3c(c2)c2c4oc5ccccc5c4ccc2n3-c2c(-c3c([2H])c([2H])c([2H])c([2H])c3[2H])c(-n3c4ccc(-c5c([2H])c([2H])c([2H])c([2H])c5[2H])cc4c4c5oc6ccccc6c5ccc43)c(-n3c4ccccc4c4ccccc43)c(C#N)c2-n2c3ccccc3c3ccccc32)c([2H])c1[2H] ; N#Cc1c(-n2c3ccccc3c3ccccc32)c(-n2c3ccc(-c4ccccc4)cc3c3c4sc5ccccc5c4ccc32)c(-c2ccccc2)c(-n2c3ccc(-c4ccccc4)cc3c3c4sc5ccccc5c4ccc32)c1-n1c2ccccc2c2ccccc21]

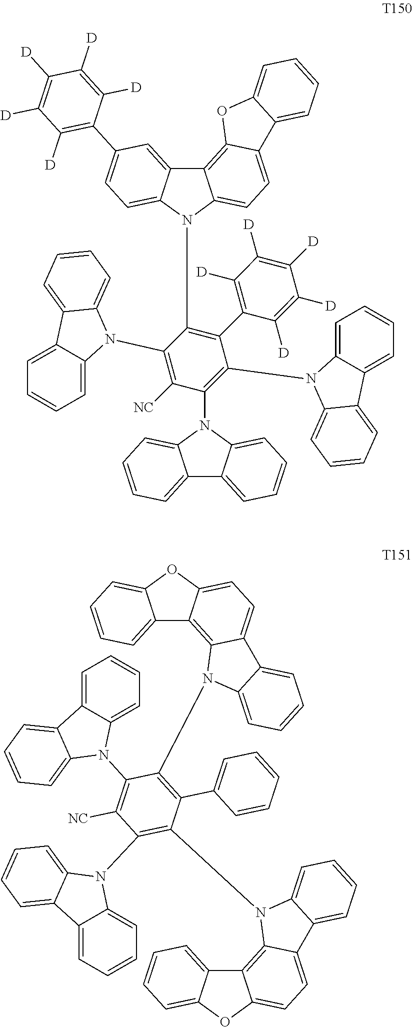 [SMILES: [2H]c1c([2H])c([2H])c(-c2ccc3c(c2)c2c4oc5ccccc5c4ccc2n3-c2c(-c3c([2H])c([2H])c([2H])c([2H])c3[2H])c(-n3c4ccccc4c4ccccc43)c(-n3c4ccccc4c4ccccc43)c(C#N)c2-n2c3ccccc3c3ccccc32)c([2H])c1[2H] ; N#Cc1c(-n2c3ccccc3c3ccccc32)c(-n2c3ccccc3c3ccc4oc5ccccc5c4c32)c(-c2ccccc2)c(-n2c3ccccc3c3ccc4oc5ccccc5c4c32)c1-n1c2ccccc2c2ccccc21]

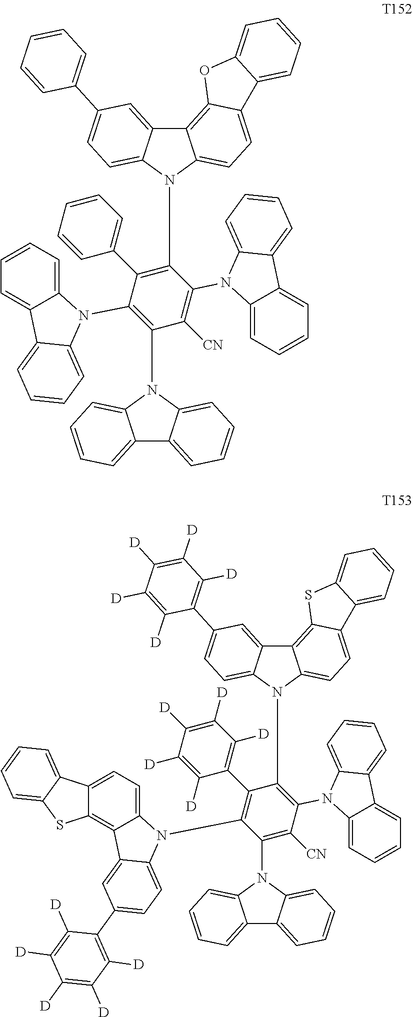 [SMILES: N#Cc1c(-n2c3ccccc3c3ccccc32)c(-n2c3ccccc3c3ccccc32)c(-c2ccccc2)c(-n2c3ccc(-c4ccccc4)cc3c3c4oc5ccccc5c4ccc32)c1-n1c2ccccc2c2ccccc21 ; [2H]c1c([2H])c([2H])c(-c2ccc3c(c2)c2c4sc5ccccc5c4ccc2n3-c2c(-c3c([2H])c([2H])c([2H])c([2H])c3[2H])c(-n3c4ccc(-c5c([2H])c([2H])c([2H])c([2H])c5[2H])cc4c4c5sc6ccccc6c5ccc43)c(-n3c4ccccc4c4ccccc43)c(C#N)c2-n2c3ccccc3c3ccccc32)c([2H])c1[2H]]

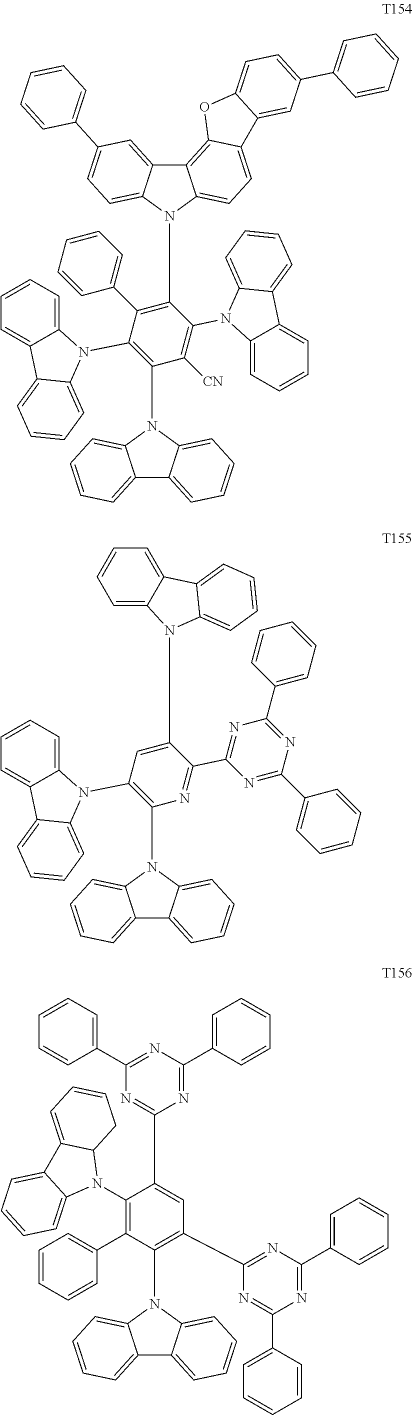

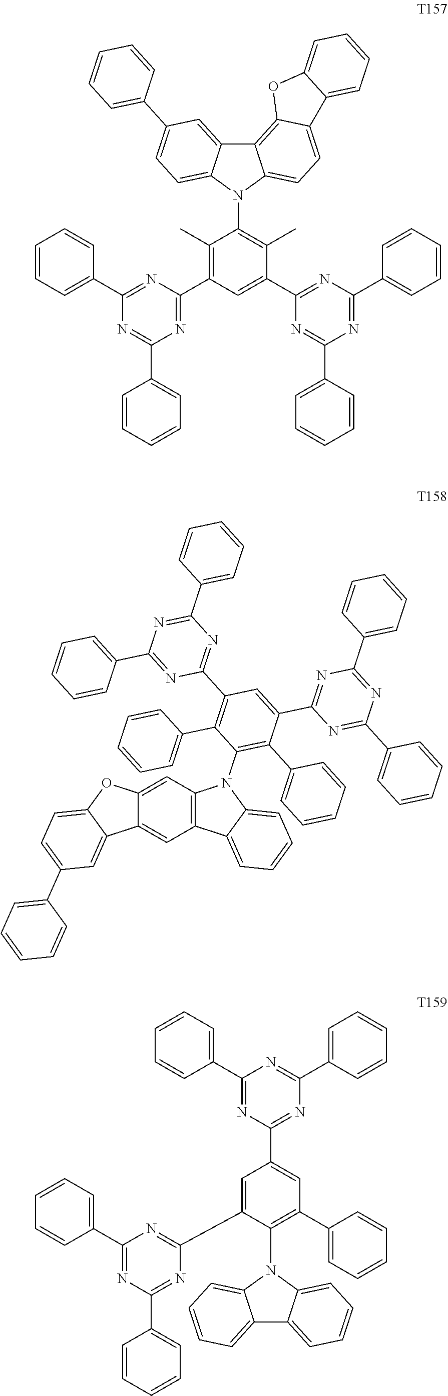 [SMILES: Cc1c(-c2nc(-c3ccccc3)nc(-c3ccccc3)n2)cc(-c2nc(-c3ccccc3)nc(-c3ccccc3)n2)c(C)c1-n1c2ccc(-c3ccccc3)cc2c2c3oc4ccccc4c3ccc21 ; c1ccc(-c2ccc3oc4cc5c(cc4c3c2)c2ccccc2n5-c2c(-c3ccccc3)c(-c3nc(-c4ccccc4)nc(-c4ccccc4)n3)cc(-c3nc(-c4ccccc4)nc(-c4ccccc4)n3)c2-c2ccccc2)cc1 ; c1ccc(-c2nc(-c3ccccc3)nc(-c3cc(-c4ccccc4)c(-n4c5ccccc5c5ccccc54)c(-c4nc(-c5ccccc5)nc(-c5ccccc5)n4)c3)n2)cc1]

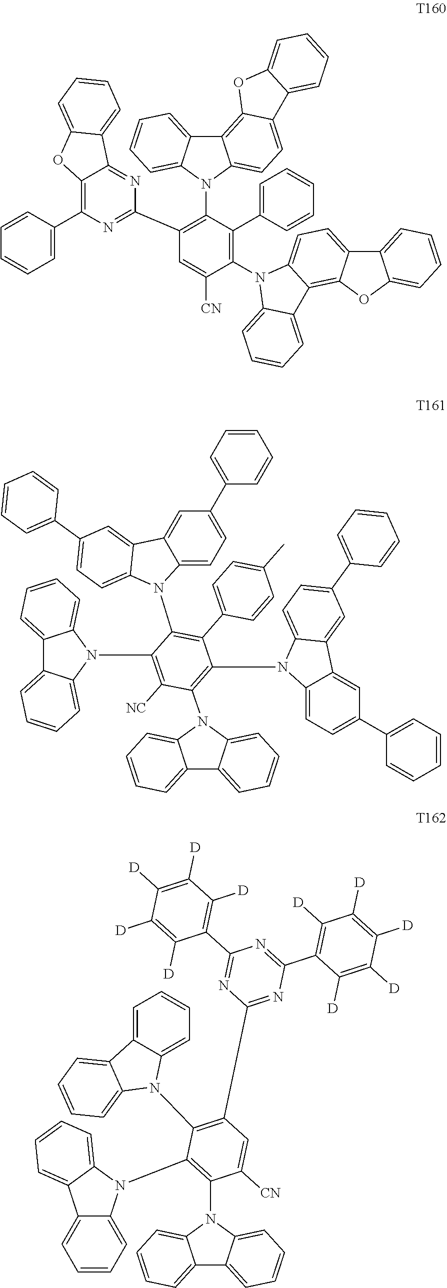 [SMILES: N#Cc1cc(-c2nc(-c3ccccc3)c3oc4ccccc4c3n2)c(-n2c3ccccc3c3c4oc5ccccc5c4ccc32)c(-c2ccccc2)c1-n1c2ccccc2c2c3oc4ccccc4c3ccc21 ; Cc1ccc(-c2c(-n3c4ccc(-c5ccccc5)cc4c4cc(-c5ccccc5)ccc43)c(-n3c4ccccc4c4ccccc43)c(C#N)c(-n3c4ccccc4c4ccccc43)c2-n2c3ccc(-c4ccccc4)cc3c3cc(-c4ccccc4)ccc32)cc1 ; [2H]c1c([2H])c([2H])c(-c2nc(-c3cc(C#N)c(-n4c5ccccc5c5ccccc54)c(-n4c5ccccc5c5ccccc54)c3-n3c4ccccc4c4ccccc43)nc(-c3c([2H])c([2H])c([2H])c([2H])c3[2H])n2)c([2H])c1[2H]]

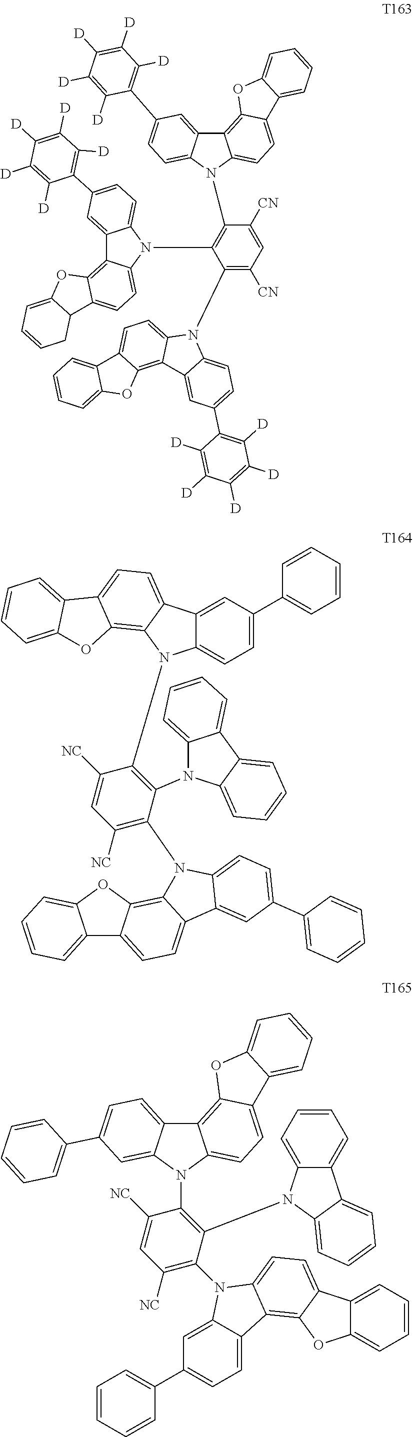 [SMILES: [2H]c1c([2H])c([2H])c(-c2ccc3c(c2)c2c4c(ccc2n3-c2c(-n3c5ccc(-c6c([2H])c([2H])c([2H])c([2H])c6[2H])cc5c5c6oc7ccccc7c6ccc53)c(C#N)cc(C#N)c2-n2c3ccc(-c5c([2H])c([2H])c([2H])c([2H])c5[2H])cc3c3c5oc6ccccc6c5ccc32)C2CC=CC=C2O4)c([2H])c1[2H] ; N#Cc1cc(C#N)c(-n2c3ccc(-c4ccccc4)cc3c3ccc4c5ccccc5oc4c32)c(-n2c3ccccc3c3ccccc32)c1-n1c2ccc(-c3ccccc3)cc2c2ccc3c4ccccc4oc3c21 ; N#Cc1cc(C#N)c(-n2c3cc(-c4ccccc4)ccc3c3c4oc5ccccc5c4ccc32)c(-n2c3ccccc3c3ccccc32)c1-n1c2cc(-c3ccccc3)ccc2c2c3oc4ccccc4c3ccc21]

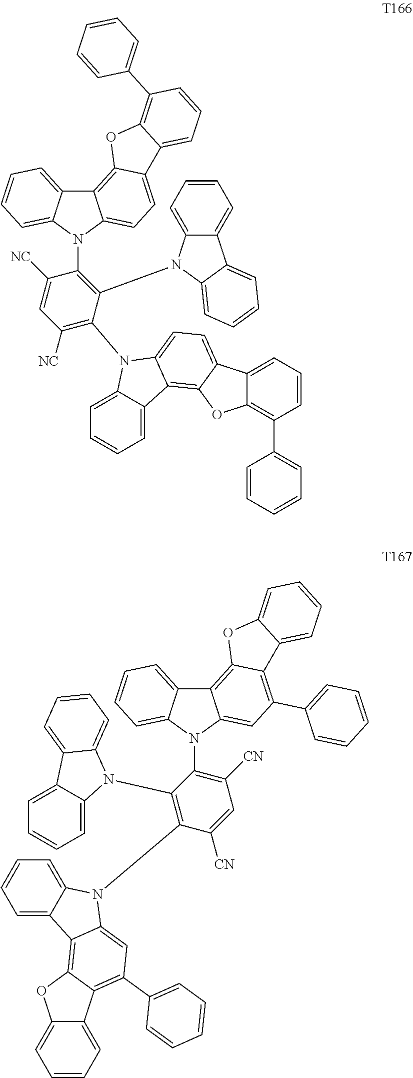 [SMILES: N#Cc1cc(C#N)c(-n2c3ccccc3c3c4oc5c(-c6ccccc6)cccc5c4ccc32)c(-n2c3ccccc3c3ccccc32)c1-n1c2ccccc2c2c3oc4c(-c5ccccc5)cccc4c3ccc21 ; N#Cc1cc(C#N)c(-n2c3ccccc3c3c4oc5ccccc5c4c(-c4ccccc4)cc32)c(-n2c3ccccc3c3ccccc32)c1-n1c2ccccc2c2c3oc4ccccc4c3c(-c3ccccc3)cc21]

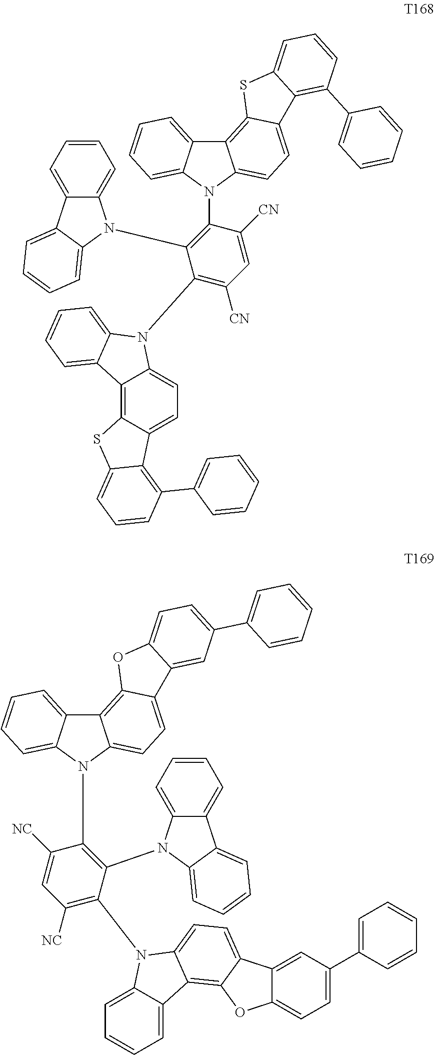 [SMILES: N#Cc1cc(C#N)c(-n2c3ccccc3c3c4sc5cccc(-c6ccccc6)c5c4ccc32)c(-n2c3ccccc3c3ccccc32)c1-n1c2ccccc2c2c3sc4cccc(-c5ccccc5)c4c3ccc21 ; N#Cc1cc(C#N)c(-n2c3ccccc3c3c4oc5ccc(-c6ccccc6)cc5c4ccc32)c(-n2c3ccccc3c3ccccc32)c1-n1c2ccccc2c2c3oc4ccc(-c5ccccc5)cc4c3ccc21]

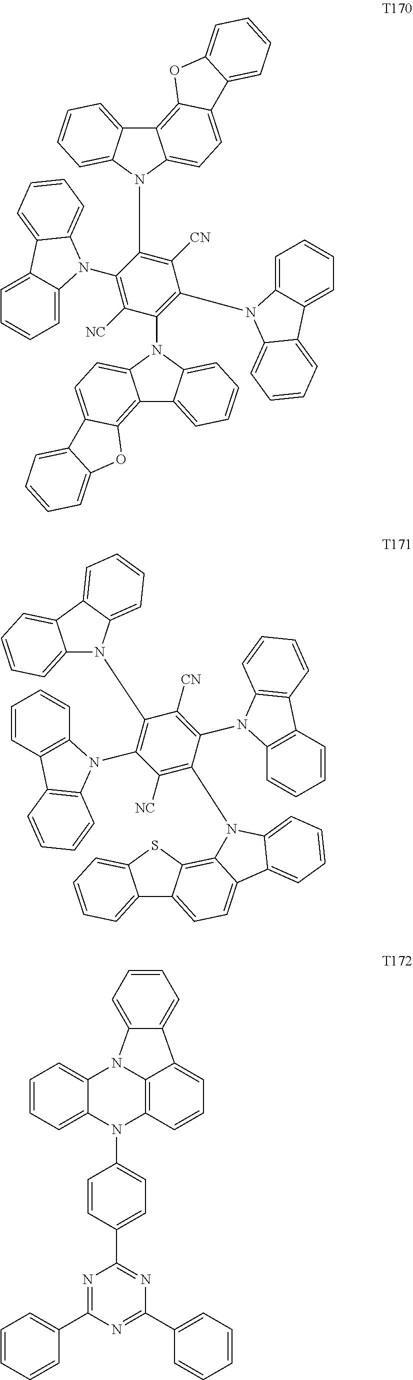 [SMILES: N#Cc1c(-n2c3ccccc3c3ccccc32)c(-n2c3ccccc3c3c4oc5ccccc5c4ccc32)c(C#N)c(-n2c3ccccc3c3ccccc32)c1-n1c2ccccc2c2c3oc4ccccc4c3ccc21 ; N#Cc1c(-n2c3ccccc3c3ccccc32)c(-n2c3ccccc3c3ccccc32)c(C#N)c(-n2c3ccccc3c3ccc4c5ccccc5sc4c32)c1-n1c2ccccc2c2ccccc21 ; c1ccc(-c2nc(-c3ccccc3)nc(-c3ccc(N4c5ccccc5-n5c6ccccc6c6cccc4c65)cc3)n2)cc1]

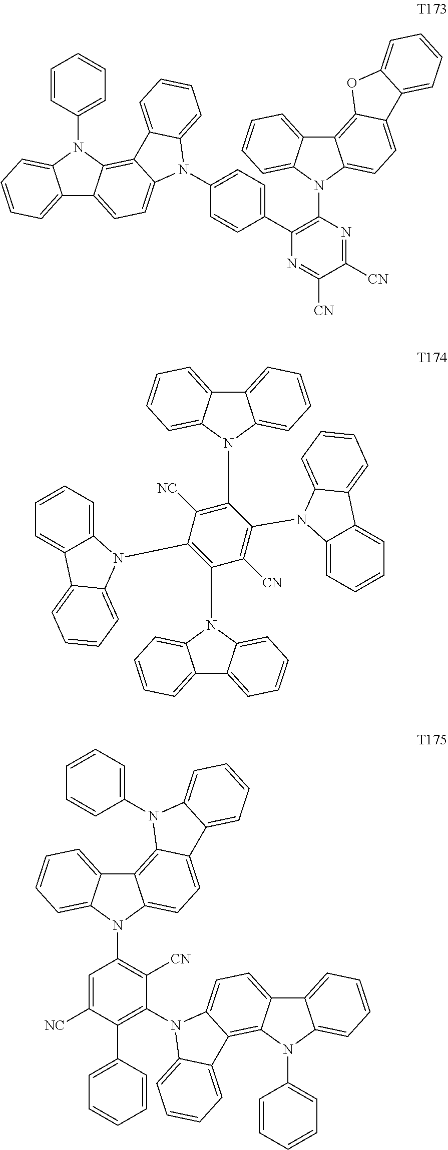 [SMILES: N#Cc1nc(-c2ccc(-n3c4ccccc4c4c3ccc3c5ccccc5n(-c5ccccc5)c34)cc2)c(-n2c3ccccc3c3c4oc5ccccc5c4ccc32)nc1C#N ; N#Cc1c(-n2c3ccccc3c3ccccc32)c(-n2c3ccccc3c3ccccc32)c(C#N)c(-n2c3ccccc3c3ccccc32)c1-n1c2ccccc2c2ccccc21 ; N#Cc1cc(-n2c3ccccc3c3c2ccc2c4ccccc4n(-c4ccccc4)c23)c(C#N)c(-n2c3ccccc3c3c2ccc2c4ccccc4n(-c4ccccc4)c23)c1-c1ccccc1]

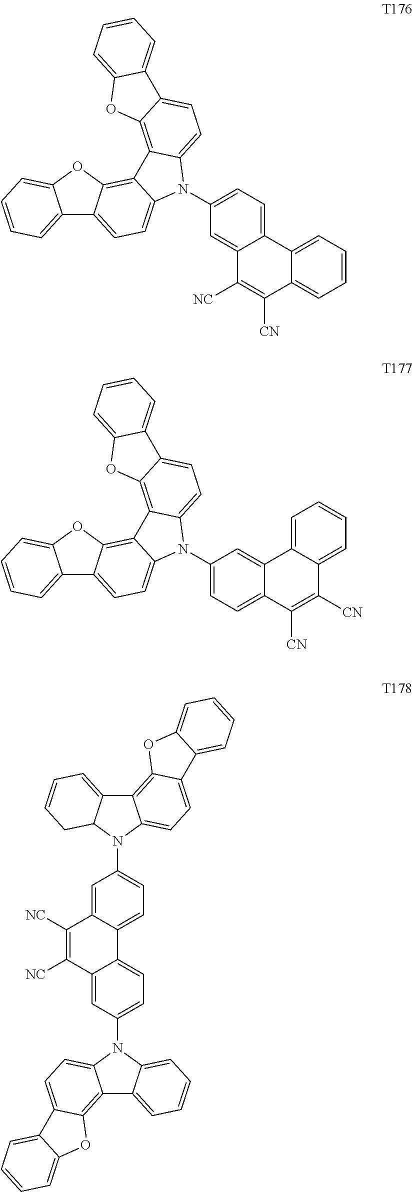 [SMILES: N#Cc1c(C#N)c2cc(-n3c4ccc5c6ccccc6oc5c4c4c5oc6ccccc6c5ccc43)ccc2c2ccccc12 ; N#Cc1c(C#N)c2ccc(-n3c4ccc5c6ccccc6oc5c4c4c5oc6ccccc6c5ccc43)cc2c2ccccc12 ; N#Cc1c(C#N)c2cc(-n3c4ccccc4c4c5oc6ccccc6c5ccc43)ccc2c2ccc(N3c4ccc5c(oc6ccccc65)c4C4=CC=CCC43)cc12]

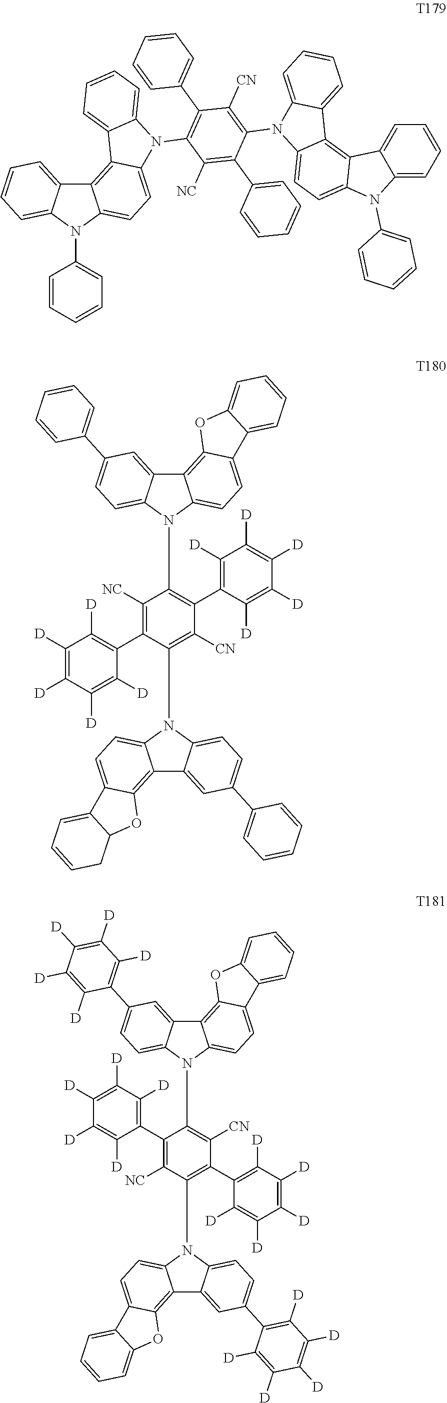

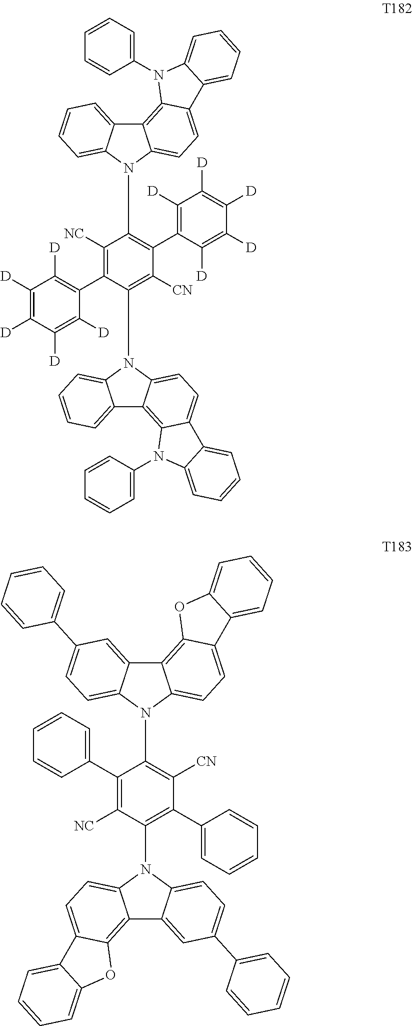 [SMILES: [2H]c1c([2H])c([2H])c(-c2c(C#N)c(-n3c4ccccc4c4c3ccc3c5ccccc5n(-c5ccccc5)c34)c(-c3c([2H])c([2H])c([2H])c([2H])c3[2H])c(C#N)c2-n2c3ccccc3c3c2ccc2c4ccccc4n(-c4ccccc4)c23)c([2H])c1[2H] ; N#Cc1c(-c2ccccc2)c(-n2c3ccc(-c4ccccc4)cc3c3c4oc5ccccc5c4ccc32)c(C#N)c(-c2ccccc2)c1-n1c2ccc(-c3ccccc3)cc2c2c3oc4ccccc4c3ccc21]

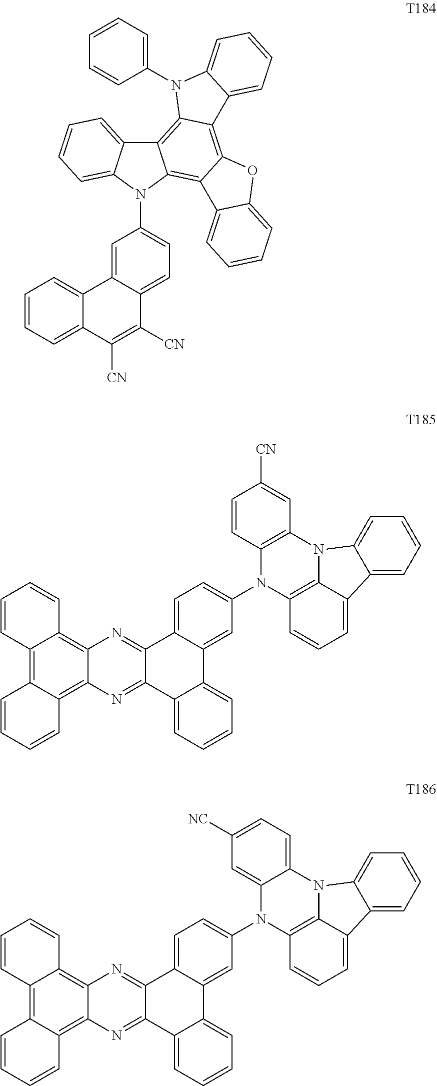 [SMILES: N#Cc1c(C#N)c2ccc(-n3c4ccccc4c4c5c(c6ccccc6n5-c5ccccc5)c5oc6ccccc6c5c43)cc2c2ccccc12 ; N#Cc1ccc2c(c1)-n1c3ccccc3c3cccc(c31)N2c1ccc2c(c1)c1ccccc1c1nc3c4ccccc4c4ccccc4c3nc21 ; N#Cc1ccc2c(c1)N(c1ccc3c(c1)c1ccccc1c1nc4c5ccccc5c5ccccc5c4nc31)c1cccc3c4ccccc4n-2c13]

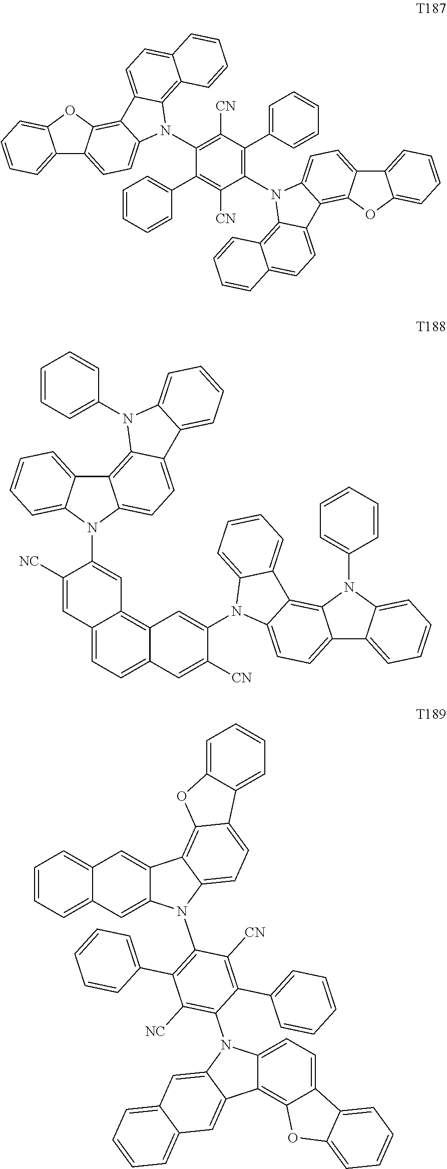

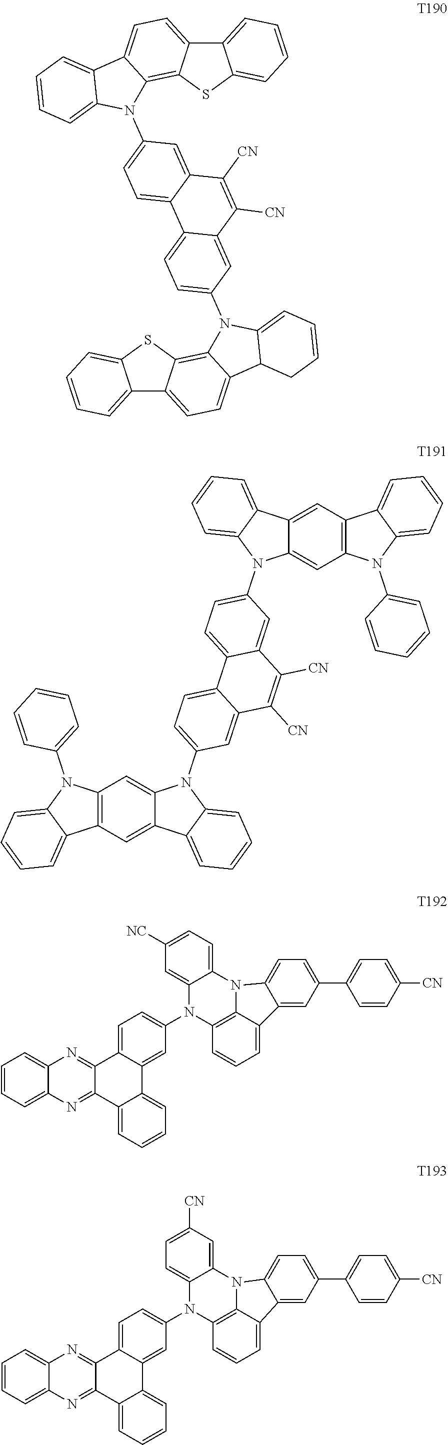 [SMILES: N#Cc1c(C#N)c2cc(-n3c4ccccc4c4ccc5c6ccccc6sc5c43)ccc2c2ccc(N3C4=CC=CCC4c4ccc5c(sc6ccccc65)c43)cc12 ; N#Cc1c(C#N)c2cc(-n3c4ccccc4c4cc5c6ccccc6n(-c6ccccc6)c5cc43)ccc2c2ccc(-n3c4ccccc4c4cc5c6ccccc6n(-c6ccccc6)c5cc43)cc12 ; N#Cc1ccc(-c2ccc3c(c2)c2cccc4c2n3-c2ccc(C#N)cc2N4c2ccc3c(c2)c2ccccc2c2nc4ccccc4nc32)cc1 ; N#Cc1ccc(-c2ccc3c(c2)c2cccc4c2n3-c2cc(C#N)ccc2N4c2ccc3c(c2)c2ccccc2c2nc4ccccc4nc32)cc1]

Any other known delayed fluorescent materials than the above can be appropriately combined and used as the second organic compound. In addition, unknown delayed fluorescent materials can also be used.

As delayed fluorescent materials, there can be mentioned compounds included in the general formulae described in WO2013/154064, paragraphs 0008 to 0048 and 0095 to 0133; WO2013/011954, paragraphs 0007 to 0047 and 0073 to 0085; WO2013/011955, paragraphs 0007 to 0033 and 0059 to 0066; WO2013/081088, paragraphs 0008 to 0071 and 0118 to 0133; JP 2013-256490 A, paragraphs 0009 to 0046 and 0093 to 0134; JP 2013-116975 A, paragraphs 0008 to 0020 and 0038 to 0040; WO2013/133359, paragraphs 0007 to 0032 and 0079 to 0084; WO2013/161437, paragraphs 0008 to 0054 and 0101 to 0121; JP 2014-9352 A, paragraphs 0007 to 0041 and 0060 to 0069; and JP 2014-9224 A, paragraphs 0008 to 0048 and 0067 to 0076; JP 2017-119663 A, paragraphs 0013 to 0025; JP 2017-119664 A, paragraphs 0013 to 0026; JP 2017-222623 A, paragraphs 0012 to 0025; JP 2017-226838 A, paragraphs 0010 to 0050; JP 2018-100411 A, paragraphs 0012 to 0043; WO2018/047853, paragraphs 0016 to 0044; and especially, exemplary compounds therein capable of emitting delayed fluorescence. In addition, also employable here are light emitting materials capable of emitting delayed fluorescence, as described in JP 2013-253121 A, WO2013/133359, WO2014/034535, WO2014/115743, WO2014/122895, WO2014/126200, WO2014/136758, WO2014/133121, WO2014/136860, WO2014/196585, WO2014/189122, WO2014/168101, WO2015/008580, WO2014/203840, WO2015/002213, WO2015/016200, WO2015/019725, WO2015/072470, WO2015/108049, WO2015/080182, WO2015/072537, WO2015/080183, JP 2015-129240 A, WO2015/129714, WO2015/129715, WO2015/133501, WO2015/136880, WO2015/137244, WO2015/137202, WO2015/137136, WO2015/146541 and WO2015/159541. These patent publications described in this paragraph are hereby incorporated as a part of this description by reference.

### (Third Organic Compound)

The third organic compound used in the light emitting layer of the organic electroluminescent device of the present invention is a fluorescent material having a smaller lowest excited singlet energy than the first organic compound and the second organic compound, and having a larger HOMO energy than the second organic compound. The organic electroluminescent device of the present indention emits fluorescence derived from the third organic compound. Light emission from the third organic compound generally includes delayed fluorescence. The maximum component of light emission from the organic electroluminescent device of the present invention is light emission from the third organic compound. Specifically, of the light emission from the organic electroluminescent device of the present invention, the amount of light emission from the third organic compound is the largest. 70% or more of light emission from the organic electroluminescent device can be light emission from the third organic compound, or 90% or more can be from the third organic compound, or 99% or more can be from the third organic compound. The third organic compound receives energy from the first organic compound in an excited singlet state, from the second organic compound in an excited singlet state, and from the second organic compound that has been in an excited singlet state through reverse intersystem crossing from an excited triplet state, and thus transitions into an excited singlet state. In a preferred embodiment of the present invention, the third organic compound receives energy from the second organic compound in an excited singlet state and from the second organic compound that has been in an excited singlet state through reverse intersystem crossing from an excited triplet state, and thus transitions into an excited singlet state. The resultant third organic compound thus in an excited singlet state emits fluorescence when thereafter returning back to a ground state.

The fluorescent material to be used as the third organic compound is not specifically limited so far as it can receive energy from the first organic compound and the second organic compound in the manner as above to emit light, and the light emission can include any of fluorescence, delayed fluorescence and phosphorescence. Preferably, the light emission includes fluorescence and delayed fluorescence, and more preferred is a case where the maximum component of light emission from the third organic compound is fluorescence. In one embodiment of the present invention, the organic electroluminescent device does not emit phosphorescence, or the radiation amount of phosphorescence from the device is not more than 1% of fluorescence therefrom.

The lowest excited triplet energy of the third organic compound is preferably larger than 1.90 eV, and can be, for example, larger than 2.45 eV, or larger than 2.48 eV, or larger than 2.60 eV. The maximum emission wavelength of the third organic compound is preferably shorter than the maximum emission wavelength of the second organic compound. The wavelength difference can be 2 nm or more, or can be 10 nm or more, or can be 20 nm or more, or can be 25 nm or more, and can be, for example, 50 nm or less, or 30 nm or less, or 10 nm or less, or 5 nm or less. In one preferred embodiment of the present invention, the ionization energy of the third organic compound is larger than the ionization energy of the second organic compound. The difference can be 0.2 eV or more, or can be 0.4 eV or more, or can be 0.7 eV or more, or can also be 1.0 eV or less, or 0.8 eV or less, or 0.5 eV or less.

Two or more kinds of third organic compounds can be used as combined so far as they satisfy the requirements in the present invention. For example, by using two or more kinds of the third organic compounds that differ in the emission color, light of a desired color can be emitted. Also by using one kind of the third organic compound, monochromatic emission can be made by the third organic compound.

In the present invention, the maximum emission wavelength of the compound usable as the third organic compound is not specifically limited. Therefore, a light emitting material having a maximum emission wavelength in a visible range (380 to 780 nm) or having a maximum emission wavelength in an IR range (780 nm to 1 mm), or a compound having a maximum emission wavelength in a UV range (for example, 280 to 380 nm) can be appropriately selected and used here. Preferred is a fluorescent material having a maximum emission wavelength in a visible range. For example, a light emitting material of which the maximum emission wavelength in a range of 380 to 780 nm falls within a range of 380 to 570 nm can be selected and used, or a light emitting material of which the maximum emission wavelength falls within a range of 570 to 650 nm can be selected and used, or a light emitting material of which the maximum emission wavelength falls within a range of 650 to 700 nm can be selected and used, or a light emitting material of which the maximum emission wavelength falls within a range of 700 to 780 nm can be selected and used.

In a preferred embodiment of the present invention, the second organic compound and the third organic compound are so selected and combined that the emission wavelength range of the former and the absorption wavelength range of the latter can overlap with each other. Especially preferably, the edge in the short wavelength side of the emission spectrum of the second organic compound overlaps with the edge on the long wavelength side of the absorption spectrum of the third organic compound.

Preferably, the third organic compound does not contain a metal atom other than a boron atom. For example, the compound can be one containing a boron atom but not containing a fluorine atom. Also the compound can be one not containing a metal atom at all. For example, as the third organic compound, a compound composed of atoms selected from the group consisting of a carbon atom, a hydrogen atom, a deuterium atom, a nitrogen atom, an oxygen atom, a sulfur atom and a boron atom can be selected. For example, as the third organic compound, a compound composed of atoms selected from the group consisting of a carbon atom, a hydrogen atom, a deuterium atom, a nitrogen atom, an oxygen atom, and a boron atom can be selected. For example, as the third organic compound, a compound composed of atoms selected from the group consisting of a carbon atom, a hydrogen atom, a deuterium atom, a nitrogen atom, an oxygen atom, a sulfur atom, and a boron atom can be selected. For example, as the third organic compound, a compound composed of atoms selected from the group consisting of a carbon atom, a hydrogen atom, a deuterium atom, a nitrogen atom, and a boron atom can be selected. For example, as the third organic compound, a compound composed of atoms selected from the group consisting of a carbon atom, a hydrogen atom, a deuterium atom, a nitrogen atom, an oxygen atom and a sulfur atom can be selected. For example, as the third organic compound, a compound composed of atoms selected from the group consisting of a carbon atom, a hydrogen atom, a deuterium atom, a nitrogen atom, and an oxygen atom can be selected. For example, as the third organic compound, a compound composed of a carbon atom, and a hydrogen atom can be selected.

Examples of the third organic compound include a compound having a multiple resonance effect of a boron atom and a nitrogen atom, and a compound having a condensed aromatic cyclic structure such as anthracene, pyrene and perylene.

In one preferred embodiment of the present invention, a compound represented by the following general formula (15) is used as the third organic compound.

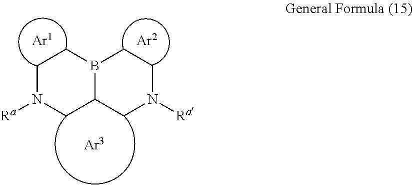

In the general formula (15), Ar¹ to Ar³ each independently represent an aryl ring or a heteroaryl ring, at least one hydrogen atom in these rings can be substituted, or the ring can be condensed. In the case where the hydrogen atom is substituted, preferably, it is substituted with one group selected from the group consisting of a deuterium atom, an aryl group, a heteroaryl group and an alkyl group, or with a combination of two or more these groups. In the case where the ring is condensed, preferably, the ring is condensed with a benzene ring or a heteroaromatic ring (for example, a furan ring, a thiophene ring, pyrrole ring). R^{a} and R^{a′}′ each independently represent a substituent, preferably one group selected from the group consisting of a deuterium atom, an aryl group, a heteroaryl group and an alkyl group, or a combination of two or more these groups. R^{a} and Ar¹, Ar¹ and Ar², Ar² and R^{a}′, R^{a}′ and Ar³, and Ar³ and R^{a} each can bond to each other to form a cyclic structure.

Preferably, the compound represented by the general formula (15) contains at least one carbazole structure. For example, one benzene ring constituting the carbazole structure can be a ring represented by Ar¹, one benzene ring constituting the carbazole structure can be a ring represented by Ar², or one benzene ring constituting the carbazole structure can be a ring represented by Ar³. Also, a carbazolyl group can bond to at least one or more of Ar¹ to Ar³. For example, a substituted or unsubstituted carbazol-9-yl group can bond to the ring represented by Ar³.

A condensed aromatic ring structure such as anthracene, pyrene or perylene may bond to Ar¹ to Ar³. The ring represented by Ar¹ to Ar³ can be one ring constituting a condensed aromatic ring structure. Further, at least one of R^{a} and R^{a}′ can be a group having a condensed aromatic ring structure.

The compound can have plural skeletons represented by the general formula (15). For example, the compound can have a structure where the skeletons represented by the general formula (15) bond to each other via a single bond or a linking group. The skeleton represented by the general formula (15) can be given a structure that exhibits a multiple resonance effect of benzene rings bonded to each other by a boron atom, a nitrogen atom, an oxygen atom or a sulfur atom.

In one preferred embodiment of the present invention, as the third organic compound, a compound having a BODIPY (4,4-difluoro-4-bora-3a,4a-diaza-s-indacene) structure is used. For example, a compound represented by the following general formula (16) is used.

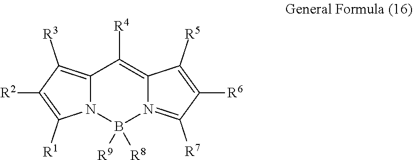

In the general formula (16), R¹ to R⁷ each independently represent a hydrogen atom, a deuterium atom or a substituent. At least one of R¹ to R⁷ is preferably a group represented by the following general formula (17).

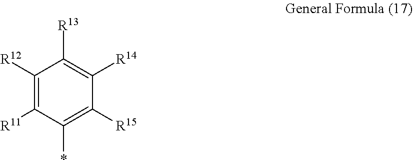

In the general formula (17), R¹¹ to R¹⁵ each independently represent a hydrogen atom, a deuterium atom or a substituent, * indicates a bonding position.

One or two or three of R¹ to R⁷ in the general formula (16) can be the group represented by the general formula (17). At least four can be the group, and for example, 4 or 5 can be the group. In one preferred embodiment of the present invention, one of R¹ to R⁷ is the group represented by the general formula (17). In one preferred embodiment of the present invention, at least R¹, R³, R⁵ and R⁷ each are the group represented by the general formula (17). In one preferred embodiment of the present invention, R¹, R³, R⁴, R⁵ and R⁷ alone are the group represented by the general formula (17). In one preferred embodiment of the present invention, R¹, R³, R⁴, R⁵ and R⁷ each are the group represented by the general formula (17), and R² and R⁴ each are a hydrogen atom, a deuterium atom, an unsubstituted alkyl group (for example, having 1 to 10 carbon atoms), or an unsubstituted aryl group (for example, having 6 to 14 carbon atoms). In one embodiment of the present invention, R¹ to R⁷ are all the group represented by the general formula (17).

In one preferred embodiment of the present invention, R¹ and R⁷ are the same. In one preferred embodiment of the present invention, R³ and R⁵ are the same. In one preferred embodiment of the present invention, R² and R⁶ are the same. In one preferred embodiment of the present invention, R¹ and R⁷ are the same, R³ and R⁵ are the same, and R¹ and R³ differ from each other. In one preferred embodiment of the present invention, R¹, R³, R⁵ and R⁷ are the same. In one preferred embodiment of the present invention, R¹ and R⁴ and R⁷ are the same, and differ from R³ and R⁵. In one preferred embodiment of the present invention, R³ and R⁴ and R⁵ are the same, and differ from R¹ and R⁷. In one preferred embodiment of the present invention, R¹, R³, R⁵ and R⁷ all differ from R⁴.

The substituent that R¹¹ to R¹⁵ in the general formula (17) can have can be selected from, for example, the above-mentioned substituent group a, or can be selected from the above-mentioned substituent group b, or can be selected from the above-mentioned substituent group c, or can be selected from the above-mentioned substituent group d. In the case where a substituted amino group is selected for the substituent, the group is preferably a di-substituted amino group, and preferably, the two substituents of the amino group each are independently a substituted or unsubstituted aryl group, a substituted or unsubstituted heteroaryl group, or a substituted or unsubstituted alkyl group, especially preferably a substituted or unsubstituted aryl group (that is, a diarylamino group). The substituent that the two aryl groups of the diarylamino group can have can be selected, for example, from the substituent group a, or can be selected from the substituent group b, or can be selected from the substituent group c, or can be selected from the substituent group d. The two aryl groups of the diarylamino group can bond to each other via a single bond or a linking group, and for the linking group as referred to herein, reference can be made to the description of the linking group in R³³ and R³⁴. As a specific example of the diarylamino group, for example, a substituted or unsubstituted carbazol-9-yl group can be employed. As the substituted or unsubstituted carbazol-9-yl group, for example, there can be mentioned the group of the general formula (9) where L¹¹ is a single bond.

In one preferred embodiment of the present invention, R¹³ alone in the general formula (17) is a substituent, and R¹¹ R¹² R¹⁴ and R¹⁵ are hydrogen atoms. In one preferred embodiment of the present invention, R¹¹ alone in the general formula (17) is a substituent, and R¹² R¹³ R¹⁴ and R¹⁵ are hydrogen atoms. In one preferred embodiment of the present invention, R¹¹ and R¹³ alone in the general formula (17) each are a substituent, and R¹², R¹⁴ and R¹⁵ are hydrogen atoms.

R¹ to R⁷ in the general formula (16) can include a group of the general formula (17) where R¹¹ to R¹⁵ are all hydrogen atoms (that is, a phenyl group). For example, R², R⁴ and R⁶ can be a phenyl group.

In the general formula (16), preferably, R⁸ and R⁹ each are one group selected from the group consisting of a hydrogen atom, a deuterium atom, a halogen atom, an alkyl group (for example, having 1 to 40 carbon atoms), an alkoxy group (for example, having 1 to 40 carbon atoms), an aryloxy group (for example, having 6 to 30 carbon atoms) and a cyano group, or a group of a combination of two or more these groups. In one preferred embodiment of the present invention, R⁸ and R⁹ are the same. In one preferred embodiment of the present invention, R⁸ and R⁹ each are a halogen atom, especially preferably a fluorine atom.

Preferred compounds usable as the third organic compound are shown below. In the structural formulae of the following exemplary compounds, t-Bu represents a tertiary butyl group.

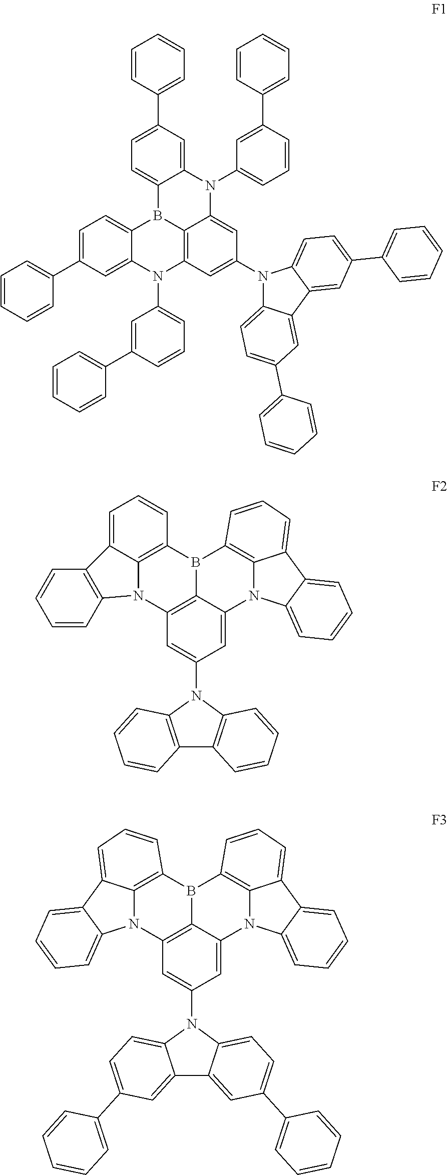 [SMILES: c1ccc(-c2cccc(N3c4cc(-c5ccccc5)ccc4B4c5ccc(-c6ccccc6)cc5N(c5cccc(-c6ccccc6)c5)c5cc(-n6c7ccc(-c8ccccc8)cc7c7cc(-c8ccccc8)ccc76)cc3c54)c2)cc1 ; c1ccc2c(c1)c1ccccc1n2-c1cc2c3c(c1)-n1c4ccccc4c4cccc(c41)B3c1cccc3c4ccccc4n-2c13 ; c1ccc(-c2ccc3c(c2)c2cc(-c4ccccc4)ccc2n3-c2cc3c4c(c2)-n2c5ccccc5c5cccc(c52)B4c2cccc4c5ccccc5n-3c24)cc1]

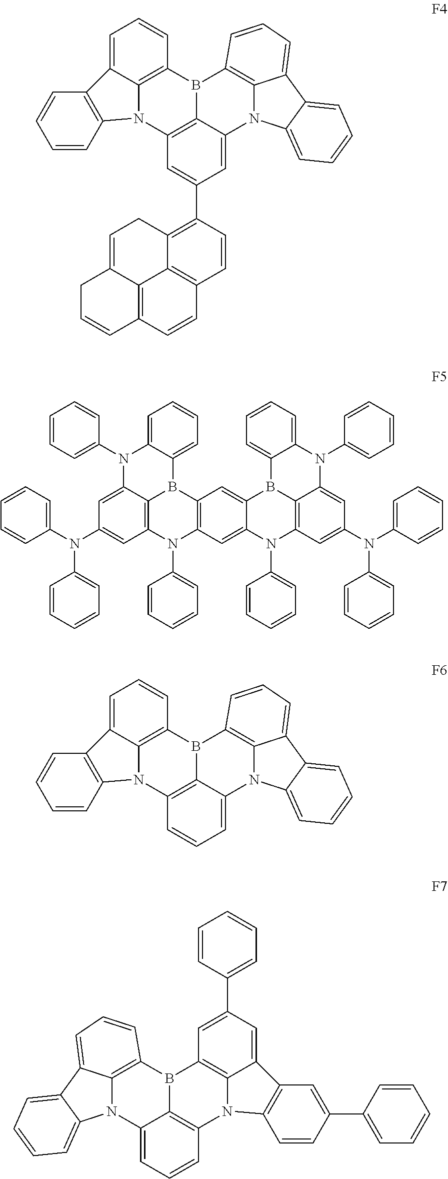 [SMILES: C1=Cc2ccc3ccc(-c4cc5c6c(c4)-n4c7ccccc7c7cccc(c74)B6c4cccc6c7ccccc7n-5c46)c4c3c2C(=CC4)C1 ; c1ccc(N(c2ccccc2)c2cc3c4c(c2)N(c2ccccc2)c2cc5c(cc2B4c2ccccc2N3c2ccccc2)B2c3ccccc3N(c3ccccc3)c3cc(N(c4ccccc4)c4ccccc4)cc(c32)N5c2ccccc2)cc1 ; c1cc2c3c(c1)-n1c4ccccc4c4cccc(c41)B3c1cccc3c4ccccc4n-2c13 ; c1ccc(-c2ccc3c(c2)c2cc(-c4ccccc4)cc4c2n3-c2cccc3c2B4c2cccc4c5ccccc5n-3c24)cc1]

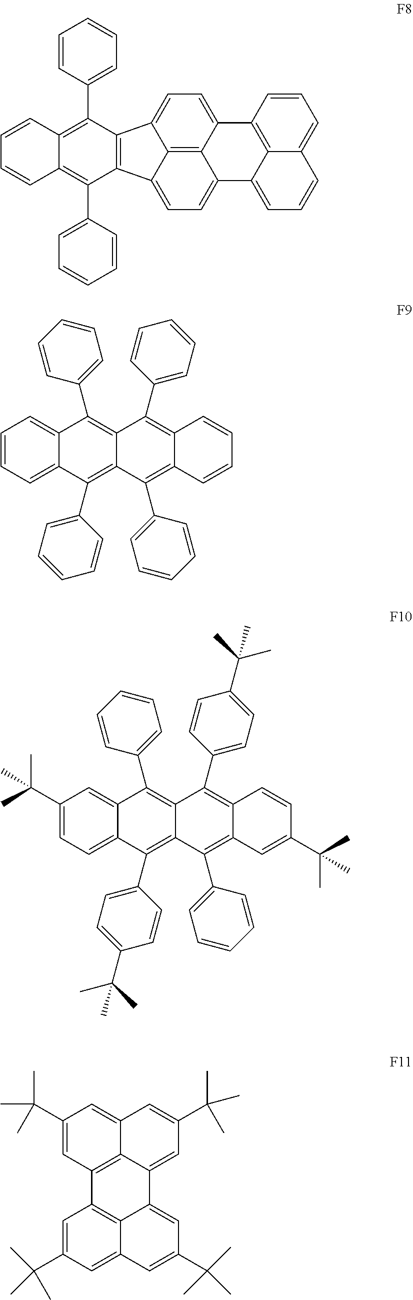

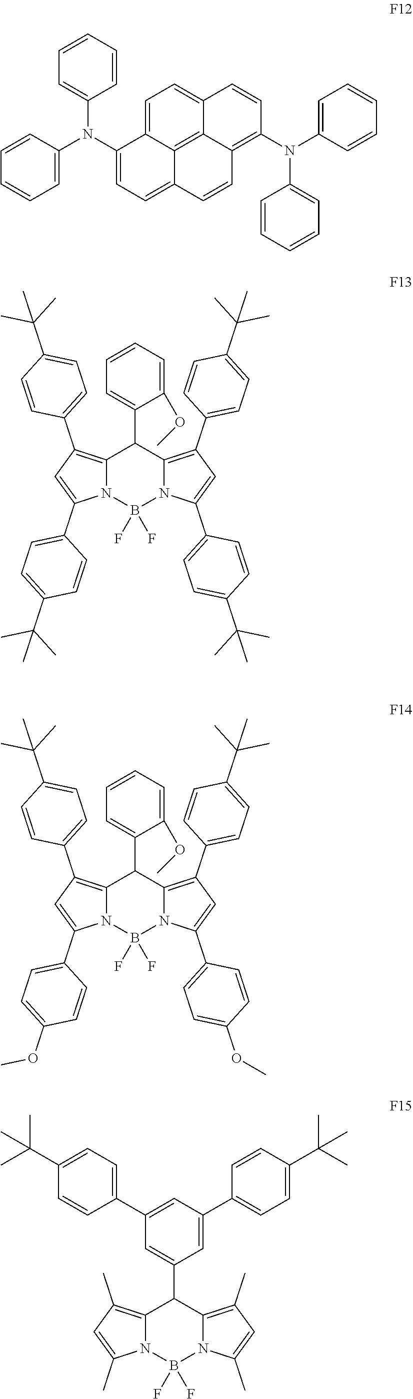

Derivatives of the above exemplary compounds include compounds where at least one hydrogen atom is substituted with a deuterium atom, an alkyl group, an aryl group, a heteroaryl group or a diarylamino group.

Also compounds described in WO2015/022974, paragraphs 0220 to 0239, and in WO2021/015177, paragraphs 0196 to 0255 are especially preferably usable as the third organic compound in the present invention.

Unless otherwise specifically indicated, the alkyl group, the alkenyl group, the aryl group, the heteroaryl group, the arylene group and the heteroarylene group in this description are as mentioned below.

“Alkyl group” can be linear, branched or cyclic. Two or more of a linear moiety, a cyclic moiety and a branched moiety can be in the group as mixed. The carbon number of the alkyl group can be, for example, 1 or more, 2 or more, or 4 or more. The carbon number can also be 30 or less, 20 or less, 10 or less, 6 or less, or 4 or less. Specific examples of the alkyl group include a methyl group, an ethyl group, an n-propyl group, an isopropyl group, an n-butyl group, an isobutyl group, a tert-butyl group, an n-pentyl group, an isopentyl group, an n-hexyl group, an isohexyl group, a 2-ethylhexyl group, an n-heptyl group, an isoheptyl group, an n-octyl group, an isooctyl group, an n-nonyl group, an isononyl group, an n-decanyl group, an isodecanyl group, a cyclopentyl group, a cyclohexyl group, and a cycloheptyl group. The alkyl group of a substituent can be further substituted with an aryl group. For the alkyl moiety of “alkoxy group”, “alkylthio group”, “acyl group” and “alkoxycarbonyl group”, reference can be made to the description of “alkyl group” herein.

“Alkenyl group” can be linear, branched or cyclic. Two or more of a linear moiety, a cyclic moiety and a branched moiety can be in the group as mixed. The carbon number of the alkenyl group can be, for example, 2 or more, or 4 or more. The carbon number can also be 30 or less, 20 or less, 10 or less, 6 or less, or 4 or less. Specific examples of the alkenyl group include an ethenyl group, an n-propenyl group, an isopropenyl group, an n-butenyl group, an isobutenyl group, an n-pentenyl group, an isopentenyl group, an n-hexenyl group, an isohexenyl group, and a 2-ethylhexenyl group. The alkenyl group to be a substituent can be further substituted with a substituent.

“Aryl group” and “Heteroaryl group” each can be a single ring or can be a condensed ring of two or more kinds of rings. In the case of a condensed ring, the number of the rings that are condensed is preferably 2 to 6, and, for example, can be selected from 2 to 4. Specific examples of the ring include a benzene ring, a pyridine ring, a pyrimidine ring, a triazine ring, a naphthalene ring, an anthracene ring, a phenanthrene ring, a triphenylene ring, a quinoline ring, a pyrazine ring, a quinoxaline ring, and a naphthyridine ring. Specific examples of the aryl group or the heteroaryl group include a phenyl group, a 1-naphthyl group, a 2-naphthyl group, a 1-anthracenyl group, a 2-anthracenyl group, a 9-anthracenyl group, a 2-pyridyl group, a 3-pyridyl group, and a 4-pyridyl group. For “arylene group” and “heteroarylene group”, the valance of the aryl group and the heteroaryl group is exchanged from 1 to 2, and the thus-exchanged description can be referred to. For the aryl moiety of “aryloxy group”, “arylthio group” and “aryloxycarbonyl group”, reference can be made to the description of “aryl group” herein. For the heteroaryl moiety of “heteroaryloxy group” “heteroarylthio group” and “heteroaryloxycarbonyl group”, reference can be made to the description of “heteroaryl group” herein.

### (Light Emitting Layer)

The light emitting layer in the organic electroluminescent device of the present invention is formed of a light emitting composition containing the first organic compound, the second organic compound of a delayed fluorescent material and the third organic compound satisfying the formula (a) and the formula (b). In a preferred embodiment of the present invention, the light emitting layer does not contain a compound and a metal element for transmitting and receiving charge or energy, in addition to the first organic compound, the second organic compound and the third organic compound. The light emitting layer can be composed of the first organic compound, the second organic compound and the third organic compound alone. The light emitting layer can be composed of a compound alone that consists of atoms selected from the group consisting of a carbon atom, a hydrogen atom, a nitrogen atom, a boron atom, an oxygen atom and a sulfur atom. For example, the light emitting layer can be composed of a compound alone that consists of atoms selected from the group consisting of a carbon atom, a hydrogen atom, a nitrogen atom, a boron atom, and an oxygen atom. In a preferred embodiment of the present invention, the light emitting layer contains a carbon atom, a hydrogen atom, a nitrogen atom, a boron atom and an oxygen atom, and further preferably does not contain any other atom than these.

The light emitting layer can be formed in a wet process or in a dry process using a light emitting composition containing the first organic compound, the second organic compound of a delayed fluorescent material and the third organic compound satisfying the formula (a) and the formula (b).

In a wet process, a solution prepared by dissolving the light emitting composition is applied onto a surface, and the solvent used is removed to form a light emitting layer. The wet process includes a spin coating method, a slit coating method, an inkjet method (spray method), a gravure printing method, an offset printing method, and a flexographic printing method, but is not limited to these. In the wet process, a suitable organic solvent capable of dissolving the light emitting composition is selected and used. In some embodiments, a substituent (for example, an alkyl group) capable of increasing the solubility in an organic solvent can be introduced into the compound contained in the light emitting composition.

As a dry process, a vacuum evaporation method can be preferably employed. In the case where a vacuum evaporation method is employed, the compounds constituting the light emitting layer can be co-evaporated from individual evaporation sources, or can be co-evaporated from a single evaporation source prepared by mixing all the compounds. In the case where a single evaporation source is used, a mixed powder prepared by mixing powders of all the compounds can be used, or a compressed-molded article prepared by compression-molding the mixed powder can be used, or a mixture prepared by heating, meting and mixing the compounds and then cooling the resultant mixture can be used. In some embodiments, plural compounds contained in a single evaporation source is co-evaporated under the condition that the evaporation speed (weight reducing speed) is the same or is nearly the same between the plural compounds to thereby form a light emitting layer having a compositional ratio corresponding to the compositional ratio of the plural compounds contained in the evaporation source. When plural compounds are mixed to prepare an evaporation source in the same compositional ratio as the compositional ratio of the light emitting layer to be formed, a light emitting layer having a desired compositional ratio can be formed in a simple manner. In some embodiments, a temperature at which the compounds to be co-evaporated could have the same weight reduction rate is specifically defined, and the temperature can be employed as the temperature for co-evaporation. In the case where a light emitting layer is formed in an evaporation method, the molecular weight of the first organic compound, the second organic compound and the third organic compound each is preferably 1500 or less, more preferably 1200 or less, even more preferably 1000 or less, further more preferably 900 or less. The lower limit of the molecular weight can be, for example, 200, or can be 400, or can be 600.

### (Layer Configuration of Organic Electroluminescent Device)

By forming a light emitting layer of the light emitting composition containing the first organic compound, the second organic compound of a delayed fluorescent material and the third organic compound satisfying the formula (a) and the formula (b), there can be provided an excellent organic light emitting device such as an organic photoluminescent device (organic PL device) and an organic electroluminescent device (organic EL device).

The thickness of the light emitting layer can be, for example, 1 to 15 nm, or can be 2 to 10 nm, or can be 3 to 7 nm.

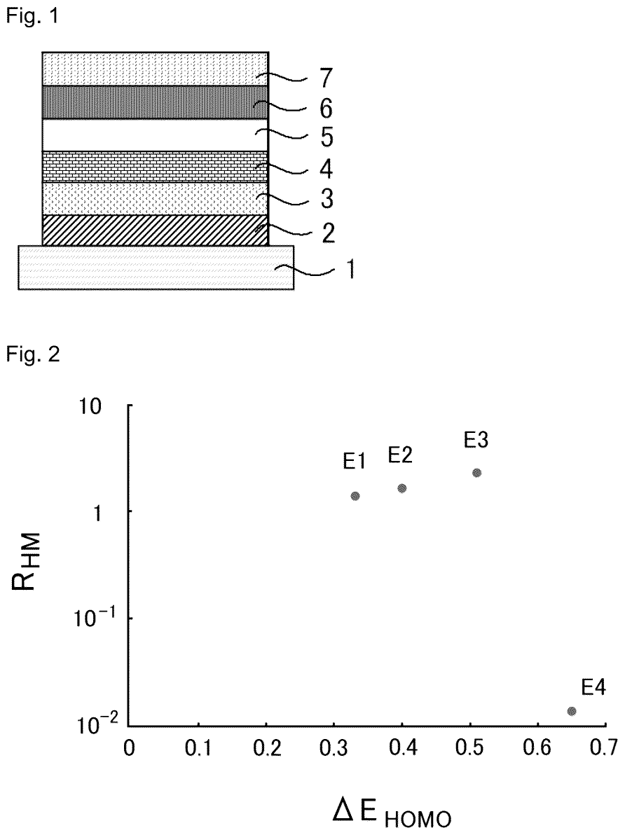

An organic photoluminescent device has a configuration that has at least a light emitting layer formed on a substrate. An organic electroluminescent device has a configuration that has at least an anode, a cathode, and an organic layer formed between the anode and the cathode. The organic layer contains at least a light emitting layer, and can be a light emitting layer alone, or can have any other one or more organic layers than a light emitting layer. Such other organic layers include a hole transporting layer, a hole injection layer, an electron barrier layer, a hole barrier layer, an electron injection layer, an electron transporting layer, and an exciton barrier layer. The hole transporting layer may also be a hole injection transporting layer having a hole injection function, and the electron transporting layer may also be an electron injection transporting layer having an electron injection function. A specific configuration example of an organic electroluminescent device is shown in FIG. 1. In FIG. 1, 1 is a substrate, 2 is an anode, 3 is a hole injection layer, 4 is a hole transporting layer, 5 is a light emitting layer, 6 is an electron transporting layer, and 7 is a cathode.

In the case where the organic electroluminescent device of the present invention is a multi-wavelength emission-type organic electroluminescent device, the device can be so designed that the shortest wavelength emission contains delayed fluorescence. The device can be so designed that the shortest wavelength emission does not contain delayed fluorescence.

The organic electroluminescent device formed of a light emitting composition, which contains the first organic compound, the second organic compound of a delayed fluorescent material and the third organic compound satisfying the formula (a) and the formula (b), is, when excited by a thermal or electronic means, able to emit light in a UV region, or light in a blue, green, yellow, orange or red region in a visible spectral region (e.g., 420 to 500 nm, 500 to 600 nm or 600 to 700 nm) or light in a near IR region. For example, the organic electroluminescent device can emit light in a red or orange region (e.g., 620 to 780 nm). For example, the organic electroluminescent device can emit light in an orange or yellow region (e.g., 570 to 620 nm). For example, the organic electroluminescent device can emit light in a green region (e.g., 490 to 575 nm). For example, the organic electroluminescent device can emit light in a blue region (e.g., 400 to 490 nm). For example, the organic electroluminescent device can emit light in a UV spectral region (e.g., 280 to 400 nm). For example, the organic electroluminescent device can emit light in an IR spectral region (e.g., 780 to 2 μm). In a preferred embodiment of the present invention, the maximum emission wavelength of the device is longer than 570 nm (for example, 570 to 780 nm).

In the following, the constituent members and the other layers than the light emitting layer of the organic electroluminescent device are described.

### Substrate:

In some embodiments, the organic electroluminescent device of the invention is supported by a substrate, wherein the substrate is not particularly limited and may be any of those that have been commonly used in an organic electroluminescent device, for example those formed of glass, transparent plastics, quartz and silicon.

### Anode

In some embodiments, the anode of the organic electroluminescent device is made of a metal, an alloy, an electroconductive compound, or a combination thereof. In some embodiments, the metal, alloy, or electroconductive compound has a large work function (4 eV or more). In some embodiments, the metal is Au. In some embodiments, the electroconductive transparent material is selected from CuI, indium tin oxide (ITO), SnO₂, and ZnO. In some embodiments, an amorphous material capable of forming a transparent electroconductive film, such as IDIXO (In₂O₃—ZnO), is be used. In some embodiments, the anode is a thin film. In some embodiments the thin film is made by vapor deposition or sputtering. In some embodiments, the film is patterned by a photolithography method. In some embodiments, where the pattern may not require high accuracy (for example, approximately 100 μm or more), the pattern may be formed with a mask having a desired shape on vapor deposition or sputtering of the electrode material. In some embodiments, when a material can be applied as a coating, such as an organic electroconductive compound, a wet film forming method, such as a printing method and a coating method is used. In some embodiments, when the emitted light goes through the anode, the anode has a transmittance of more than 10%, and the anode has a sheet resistance of several hundred Ohm per square or less. In some embodiments, the thickness of the anode is from 10 to 1,000 nm. In some embodiments, the thickness of the anode is from 10 to 200 nm. In some embodiments, the thickness of the anode varies depending on the material used.

### Cathode

In some embodiments, the cathode is made of an electrode material a metal having a small work function (4 eV or less) (referred to as an electron injection metal), an alloy, an electroconductive compound, or a combination thereof. In some embodiments, the electrode material is selected from sodium, a sodium-potassium alloy, magnesium, lithium, a magnesium-cupper mixture, a magnesium-silver mixture, a magnesium-aluminum mixture, a magnesium-indium mixture, an aluminum-aluminum oxide (Al₂O₃) mixture, indium, a lithium-aluminum mixture, and a rare earth metal. In some embodiments, a mixture of an electron injection metal and a second metal that is a stable metal having a larger work function than the electron injection metal is used. In some embodiments, the mixture is selected from a magnesium-silver mixture, a magnesium-aluminum mixture, a magnesium-indium mixture, an aluminum-aluminum oxide (Al₂O₃) mixture, a lithium-aluminum mixture, and aluminum. In some embodiments, the mixture increases the electron injection property and the durability against oxidation. In some embodiments, the cathode is produced by forming the electrode material into a thin film by vapor deposition or sputtering. In some embodiments, the cathode has a sheet resistance of several hundred Ohm per square or less. In some embodiments, the thickness of the cathode ranges from 10 nm to 5 μm. In some embodiments, the thickness of the cathode ranges from 50 to 200 nm. In some embodiments, for transmitting the emitted light, any one of the anode and the cathode of the organic electroluminescent device is transparent or translucent. In some embodiments, the transparent or translucent electroluminescent devices enhances the light emission luminance.

In some embodiments, the cathode is formed with an electroconductive transparent material, as described for the anode, to form a transparent or translucent cathode. In some embodiments, a device comprises an anode and a cathode, both being transparent or translucent.

### Injection Layer

An injection layer is a layer between the electrode and the organic layer. In some embodiments, the injection layer decreases the driving voltage and enhances the light emission luminance. In some embodiments the injection layer includes a hole injection layer and an electron injection layer. The injection layer can be positioned between the anode and the light emitting layer or the hole transporting layer, and between the cathode and the light emitting layer or the electron transporting layer. In some embodiments, an injection layer is present. In some embodiments, no injection layer is present.

Preferred compound examples for use as a hole injection material are shown below.

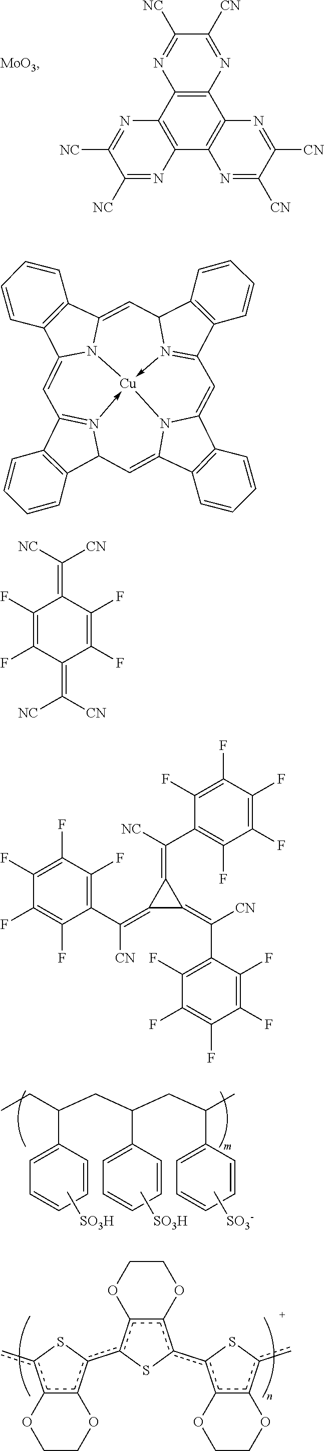

Next, preferred compound examples for use as an electron injection material are shown below.

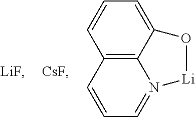

### Barrier Layer

A barrier layer is a layer capable of inhibiting charges (electrons or holes) and/or excitons present in the light emitting layer from being diffused outside the light emitting layer. In some embodiments, the electron barrier layer is between the light emitting layer and the hole transporting layer, and inhibits electrons from passing through the light emitting layer toward the hole transporting layer. In some embodiments, the hole barrier layer is between the light emitting layer and the electron transporting layer, and inhibits holes from passing through the light emitting layer toward the electron transporting layer. In some embodiments, the barrier layer inhibits excitons from being diffused outside the light emitting layer. In some embodiments, the electron barrier layer and the hole barrier layer are exciton barrier layers. As used herein, the term “electron barrier layer” or “exciton barrier layer” includes a layer that has the functions of both electron barrier layer and of an exciton barrier layer.

### Hole Barrier Layer

A hole barrier layer acts as an electron transporting layer. In some embodiments, the hole barrier layer inhibits holes from reaching the electron transporting layer while transporting electrons. In some embodiments, the hole barrier layer enhances the recombination probability of electrons and holes in the light emitting layer. The material for the hole barrier layer may be the same materials as the ones described for the electron transporting layer.

Preferred compound examples for use for the hole barrier layer are shown below.

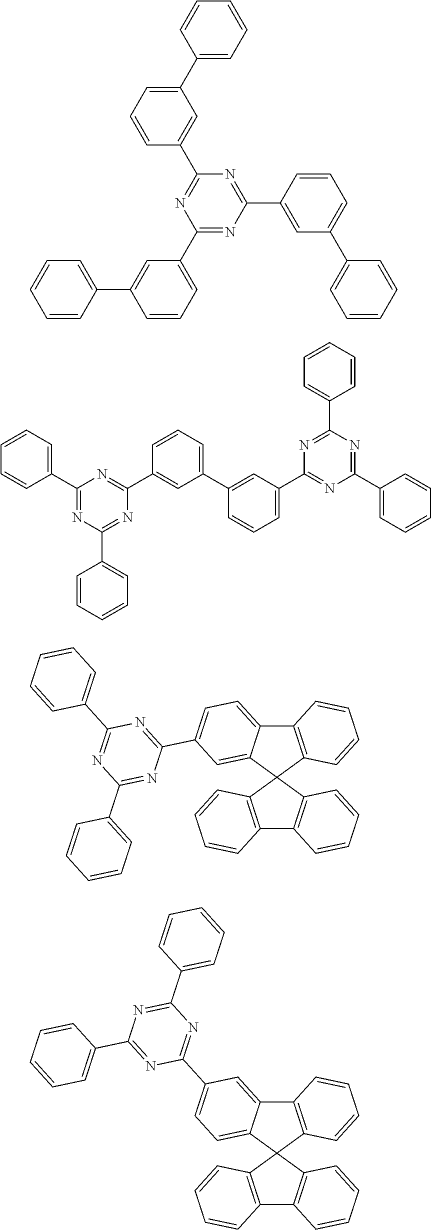

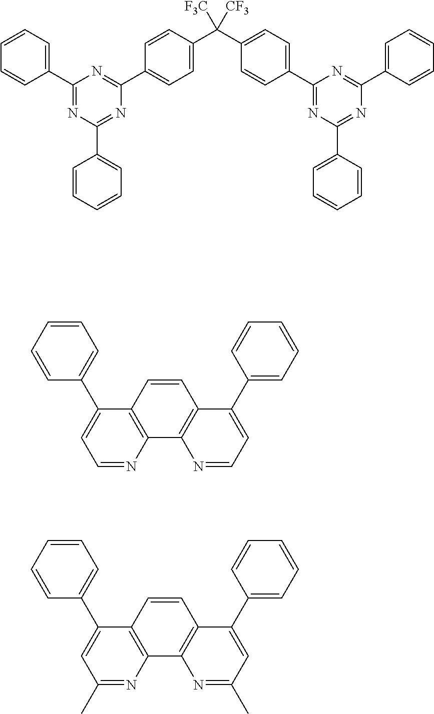 [SMILES: FC(F)(F)C(c1ccc(-c2nc(-c3ccccc3)nc(-c3ccccc3)n2)cc1)(c1ccc(-c2nc(-c3ccccc3)nc(-c3ccccc3)n2)cc1)C(F)(F)F ; c1ccc(-c2ccnc3c2ccc2c(-c4ccccc4)ccnc23)cc1 ; Cc1cc(-c2ccccc2)c2ccc3c(-c4ccccc4)cc(C)nc3c2n1]

### Electron Barrier Layer

As electron barrier layer transports holes. In some embodiments, the electron barrier layer inhibits electrons from reaching the hole transporting layer while transporting holes. In some embodiments, the electron barrier layer enhances the recombination probability of electrons and holes in the light emitting layer.

Preferred compound examples for use as the electron barrier material are shown below.

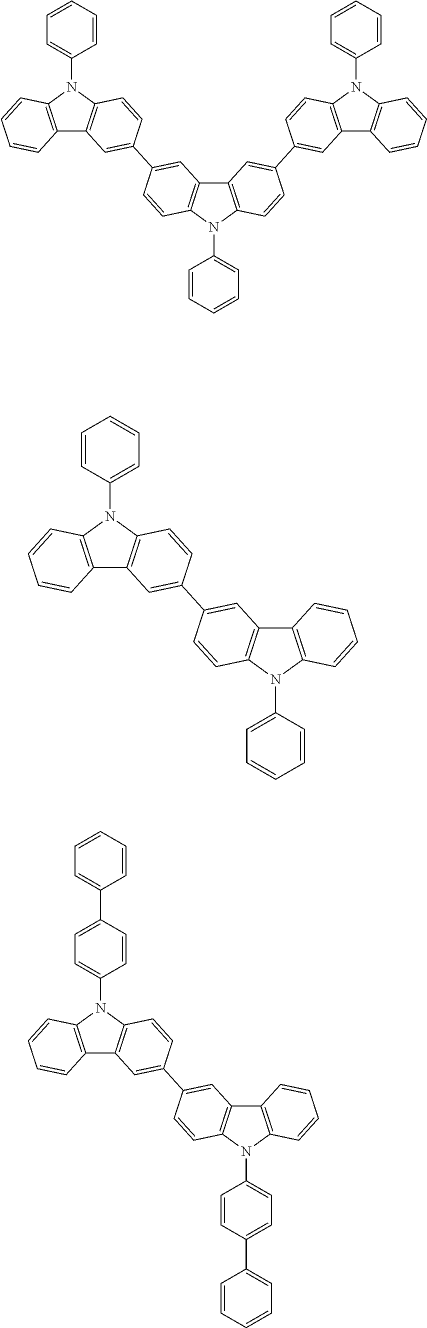 [SMILES: c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1 ; c1ccc(-n2c3ccccc3c3cc(-c4ccc5c(c4)c4ccccc4n5-c4ccccc4)ccc32)cc1 ; c1ccc(-c2ccc(-n3c4ccccc4c4cc(-c5ccc6c(c5)c5ccccc5n6-c5ccc(-c6ccccc6)cc5)ccc43)cc2)cc1]

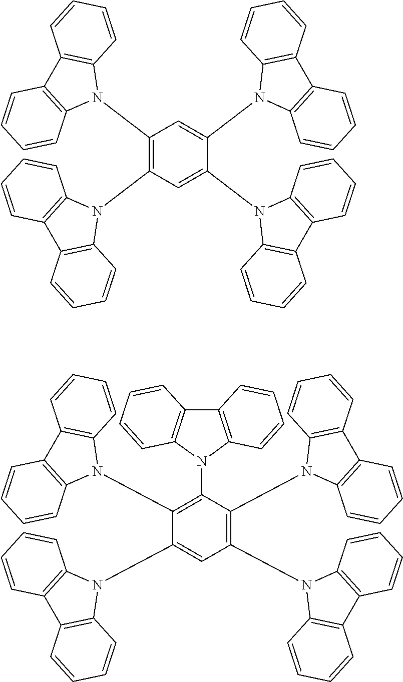 [SMILES: c1ccc2c(c1)c1ccccc1n2-c1cc(-n2c3ccccc3c3ccccc32)c(-n2c3ccccc3c3ccccc32)cc1-n1c2ccccc2c2ccccc21 ; c1ccc2c(c1)c1ccccc1n2-c1cc(-n2c3ccccc3c3ccccc32)c(-n2c3ccccc3c3ccccc32)c(-n2c3ccccc3c3ccccc32)c1-n1c2ccccc2c2ccccc21]

### Exciton Barrier Layer

An exciton barrier layer inhibits excitons generated through recombination of holes and electrons in the light emitting layer from being diffused to the charge transporting layer. In some embodiments, the exciton barrier layer enables effective confinement of excitons in the light emitting layer. In some embodiments, the light emission efficiency of the device is enhanced. In some embodiments, the exciton barrier layer is adjacent to the light emitting layer on any of the side of the anode and the side of the cathode, and on both the sides. In some embodiments, where the exciton barrier layer is on the side of the anode, the layer can be between the hole transporting layer and the light emitting layer and adjacent to the light emitting layer. In some embodiments, where the exciton barrier layer is on the side of the cathode, the layer can be between the light emitting layer and the cathode and adjacent to the light emitting layer. In some embodiments, a hole injection layer, an electron barrier layer, or a similar layer is between the anode and the exciton barrier layer that is adjacent to the light emitting layer on the side of the anode. In some embodiments, a hole injection layer, an electron barrier layer, a hole barrier layer, or a similar layer is between the cathode and the exciton barrier layer that is adjacent to the light emitting layer on the side of the cathode. In some embodiments, the exciton barrier layer comprises excited singlet energy and excited triplet energy, at least one of which is higher than the excited singlet energy and the excited triplet energy of the light emitting material, respectively.

### Hole Transporting Layer

The hole transporting layer comprises a hole transporting material. In some embodiments, the hole transporting layer is a single layer. In some embodiments, the hole transporting layer comprises a plurality layers.

In some embodiments, the hole transporting material has one of injection or transporting property of holes and barrier property of electrons. In some embodiments, the hole transporting material is an organic material. In some embodiments, the hole transporting material is an inorganic material. Examples of known hole transporting materials that may be used herein include but are not limited to a triazole derivative, an oxadiazole derivative, an imidazole derivative, a carbazole derivative, an indolocarbazole derivative, a polyarylalkane derivative, a pyrazoline derivative, a pyrazolone derivative, a phenylenediamine derivative, an arylamine derivative, an amino-substituted chalcone derivative, an oxazole derivative, a styrylanthracene derivative, a fluorenone derivative, a hydrazone derivative, a stilbene derivative, a silazane derivative, an aniline copolymer and an electroconductive polymer oligomer, particularly a thiophene oligomer, or a combination thereof. In some embodiments, the hole transporting material is selected from a porphyrin compound, an aromatic tertiary amine compound, and a styrylamine compound. In some embodiments, the hole transporting material is an aromatic tertiary amine compound. Preferred compound examples for use as the hole transporting material are shown below.

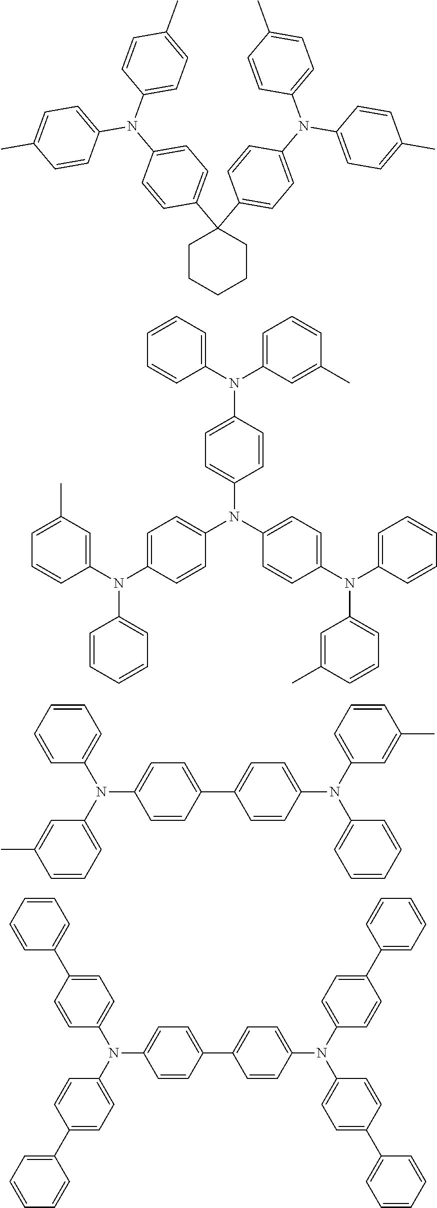

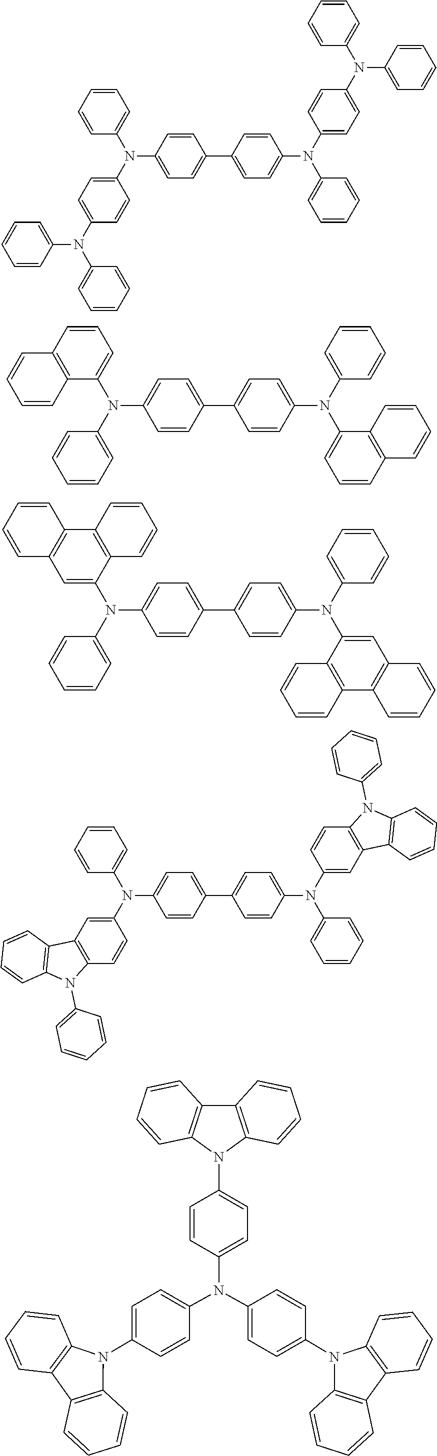

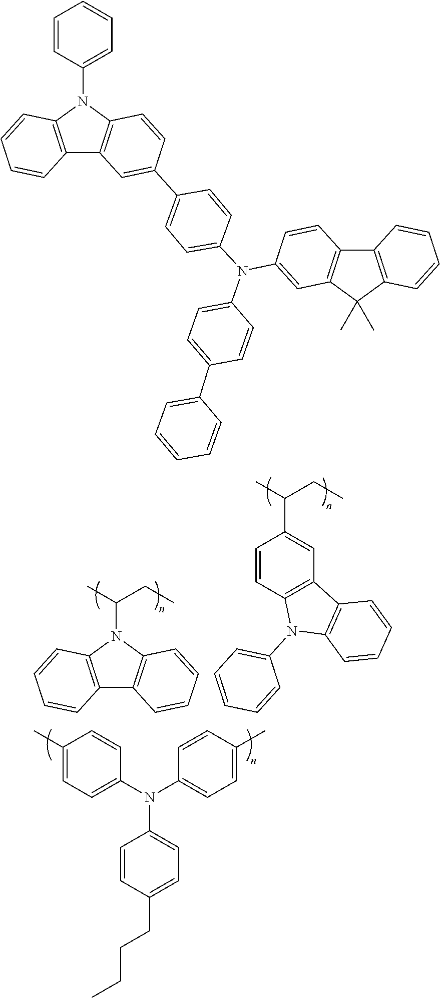

### Electron Transporting Layer

The electron transporting layer comprises an electron transporting material. In some embodiments, the electron transporting layer is a single layer. In some embodiments, the electron transporting layer comprises a plurality of layer.

In some embodiments, the electron transporting material needs only to have a function of transporting electrons, which are injected from the cathode, to the light emitting layer. In some embodiments, the electron transporting material also function as a hole barrier material. Examples of the electron transporting layer that may be used herein include but are not limited to a nitro-substituted fluorene derivative, a diphenylquinone derivative, a thiopyran dioxide derivative, carbodiimide, a fluorenylidene methane derivative, anthraquinodimethane, an anthrone derivatives, an azole derivative, an azine derivative, an oxadiazole derivative, or a combination thereof, or a polymer thereof. In some embodiments, the electron transporting material is a thiadiazole derivative, or a quinoxaline derivative. In some embodiments, the electron transporting material is a polymer material. Preferred compound examples for use as the electron transporting material are shown below.

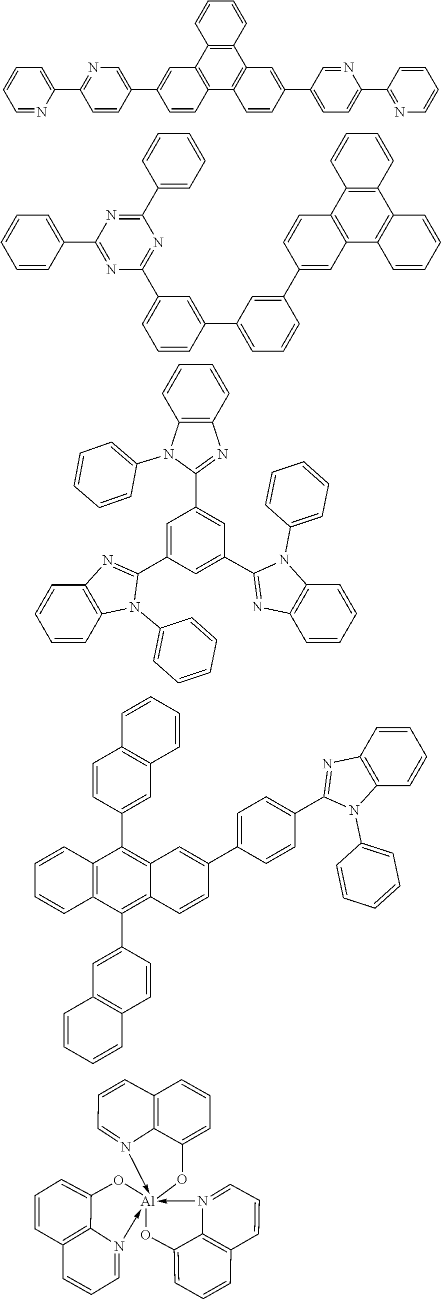

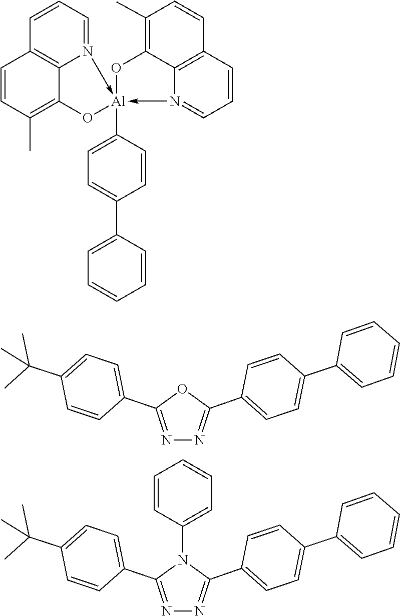

Hereinunder compound examples preferred as a material that can be added to the organic layers are shown. For example, these can be added as a stabilization material.

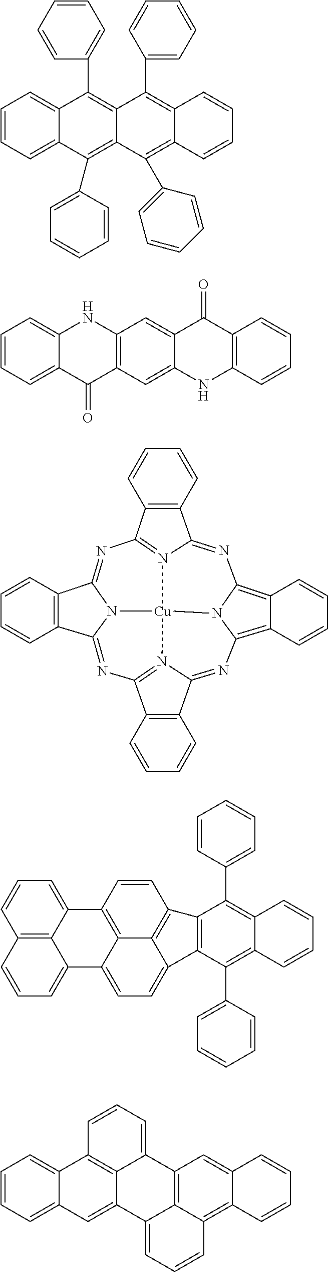

Preferred materials for use in the organic electroluminescent device are specifically shown. However, the materials usable in the invention should not be limitatively interpreted by the following exemplary compounds. Compounds that are exemplified as materials having a specific function can also be used as materials having any other function.

### Devices

In some embodiments, an light emitting layer is incorporated into a device. For example, the device includes, but is not limited to an OLED bulb, an OLED lamp, a television screen, a computer monitor, a mobile phone, and a tablet.

In some embodiments, an electronic device comprises an OLED comprising an anode, a cathode, and at least one organic layer comprising a light emitting layer between the anode and the cathode.

In some embodiments, compositions described herein may be incorporated into various light-sensitive or light-activated devices, such as a OLEDs or photovoltaic devices. In some embodiments, the composition may be useful in facilitating charge transfer or energy transfer within a device and/or as a hole-transport material. The device may be, for example, an organic light emitting diode (OLED), an organic integrated circuit (O—IC), an organic field-effect transistor (O-FET), an organic thin-film transistor (O-TFT), an organic light emitting transistor (O-LET), an organic solar cell (O—SC), an organic optical detector, an organic photoreceptor, an organic field-quench device (O-FQD), a light emitting electrochemical cell (LEC) or an organic laser diode (O-laser).

### Bulbs or Lamps

In some embodiments, an electronic device comprises an OLED comprising an anode, a cathode, and at least one organic layer comprising a light emitting layer between the anode and the cathode.

In some embodiments, a device comprises OLEDs that differ in color. In some embodiments, a device comprises an array comprising a combination of OLEDs. In some embodiments, the combination of OLEDs is a combination of three colors (e.g., RGB). In some embodiments, the combination of OLEDs is a combination of colors that are not red, green, or blue (for example, orange and yellow green). In some embodiments, the combination of OLEDs is a combination of two, four, or more colors.

In some embodiments, a device is an OLED light comprising:
a circuit board having a first side with a mounting surface and an opposing second side, and defining at least one aperture;
at least one OLED on the mounting surface, the at least one OLED configured to emanate light, comprising:
   an anode, a cathode, and at least one organic layer comprising a light emitting layer between the anode and the cathode;
a housing for the circuit board; and
at least one connector arranged at an end of the housing, the housing and the connector defining a package adapted for installation in a light fixture.

In some embodiments, the OLED light comprises a plurality of OLEDs mounted on a circuit board such that light emanates in a plurality of directions. In some embodiments, a portion of the light emanated in a first direction is deflected to emanate in a second direction. In some embodiments, a reflector is used to deflect the light emanated in a first direction.

### Displays or Screens

In some embodiments, the compounds of the invention can be used in a screen or a display. In some embodiments, the compounds of the invention are deposited onto a substrate using a process including, but not limited to, vacuum evaporation, deposition, vapor deposition, or chemical vapor deposition (CVD). In some embodiments, the substrate is a photoplate structure useful in a two-sided etch provides a unique aspect ratio pixel. The screen (which may also be referred to as a mask) is used in a process in the manufacturing of OLED displays. The corresponding artwork pattern design facilitates a very steep and narrow tie-bar between the pixels in the vertical direction and a large, sweeping bevel opening in the horizontal direction. This allows the close patterning of pixels needed for high definition displays while optimizing the chemical deposition onto a TFT backplane.

The internal patterning of the pixel allows the construction of a 3-dimensional pixel opening with varying aspect ratios in the horizontal and vertical directions. Additionally, the use of imaged “stripes” or halftone circles within the pixel area inhibits etching in specific areas until these specific patterns are undercut and fall off the substrate. At that point the entire pixel area is subjected to a similar etch rate but the depths are varying depending on the halftone pattern. Varying the size and spacing of the halftone pattern allows etching to be inhibited at different rates within the pixel allowing for a localized deeper etch needed to create steep vertical bevels.

A preferred material for the deposition mask is invar. Invar is a metal alloy that is cold rolled into long thin sheet in a steel mill. Invar cannot be electrodeposited onto a rotating mandrel as the nickel mask. A preferred and more cost feasible method for forming the open areas in the mask used for deposition is through a wet chemical etching.

In some embodiments, a screen or display pattern is a pixel matrix on a substrate. In some embodiments, a screen or display pattern is fabricated using lithography (e.g., photolithography and e-beam lithography). In some embodiments, a screen or display pattern is fabricated using a wet chemical etch. In further embodiments, a screen or display pattern is fabricated using plasma etching.

### Methods of Manufacturing Devices Using the Disclosed Compounds

An OLED display is generally manufactured by forming a large mother panel and then cutting the mother panel in units of cell panels. In general, each of the cell panels on the mother panel is formed by forming a thin film transistor (TFT) including an active layer and a source/drain electrode on a base substrate, applying a planarization film to the TFT, and sequentially forming a pixel electrode, a light emitting layer, a counter electrode, and an encapsulation layer, and then is cut from the mother panel.

An OLED display is generally manufactured by forming a large mother panel and then cutting the mother panel in units of cell panels. In general, each of the cell panels on the mother panel is formed by forming a thin film transistor (TFT) including an active layer and a source/drain electrode on a base substrate, applying a planarization film to the TFT, and sequentially forming a pixel electrode, a light emitting layer, a counter electrode, and an encapsulation layer, and then is cut from the mother panel.

In another aspect, provided herein is a method of manufacturing an organic light emitting diode (OLED) display, the method comprising:
forming a barrier layer on a base substrate of a mother panel;
forming a plurality of display units in units of cell panels on the barrier layer;
forming an encapsulation layer on each of the display units of the cell panels;
applying an organic film to an interface portion between the cell panels.

In some embodiments, the barrier layer is an inorganic film formed of, for example, SiNx, and an edge portion of the barrier layer is covered with an organic film formed of polyimide or acryl. In some embodiments, the organic film helps the mother panel to be softly cut in units of the cell panel.

In some embodiments, the thin film transistor (TFT) layer includes a light emitting layer, a gate electrode, and a source/drain electrode. Each of the plurality of display units may include a thin film transistor (TFT) layer, a planarization film formed on the TFT layer, and a light emitting unit formed on the planarization film, wherein the organic film applied to the interface portion is formed of a same material as a material of the planarization film and is formed at a same time as the planarization film is formed. In some embodiments, a light emitting unit is connected to the TFT layer with a passivation layer and a planarization film therebetween and an encapsulation layer that covers and protects the light emitting unit. In some embodiments of the method of manufacturing, the organic film contacts neither the display units nor the encapsulation layer.

Each of the organic film and the planarization film may include any one of polyimide and acryl. In some embodiments, the barrier layer may be an inorganic film. In some embodiments, the base substrate may be formed of polyimide. The method may further include, before the forming of the barrier layer on one surface of the base substrate formed of polyimide, attaching a carrier substrate formed of a glass material to another surface of the base substrate, and before the cutting along the interface portion, separating the carrier substrate from the base substrate. In some embodiments, the OLED display is a flexible display.

In some embodiments, the passivation layer is an organic film disposed on the TFT layer to cover the TFT layer. In some embodiments, the planarization film is an organic film formed on the passivation layer. In some embodiments, the planarization film is formed of polyimide or acryl, like the organic film formed on the edge portion of the barrier layer. In some embodiments, the planarization film and the organic film are simultaneously formed when the OLED display is manufactured. In some embodiments, the organic film may be formed on the edge portion of the barrier layer such that a portion of the organic film directly contacts the base substrate and a remaining portion of the organic film contacts the barrier layer while surrounding the edge portion of the barrier layer.

In some embodiments, the light emitting layer includes a pixel electrode, a counter electrode, and an organic light emitting layer disposed between the pixel electrode and the counter electrode. In some embodiments, the pixel electrode is connected to the source/drain electrode of the TFT layer.

In some embodiments, when a voltage is applied to the pixel electrode through the TFT layer, an appropriate voltage is formed between the pixel electrode and the counter electrode, and thus the organic light emitting layer emits light, thereby forming an image. Hereinafter, an image forming unit including the TFT layer and the light emitting unit is referred to as a display unit.

In some embodiments, the encapsulation layer that covers the display unit and prevents penetration of external moisture may be formed to have a thin film encapsulation structure in which an organic film and an inorganic film are alternately stacked. In some embodiments, the encapsulation layer has a thin film encapsulation structure in which a plurality of thin films are stacked. In some embodiments, the organic film applied to the interface portion is spaced apart from each of the plurality of display units. In some embodiments, the organic film is formed such that a portion of the organic film directly contacts the base substrate and a remaining portion of the organic film contacts the barrier layer while surrounding an edge portion of the barrier layer.

In one embodiment, the OLED display is flexible and uses the soft base substrate formed of polyimide. In some embodiments, the base substrate is formed on a carrier substrate formed of a glass material, and then the carrier substrate is separated.

In some embodiments, the barrier layer is formed on a surface of the base substrate opposite to the carrier substrate. In one embodiment, the barrier layer is patterned according to a size of each of the cell panels. For example, while the base substrate is formed over the entire surface of a mother panel, the barrier layer is formed according to a size of each of the cell panels, and thus a groove is formed at an interface portion between the barrier layers of the cell panels. Each of the cell panels can be cut along the groove.

In some embodiments, the method of manufacture further comprises cutting along the interface portion, wherein a groove is formed in the barrier layer, wherein at least a portion of the organic film is formed in the groove, and wherein the groove does not penetrate into the base substrate. In some embodiments, the TFT layer of each of the cell panels is formed, and the passivation layer which is an inorganic film and the planarization film which is an organic film are disposed on the TFT layer to cover the TFT layer. At the same time as the planarization film formed of, for example, polyimide or acryl is formed, the groove at the interface portion is covered with the organic film formed of, for example, polyimide or acryl. This is to prevent cracks from occurring by allowing the organic film to absorb an impact generated when each of the cell panels is cut along the groove at the interface portion. That is, if the entire barrier layer is entirely exposed without the organic film, an impact generated when each of the cell panels is cut along the groove at the interface portion is transferred to the barrier layer, thereby increasing the risk of cracks. However, in one embodiment, since the groove at the interface portion between the barrier layers is covered with the organic film and the organic film absorbs an impact that would otherwise be transferred to the barrier layer, each of the cell panels may be softly cut and cracks may be prevented from occurring in the barrier layer. In one embodiment, the organic film covering the groove at the interface portion and the planarization film are spaced apart from each other. For example, if the organic film and the planarization film are connected to each other as one layer, since external moisture may penetrate into the display unit through the planarization film and a portion where the organic film remains, the organic film and the planarization film are spaced apart from each other such that the organic film is spaced apart from the display unit.

In some embodiments, the display unit is formed by forming the light emitting unit, and the encapsulation layer is disposed on the display unit to cover the display unit. As such, once the mother panel is completely manufactured, the carrier substrate that supports the base substrate is separated from the base substrate. In some embodiments, when a laser beam is emitted toward the carrier substrate, the carrier substrate is separated from the base substrate due to a difference in a thermal expansion coefficient between the carrier substrate and the base substrate.

In some embodiments, the mother panel is cut in units of the cell panels. In some embodiments, the mother panel is cut along an interface portion between the cell panels by using a cutter. In some embodiments, since the groove at the interface portion along which the mother panel is cut is covered with the organic film, the organic film absorbs an impact during the cutting. In some embodiments, cracks may be prevented from occurring in the barrier layer during the cutting.

In some embodiments, the methods reduce a defect rate of a product and stabilize its quality.

Another aspect is an OLED display including: a barrier layer that is formed on a base substrate; a display unit that is formed on the barrier layer; an encapsulation layer that is formed on the display unit; and an organic film that is applied to an edge portion of the barrier layer.

### (Design Method for Light Emitting Composition)

The present application also provides a method for designing a light emitting composition usable for the light emitting layer of an organic electroluminescent device. According to the design method of the present invention, there can be readily designed a light emitting composition for use for the light emitting layer of a light emitting device having a long emission lifetime and excellent in stability.

The design method for a light emitting composition of the present invention includes the following steps 1 to 3:
[Step 1] evaluating the emission lifetime of a composition containing a first organic compound, a second organic compound of a delayed fluorescent material and a third organic compound, and satisfying the above-mentioned formula (a) and formula (b),
[Step 2] carrying out at least once evaluating the emission lifetime of a composition prepared by changing at least one of the first organic compound, the second organic compound of a delayed fluorescent material and the third organic compound within the range satisfying the above-mentioned formula (a) and formula (b),
[Step 3] selecting a combination of compounds providing the best emission lifetime evaluated.

Evaluation of the emission lifetime can be carried out by actually emitting a light emitting composition, or can be carried out by calculation. In addition, evaluation can also be carried out by actually emitting a light emitting composition combined with a calculation method. Preferably, evaluation is carried out from a comprehensive viewpoint using a high level of practicality as an index. In the design method for the light emitting composition of the present invention, it is necessary to select and replace the first organic compound, the second organic compound and the third organic compound within a range satisfying the formula (a) and the formula (b). Also it is necessary to select and replace the second organic compound from a delayed fluorescent material. For the compound replacement in the step 2, preferably, the compound is replaced to another one capable of attaining a more excellent evaluation. The step 2 can be carried out, for example, 10 times or more, 100 times or more, 1000 times or more, or 10000 times or more. In the present invention, the other performance than the emission lifetime can be additionally measured or evaluated. The light emitting composition designed according to the design method of the present invention can be used for the light emitting layer in an organic electroluminescent device (especially for the organic electroluminescent device of the present invention).

The design method for the light emitting composition of the present invention can be stored as a program and can be used as such. The program can be stored on a recording medium and can be transmitted and received by an electronic means.

All matters described in the specification of Japanese Patent Application No. 2020 190698 and Japanese Patent Application No. 2021-090608, which are the basis for priority of the present application, and all matters of Adv. Electron. Mater. 2021, 7, 2001090 are hereby incorporated as a part of this description by reference.

### Examples

The features of the present invention will be described more specifically with reference to Experimental Examples, Examples and Synthesis Examples given below. The materials, processes, procedures and the like shown below may be appropriately modified unless they deviate from the substance of the invention. Accordingly, the scope of the present invention is not construed as being limited to the specific examples shown below.

Hereinunder the light emission characteristics were evaluated using a source meter (available from Keithley Instruments Corporation: 2400 series), a semiconductor parameter analyzer (available from Agilent Corporation, E5273A), an optical power meter device (available from Newport Corporation, 1930C), an optical spectroscope (available from Ocean Optics Corporation, USB2000), a spectroradiometer (available from Topcon Corporation, SR-3), and a streak camera (available from Hamamatsu Photonics K.K., Model C4334).

### (Experimental Example) Measurement of Hole Mobility

On a glass substrate having, as formed thereon, an anode of indium tin oxide (ITO) having a film thickness of 50 nm, the following thin films were laminated according to a vacuum evaporation method at a vacuum degree of 5.0×10⁻⁵ Pa to produce a device for measurement of hole mobility.

First, on ITO, HAT-CN was deposited at a thickness of 10 nm. Next, the first organic compound, the second organic compound and the third organic compound were co-deposited from different evaporation sources to form a layer having a thickness of 100 nm. At that time, the compounds were so co-deposited that the first organic compound accounted for 69.5% by weight, the second organic compound for 30% by weight, and the third organic compound for 0.5% by weight. Next, aluminum (Al) was deposited at a thickness of 100 nm to form a cathode, thereby producing a device for measurement of hole mobility. A different device for measurement of hole mobility was produced in the same manner as above except that the third organic compound was not used. The devices were measured for the hole mobility, and (hole mobility of the device using the third organic compound)/(hole mobility of device not using the third organic compound) was calculated. The result is referred to as a hole mobility ratio R_{HM}.

In the devices, H1 was used for the first organic compound, T1 was for the second organic compound, and the compound shown in Table 1 was for the third organic compound. Table 1 shows the HOMO energy of the third organic compound E_{HOMO}(3), the LUMO energy E_{LUMO}(3), the lowest excited singlet energy E_{S1}(3), the lowest excited triplet energy E_{T1}(3), and the difference between the excited singlet energy and the excited triplet energy ΔE_{ST}. The HOMO energy of T1 used as the second organic compound is −6.01 eV, and therefore the HOMO energy difference ΔE_{HOMO} between the third organic compound and the second organic compound in the devices using the third organic compound can be calculated. In FIG. 2, the relationship between the hole mobility ratio R_{HM} and the HOMO energy difference between the third organic compound and the second organic compound ΔE_{HOMO} was plotted. The results in FIG. 2 show that when the HOMO energy difference between the third organic compound and the second organic compound ΔE_{HOMO} has reached 0.65 eV or more, the hole mobility greatly lowers. Namely, it is confirmed that when ΔE_{HOMO} is 0.65 eV or more, the hole mobility lowers owing to trap site formation by the third organic compound.

TABLE 1

| | E_{HOMO} | E_{LUMO} | E_{S1} | E_{T1} | ΔE_{ST} |
|---|---|---|---|---|---|
| | (eV) | (eV) | (eV) | (eV) | (eV) |
| F1 | −5.68 | −3.04 | 2.75 | 2.48 | 0.27 |
| F2 | −5.61 | −3.00 | 2.66 | 2.40 | 0.24 |
| F3 | −5.50 | −3.00 | 2.58 | 2.41 | 0.17 |
| F4 | −5.36 | −2.76 | 2.69 | 2.60 | 0.09 |

### Examples 1 to 2, Comparative Example 1

Organic electroluminescent devices were produced and evaluated.

On a glass substrate having, as formed thereon, an anode of indium tin oxide (ITO) having a film thickness of 50 nm, the following thin films were laminated at a vacuum degree of 5.0×10^{0.5} Pa in a vacuum evaporation method to produce an organic electroluminescent device.

First, on the ITO, HAT-CN was formed at a thickness of 10 nm, then NPD was formed thereon at a thickness of 30 nm. Next, Tris-PCz was formed at a thickness of 10 nm, and EB1 was formed thereon at a thickness of 5 nm. Next, the first organic compound, the second organic compound and the third organic compound were co-deposited from different evaporation sources to form a layer having a thickness of 30 nm to be a light emitting layer. At that time, the compounds were so co-deposited that the first organic compound accounted for 69.5% by weight, the second organic compound for 30% by weight and the third organic compound for 0.5% by weight. Next, SF3-TRZ was formed at a thickness of 10 nm, and then Liq and SF3-TRZ were co-deposited from different evaporation sources to form a layer having thickness of 30 nm. The content of Liq and SF3-TRZ in the layer was 30% by weight and 70% by weight, respectively. Further, Liq was formed at a thickness of 2 nm, and then aluminum (Al) was deposited at a thickness of 100 nm to form a cathode, thereby producing an organic electroluminescent device.

The compounds shown in Table 2 were used as the first organic compound, the second organic compound and the third organic compound to produce organic electroluminescent devices of Examples 1 to 2 and Comparative Example 1.

Other organic electroluminescent devices corresponding to Examples 1 to 2 and Comparative Example 1 were produced in the same manner as above except that the third organic compound was not added, and it was measured how many times LT95 of the device containing the third organic compound was that of the device not containing the third organic compound. LT95 is a time taken until the emission intensity reaches 95% that at the start of light emission. The results are shown in Table 2 as a relative value based on the value 1, of the device of Comparative Example 1. Table 2 also shows the found data of the lowest excited singlet energy of each organic compound E_{S1}, the maximum emission wavelength and the ionization energy.

### Example 3

In Example 3, an organic electroluminescent device was produced using two delayed fluorescent materials as the second organic compound.

An organic electroluminescent device was produced in the same manner as in Example 1, except that the light emitting layer was formed by co-deposition of a compound H2 in an amount of 68.5% by weight as the first organic compound, a compound T133 in an amount of 30% by weight and a compound T33 in an amount of 1% by weight as the second organic compound, and a compound F4 in an amount of 0.5% by weight as the third organic compound. The results of the same measurement of these devices as in Example 1 are shown in Table 2.

The data of the second organic compound is the data of the compound T133 having a larger content.

TABLE 2

| | | Comparative | | | |
|---|---|---|---|---|---|
| | | Example 1 | Example 1 | Example 2 | Example 3 |
| Materials | First organic compound | H1 | H1 | H1 | H2 |
| used | Second organic compound | T1 | T1 | T2 | T133/T33 |
| | Third organic compound | F4 | F1 | F1 | F4 |
| E_{S1} | First organic compound | 3.69 | 3.69 | 3.69 | 3.69 |
| (eV) | Second organic compound | 2.88 | 2.88 | 2.93 | 2.72 |
| | Third organic compound | 2.69 | 2.75 | 2.75 | 2.69 |
| E_{HOMO}(3) − E_{HOMO}(2) (eV) | | 0.65 | 0.33 | 0.15 | 0.62 |
| Relative value (times) of LT95 | | 1 | 5.2 | 6.2 | 3.3 |
| Emission | Device | 477 | 470 | 470 | 477 |
| maximum | Second organic compound | 500 | 500 | 468 | 486 |
| wavelength | Third organic compound | 477 | 466 | 466 | 477 |
| (nm) | | | | | |
| Ionization | Second organic compound | −1.32 | −1.32 | −1.06 | −1.28 |
| Energy (eV) | Third organic compound | −0.39 | −0.61 | −0.61 | −0.39 |

As obvious from Table 2, it is confirmed that the organic electroluminescent devices of Examples 1 and 2, in which the HOMO energy difference ΔE_{HOMO} between the third organic compound and the second organic compound [that is, E_{HOMO}(3)-E_{HOMO}(2)] is less than 0.65 eV, are stable devices as having a prolonged lifetime, while on the other hand, the organic electroluminescent device of Comparative Example 1 where ΔE_{HOMO} is 0.65 eV is a device having a short lifetime and lacking in stability.

Driven at 10 mA/cm², the organic electroluminescent devices of Examples 1 to 2 and Comparative Example 1 were measured for the voltage change. As compared with Comparative Example 1, the voltage increase in Examples 1 to 2 was suppressed. In addition, Example 1 and Example 2 were compared, and it is confirmed that the voltage increase in the device of Example 1 was suppressed more than in the device of Example 2.

### Example 4

In Example 4, an organic electroluminescent device that differs in the emission mode was produced. Here, a compound H1 was used as the first organic compound, a compound T63 was as the second organic compound, and a compound F was as the third organic compound. The HOMO energy of the compound F is higher than the HOMO energy of the compound T63.

On a 2-mm thick glass substrate having, as formed thereon, an anode of indium tin oxide (ITO) having a film thickness of 50 nm, the following thin films were laminated according to a vacuum evaporation method at a vacuum degree of 1×10⁻⁶ Pa. First, on the ITO, HAT-CN was formed at a thickness of 10 nm, and EB1 was formed thereon at a thickness of 10 nm. Next, the first organic compound (69% by weight), the second organic compound (30% by weight) and the third organic compound (1% by weight) were co-deposited from different evaporation sources to form a light emitting layer having a thickness of 40 nm. Next, HB1 was formed at a thickness of 10 nm, and subsequently, SF3-TRZ and Liq (weight ratio 70/30) was formed at a thickness of 30 nm. Further, Liq was formed at a thickness of 2 nm, and aluminum (Al) was deposited at a thickness of 100 nm to form a cathode. Accordingly, a bottom-emission type organic electroluminescent device was produced.

Apart from the above, on a 2-mm thick glass substrate having, as formed thereon, a multilayer transparent anode of indium tin oxide (ITO) at a film thickness of 10 nm and silver palladium copper alloy (APC) at a thickness of 150 nm, the following thin films were laminated according to a vacuum evaporation method at a vacuum degree of 1×10⁻⁶ Pa. First, on the ITO, HAT-CN was formed at a thickness of 10 nm, and EB1 was formed thereon at a thickness of 10 nm. Next, the first organic compound (69% by weight), the second organic compound (30% by weight) and the third organic compound (1% by weight) were co-deposited from different evaporation sources to form a light emitting layer having a thickness of 40 nm. Next, HB1 was formed at a thickness of 10 nm, and subsequently, SF3-TRZ and Liq (the same weight ratio as in the bottom-emission system) was formed at a thickness of 30 nm. Further, Liq was formed at a thickness of 2 nm. Next, Mg/Ag (weight ratio 1/10) was deposited at a thickness of 15 nm to form a cathode, and further, NPD was deposited at a thickness of 105 nm to form a cap layer. Accordingly, a top-emission type organic electroluminescent device was produced.

The external quantum efficiency (EQE) and the emission peak intensity of the produced organic electroluminescent devices were measured, and the two devices all showed high values. EQE of the top-emission mode was 1.15 times EQE of the bottom-emission mode, and was higher by 27.6% than the latter. In addition, the emission peak intensity of the top-emission mode was 2.98 times that of the bottom-emission mode.

The composition of the light emitting layer was changed to contain the first organic compound (compound H1: 69.5% by weight), the second organic compound (compound H63: 30% by weight) and the third organic compound (compound F: 0.5% by weight), and in the same manner as above except this, a top-emission mode device and a bottom-emission mode device were produced and evaluated. As a result, the produced organic electroluminescent devices had further higher values of the external quantum yield (EQE) and the emission peak intensity. EQE of the top-emission mode was 1.52 times that of the bottom-emission mode, and was higher by 36.4% than the latter. In addition, the emission peak intensity of the top-emission mode was 4.32 times that of the bottom-emission mode.

From the above, it is confirmed that the organic electroluminescent devices satisfying the requirements in the present invention realize high emission efficiency.

In the following, results of further investigations of Compounds 1 to 3 are shown.

### (Synthesis Example 1) Synthesis of Compound 1

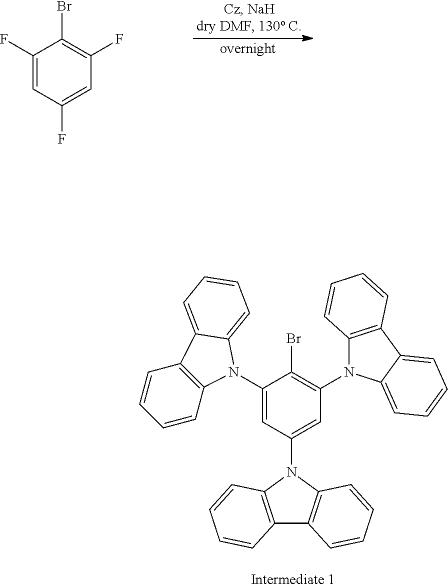 [SMILES: Fc1cc(F)c(Br)c(F)c1 ; Brc1c(-n2c3ccccc3c3ccccc32)cc(-n2c3ccccc3c3ccccc32)cc1-n1c2ccccc2c2ccccc21]

In a nitrogen atmosphere, 9H-carbazole (3.00 g, 17.9 mmol) was added to N,N-dimethylformamide (dewatered) (100 mL) and dissolved therein, and sodium hydride (0.81 g, 20.4 mmol, 60% mineral oil dispersion) was gradually added to the resultant solution and stirred at room temperature for 1 hour. 2-Bromo-1,3,5-trifluorobenzene (1.08 g, 5.1 mmol) was added to the mixture and heated at 120° C. for 16 hours. Water was added to the reaction mixture to stop the reaction, and then the precipitate was separated by filtration. The resultant crude product was purified by flash column chromatography (filler, silica gel) using a mixed solvent of chloroform/hexane=3/7 as a developing solvent to give Intermediate 1 at a yield of 2.17 g, 65%.

¹H NMR (500 MHz, CDCl₃, 298 K, relative to Me4Si): δ=8.19 (d, 4H, J=7.5 Hz), 8.12 (d, 2H, J=7.5 Hz), 8.01 (s, 2H), 7.61 (d, 2H, J=8.0 Hz) 7.54 (t, 4H, J=8.0 Hz), 7.44 (t, 2H, J=8.0 Hz), 7.38-7.35 (m, 8H), 7.32 (t, 2H, J=7.5 Hz). ¹³C NMR (125 MHz, CDCl₃): δ=140.68, 140.64, 139.93, 139.32, 128.77, 126.59, 126.45, 124.12, 123.75, 123.58, 121.18, 120.93, 120.73, 120.71, 109.93, 109.46.

MS (APCI) calcd. for C42H26BrN₃: m/z=651.13; found: 651.06 [M]⁺

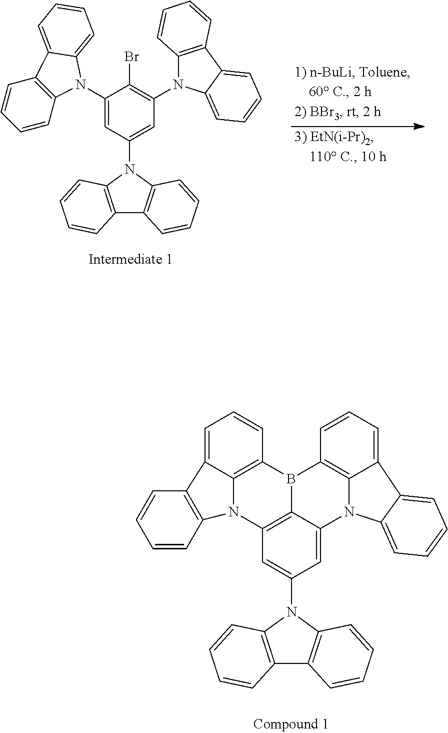 [SMILES: Brc1c(-n2c3ccccc3c3ccccc32)cc(-n2c3ccccc3c3ccccc32)cc1-n1c2ccccc2c2ccccc21 ; c1ccc2c(c1)c1ccccc1n2-c1cc2c3c(c1)-n1c4ccccc4c4cccc(c41)B3c1cccc3c4ccccc4n-2c13]

In a nitrogen atmosphere at −30° C., n-butyllithium (1.15 mL, 1.8 mmol, 1.6 M hexane solution) was gradually added to a dewatered toluene solution (80 mL) in which Intermediate 1 (1.00 g, 1.5 mmol) had been dissolved, then heated up to room temperature, and stirred at 60° C. for 2 hours. Further, boron tribromide (0.18 mL, 1.8 mmol) was added at −15° C., and stirred at room temperature for 2 hours. N,N-diisopropylethylamine (0.53 mL, 3.6 mmol) was added to the mixture at 0° C., heated up to room temperature, and stirred at 110° C. for 10 hours. The reaction mixture was cooled down to room temperature, then an aqueous solution of sodium acetate and ethyl acetate was added, and the precipitated solid was separated by filtration. The resultant crude product was dissolved in warmed toluene, and recrystallized, and then further sublimed to give the intended product, Compound 1 at a yield of 0.30 g, 34%.

¹H NMR (500 MHz, CDCl₃, 298 K, relative to Me4Si): δ=9.09 (d, 2H, J=6.5 Hz), 8.65 (s, 2H), 8.45 (d, 2H, J=7.5 Hz) 8.35 (d, 2H, J=8.5 Hz), 8.29-8.27 (m, 4H), 7.86 (d, 2H, J=8.0 Hz), 7.82 (t, 2H, J=7.5 Hz). 7.56-7.51 (m, 4H), 7.47-7.40 (m, 4H).

MS (APCI) calcd. for C₄₂H₂₄BN₃: m/z=581.21; found: 581.19 [M]⁺.

Elemental analysis calcd. (%) for C₄₂H₂₄BN₃: C 86.75, H 4.16, N 7.23; found: C 86.90, H 4.08, N 7.31.

### (Synthesis Example 2) Synthesis of Compound 2

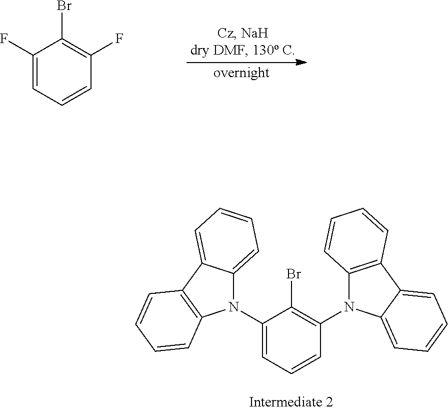 [SMILES: Fc1cccc(F)c1Br ; Brc1c(-n2c3ccccc3c3ccccc32)cccc1-n1c2ccccc2c2ccccc21]

In a nitrogen atmosphere, 9H-carbazole (3.00 g, 17.9 mmol) was added to N,N-dimethylformamide (dewatered) (100 mL) and dissolved therein, and sodium hydride (0.72 g, 53.7 mmol, 60% mineral oil dispersion) was gradually added to the resultant solution and stirred at room temperature for 1 hour. 2-Bromo-1,3-difluorobenzene (1.15 g, 6.0 mmol) was added to the mixture and heated at 130° C. for 18 hours. Water was added to the reaction mixture to stop the reaction, and then the precipitate was separated by filtration. The resultant crude product was purified by flash column chromatography (filler, silica gel) using a mixed solvent of chloroform/hexane=4/6 as a developing solvent to give Intermediate 2 at a yield of 2.38 g, 82%.

¹H NMR (500 MHz, CDCl₃, 298 K, relative to Me4Si): δ=8.18 (t, 4H, J=7.5 Hz), 7.78-7.75 (m, 1H), 7.72-7.70 (m, 2H), 7.48 (t, 4H, J=7.5 Hz), 7.33 (t, 4H, J=8.0 Hz), 7.21 (d, 4H, J=8.5 Hz).

¹³C NMR (125 MHz, CDCl₃): δ=140.78, 139.36, 131.34, 129.52, 126.20, 126.09, 123.52, 120.54, 120.35, 109.96.

MS (APCI) calcd. for C₃₀H₁₉BrN₂: m/z=486.07; found: 486.22 [M]⁺.

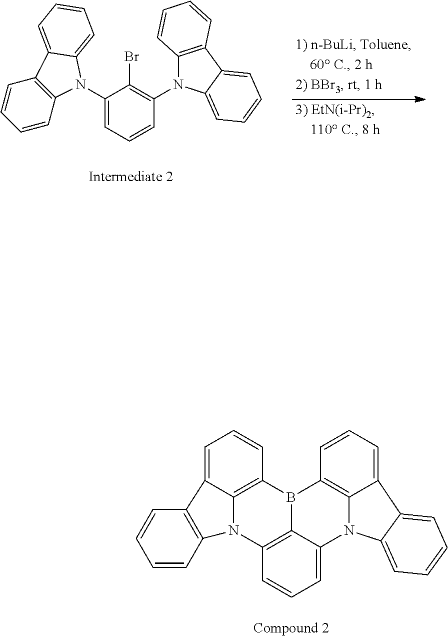 [SMILES: Brc1c(-n2c3ccccc3c3ccccc32)cccc1-n1c2ccccc2c2ccccc21 ; c1cc2c3c(c1)-n1c4ccccc4c4cccc(c41)B3c1cccc3c4ccccc4n-2c13]

In a nitrogen atmosphere at −30° C., n-butyllithium (3.07 mL, 4.9 mmol, 1.6 M hexane solution) was gradually added to a dewatered toluene solution (50 mL) in which Intermediate 2 (2.00 g, 4.1 mmol) had been dissolved, then heated up to room temperature, and stirred at 60° C. for 2 hours. Further, boron tribromide (0.47 mL, 4.9 mmol) was added at −15° C., and stirred at room temperature for 1 hour. N,N-diisopropylethylamine (1.43 mL, 8.2 mmol) was added to the mixture at 0° C., heated up to room temperature, and stirred at 110° C. for 8 hours. The reaction mixture was cooled down to room temperature, then an aqueous solution of sodium acetate and ethyl acetate was added, and the precipitated solid was separated by filtration. The resultant crude product was dissolved in warmed toluene, and recrystallized, and then further sublimed to give the intended product, Compound 2 at a yield of 0.49 g, 29%.

¹H NMR (500 MHz, CDCl_{3, 298} K, relative to Me4Si): δ=9.00 (d, 2H, J=7.5 Hz), 8.52 (d, 2H, J=8.5 Hz), 8.40 (d, 4H, J=8.0 Hz), 8.26 (d, 2H, J=8.5 Hz), 8.05 (t, 1H, J=8.5 Hz), 7.71 (t, 2H, J=7.5 Hz), 7.64 (t, 2H, J=8.5 Hz), 7.47 (t, 2H, J=7.5 Hz).

¹³C NMR (125 MHz, CDCl₃): δ=144.26, 142.73, 139.91, 133.41, 133.30, 127.05, 126.96, 123.62, 123.60, 122.46, 122.17, 121.07, 114.58, 108.77.

MS (APCI) calcd. for C₃₀H₁₇BN₂: m/z=416.15; found: 416.33 [M]⁺.

Elemental analysis calcd. (%) for C₃₀H₁₇BN₂: C 86.56, H 4.12, N 6.73; found: C 86.58, H 4.08, N 6.73.

### <Evaluation of Physical Properties>

Here, Compound 1 and Compound 2 were evaluated for the following items.

### Evaluation of Thermal Stability

Compound 1 and Compound 2 were subjected to thermogravimetric differential thermal analysis, and were found to have a decomposition temperature of 502° C. and 447° C., respectively. That is, Compound 1 was confirmed to have especially high thermal stability.

### Evaluation of Optical Properties

Each toluene solution of Compound 1 and Compound 2, each single film thereof, and each mixed film using mCBP as a host material (mixed film of each compound and mCBP) were produced.

In addition, a mixed film of the following Compound 3 and mCBP was produced.

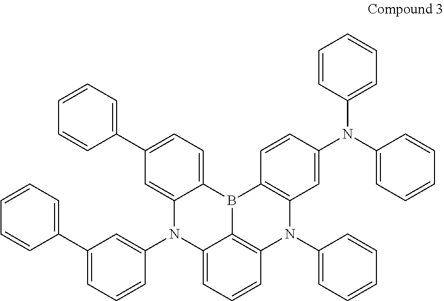 [SMILES: c1ccc(-c2cccc(N3c4cc(-c5ccccc5)ccc4B4c5ccc(N(c6ccccc6)c6ccccc6)cc5N(c5ccccc5)c5cccc3c54)c2)cc1]

Specific production methods for each sample are shown below.

First, a toluene solution of Compound 1 (concentration 10⁻⁵ mol/L) was prepared in a glove box in a nitrogen atmosphere.

Also a thin film (single film) of Compound 1 was formed at a thickness of 50 nm on a quartz substrate according to a vacuum evaporation method at a vacuum degree of 10⁻⁵ Torr or less, thereby producing an organic photoluminescent device.

Apart from this, Compound 1 and mCBP were deposited on a quartz substrate from different evaporation sources according to a vacuum evaporation method at a vacuum degree of 10^{0.5} Torr or less to form a thin film (mixed film) at a thickness of 30 nm, in which the concentration of Compound 1 was 1% by weight, thereby producing an organic photoluminescent device.

A toluene solution of Compound 2, a single film of Compound 2 and a mixed film of Compound 2 and mCBP were produced in the same manner as that for producing the devices of Compound 1 except that Compound 2 was used in place of Compound 1.

Also, a mixed film of Compound 3 and mCBP was produced in the same manner as that for producing the mixed film of Compound 1 and mCBP except that Compound 3 was used in place of Compound 1.

Optical properties of each toluene solution of Compound 1 and Compound 2 and each mixed film thereof, as well as HOMO-LUMO energy gap E_{g} read in the photoabsorption spectrum of each single film, HOMO energy E_{HOMO} and LUMO energy E_{LUMO} measured in cyclic voltammetry are shown in Table 3. In addition, emission lifetime τₚ and τ_{d} and PL quantum yield Φₚ and Φ_{d} in instantaneous fluorescence and delayed fluorescence measured with each mixed film of Compound 1, Compound 2 and Comparative Compound A, as well as energy transition rate constant are shown in Table 4. In Table 4, “kᵣ” represents rate constant in radiative deactivation, “kₙᵣ” represents rate constant in nonradiative deactivation, “k_{RISC}” represents rate constant in intersystem crossing from excited singlet state to excited triplet state, and “k_{RISC}” represents rate constant in reverse intersystem crossing from excited triplet state to excited singlet state. For measurement of the emission characteristics, 340-nm excitation light was used.

TABLE 3

| | Optical Properties of Toluene Solution | | | | | Optical Properties of Mixed Film | | | | | |
|---|---|---|---|---|---|---|---|---|---|---|---|
| | Absorption | Emission | Full Width at | PL | | Emission | Full Width at | PL | | | |
| Com- | Maximum | Maximum | Half-Maximum | Quantum | | Maximum | Half-Maximum | Quantum | | | |
| pound | Wavelength λ_{abs} | Wavelength λₑₘ | FWHM | Yield | ΔE_{ST} | Wavelength | FWHM | Yield | E_{g} | E_{HOMO} | E_{LUMO} |
| No | [nm] | [nm] | [nm] | [%] | [eV] | [nm] | [nm] | [%] | [eV] | [eV] | [eV] |
| Com- | 450 | 465 | 22 | 92 | 0.18 | 471 | 26 | 95 | 2.71 | −5.71 | −2.78 |
| pound 1 | | | | | | | | | | | |
| Com- | 457 | 473 | 25 | 91 | 0.15 | 483 | 32 | 99 | 2.67 | −5.56 | −2.75 |
| pound 2 | | | | | | | | | | | |
| Com- | 446 | 463 | 23 | 81 | 0.15 | 469 | 28 | 87 | 2.71 | −5.38 | −2.75 |
| pound 3 | | | | | | | | | | | |

TABLE 4

| | Optical Properties of Mixed Film | | | | | | | |
|---|---|---|---|---|---|---|---|---|
| | Emission Lifetime | | PL Quantum Yield | | | | | |
| | Instantaneous | Delayed | Instantaneous | Delayed | | | | |
| | Fluorescence | Fluorescence | Fluorescence | Fluorescence | Rate Constant of Mixed Film | | | |
| Compound | τₚ | τ_{d} | φₚ | φ_{d} | kᵣ | kₙᵣ | k_{ISC} | k_{RISC} |
| No | [ns] | [us] | [%] | [%] | [10⁸ s⁻¹] | [10⁶ s⁻¹] | [10⁸ s⁻¹] | [10⁵ s⁻¹] |
| Compound 1 | 6.8 | 92 | 48 | 47 | 0.71 | 4.55 | 0.76 | 0.20 |
| Compound 2 | 6.0 | 75 | 24 | 75 | 0.40 | 0.39 | 1.27 | 0.56 |
| Compound 3 | 6.0 | 65 | 84 | 6 | 1.41 | 19.4 | 0.10 | 0.15 |

As shown in Table 4, kᵣ of Compound 1 and Compound 2 is a value close to that of Compound 3 known to have an extremely high kr. In addition, Compound 1 and Compound 2 exhibited a steep emission peak having a narrow full width at half-maximum. From these, it is known that Compound 1 and Compound 2 efficiently undergo radiative deactivation from the excited singlet state, and are favorable as a light emitting material (that is, the third organic compound) for use in a TAF (TADF-assisted fluorescent) mechanism.

### <Evaluation of EL Device>

In the following, results of evaluation of EL devices are shown. For photoabsorption spectrometry, used was a spectrophotometer (LAMBDA950-PKA, by Perkin Elmer Corporation). Emission characteristics were evaluated using a fluorescent spectrophotometer (FP-6500, by JASCO Corporation), an absolute PL quantum yield measuring system (C 11347 01 Quantaurus-QY, by Hamamatsu Photonics K.K.), a fluorescent lifetime measuring apparatus (C11367-03, by Hamamatsu Photonics K.K.), and a streak camera (C4334, by Hamamatsu Photonics K.K.). EL device characteristics were evaluated using a source meter (2400 Series, by Keithley Corporation), an absolute EQE measuring system (C9920-12, by Hamamatsu Photonics K.K.), and a luminance meter (SR-3AR, by Topcon Corporation). HOMO and LUMO energy was measured with a voltammetry analyzer (ALS608D, by B.A.S. Co., Ltd.) using ferrocene as a standard substance and using an N,N-dimethylformamide solution of TBAPF₆ as an electrolytic solution.

The lowest excited singlet energy E_{S1}, the HOMO energy E_{HOMO} and LUMO energy E_{LUMO} of the materials used in the light emitting layer of the EL device are shown collectively in Table 5.

TABLE 5

| | E_{S1} | E_{HOMO} | E_{LUMO} |
|---|---|---|---|
| Material | (eV) | (eV) | (eV) |
| mCBP | 3.54 | −6.0 | −2.40 |
| HDT-1 | 2.91 | −5.73 | −2.85 |
| Compound 1 | 2.80 | −5.71 | −2.78 |
| Compound 2 | 2.67 | −5.56 | −2.75 |
| Compound 3 | 2.77 | −5.38 | −2.75 |

### Example 5

In this Example, an organic electroluminescent device was produced using mCBP as the first organic compound, HDT-1 as the second organic compound and Compound 1 as the third organic compound.

Specifically, on a glass substrate having, as formed thereon, an anode of indium tin oxide (ITO) having a film thickness of 100 nm, the following thin films were laminated according to a vacuum evaporation method at a vacuum degree of 10⁻⁵ Torr or less. First, on the ITO, HAT-CN was formed at a thickness of 10 nm, and Tris-PCz was formed thereon at a thickness of 30 nm. Subsequently, mCBP was formed at a thickness of 5 nm. Next, mCBP, HDT-1 and Compound 1 were co-deposited from different evaporation sources to form a layer having a thickness of 30 nm to be a light emitting layer. At that time, the concentration of HDT-1 was 20% by weight, and the concentration of Compound 1 was 1% by weight. Next, SF3-TRZ was formed at a thickness of 10 nm, and further thereon, F3-TRZ and Liq were co-deposited from different evaporation sources to form a layer having a thickness of 20 nm. At that time, the concentration of Liq was 30% by weight. Further, Liq was formed at a thickness of 2 nm, and next, aluminum (Al) was deposited at a thickness of 100 nm to form a cathode, thereby producing an organic electroluminescent device (EL device 1).

Apart from this, an organic electroluminescent device (EL device 2) was produced according to the same method for EL device 1, except that the concentration of Compound 1 in the light emitting layer was changed to 0.5% by weight.

### Example 6

In the same manner as in Example 5 except that Compound 2 was used as the third organic compound in place of Compound 1, an organic electroluminescent device (EL device 3) having a concentration of Compound 2 in the light emitting layer of 1% by weight and an organic electroluminescent device (EL device 4) having a concentration of Compound 2 in the light emitting layer of 0.5% by weight were produced.

### Example 7

In the same manner as in Example 5 except that Compound 3 was used as the third organic compound in place of Compound 1, an organic electroluminescent device (EL device 5) having a concentration of Compound 3 in the light emitting layer of 1% by weight and an organic electroluminescent device (EL device 6) having a concentration of Compound 3 in the light emitting layer of 0.5% by weight were produced.

Device characteristics of the EL devices produced in Examples 5 to 7 are shown in Table 6. In Table 6, turn-on voltage Von indicates the voltage at 10 cd/m² and driving voltage V_{driving} indicates the voltage at 5 mA/cm². Maximum luminance Lₘₐₓ, external quantum efficiency EQE, emission maximum wavelength λ_{EL} were measured at 1000 cd/m². EQE/EQEₘₐₓ is a ratio of the external quantum efficiency measured at 1000 cd/m² to the maximum external quantum efficiency, and LT90 indicates the time taken until the luminance has reached 90% of the initial luminance (1000 cd/m²). Here, a larger value of EQE/EQEₘₐₓ means more reduced roll-off.

TABLE 6

| | | Concentration | | | Maximum | External |
|---|---|---|---|---|---|---|
| | | of Third | Turn-on | Maximum | Power | Quantum |
| | Third | Organic | Voltage | Luminance | Efficiency | Efficiency EQE |
| | Organic | Compound | Vₒₙ | Lₘₐₓ | PEₘₐₓ | (at 1000 cd m⁻²) |
| Device No | Compound | (wt %) | (V) | (cd m⁻²) | (lm W⁻¹) | (%) |
| EL Device 1 | Compound 1 | 1 | 3.2 | 52803 | 37.6 | 17.9 |
| EL Device 2 | Compound 1 | 0.5 | 3.2 | 63777 | 47.8 | 19.8 |
| EL Device 3 | Compound 2 | 1 | 3.4 | 45403 | 32.4 | 13.8 |
| EL Device 4 | Compound 2 | 0.5 | 3.4 | 49933 | 40.1 | 17 |
| EL Device 5 | Compound 3 | 1 | 3.6 | 42046 | 39.8 | 17 |
| EL Device 6 | Compound 3 | 0.5 | 3.6 | 43513 | 45.4 | 18.4 |

| | | Emission | | | | Driving |
|---|---|---|---|---|---|---|
| | | Maximum | | | | Voltage |
| | EQE/EQEₘₐₓ | Wavelength | FWHM | CIE | LT90 | V_{driving} |
| Device No | (%) | λₑₘ (nm) | (nm) | (x, y) | (hour) | (V) |
| EL Device 1 | 86 | 471 | 36 | (0.149, 0.264) | 16.6 | 5.9 |
| EL Device 2 | 90 | 471 | 50 | (0.160, 0.305) | 39.3 | 5.9 |
| EL Device 3 | 80 | 481 | 34 | (0.129, 0.315) | 14.3 | 6.4 |
| EL Device 4 | 83 | 480 | 34 | (0.135, 0.312) | 28.6 | 6.3 |
| EL Device 5 | 72 | 469 | 48 | (0.151, 0.259) | 12 | 6.7 |
| EL Device 6 | 76 | 471 | 61 | (0.158, 0.298) | 16.4 | 6.5 |

As shown in Table 6, the emission maximum wavelength λ_{EL} of each EL device was nearly the same as the emission maximum wavelength λₑₘ observed with the mixed film of the light emitting material (Compound 1 to 3 of the third organic compound) and mCBP. From this, it is confirmed that the emission observed with the EL devices was derived from the light emitting material and energy transfer from HDT-1 to each light emitting material was surely attained.

The devices having the same concentration of the light emitting material therein were compared in device characteristics. As compared with that of EL device 5, LT90 of EL devices 1 and 3 was larger, and as compared with that of EL device 6, LT90 of EL devices 2 and 4 was larger. In particular, LT 90 of EL device 2 was not less than 2 times that of EL device 6 using Compound 3 known as an excellent light emitting material. In addition, EL devices 1 to 4 all had a lower value of roll-off (a larger value of EQE/EQEₘₐₓ) as compared with that of EL devices 5 and 6 where the concentration of the light emitting material was the same, had a higher value of maximum luminance Lₘₐₓ, and lower values of turn-on voltage Von and driving voltage V_{driving}. With those data, EL devices 1 to 4 exhibited more excellent performance than EL devices 5 and 6, and this is because, in EL devices 1 to 4, the HOMO level of Compounds 1 and 2 is near to the HOMO level of HDT-1, and therefore the holes taken in HOMO of Compounds 1 and 2 readily transferred to HOMO of HDT-1 to reduce hole trapping. In particular, with Compound 1, hole trapping reduction is significant.

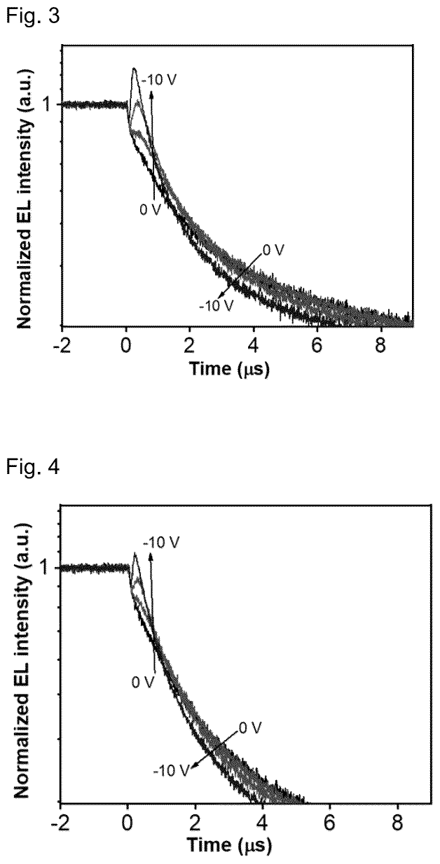

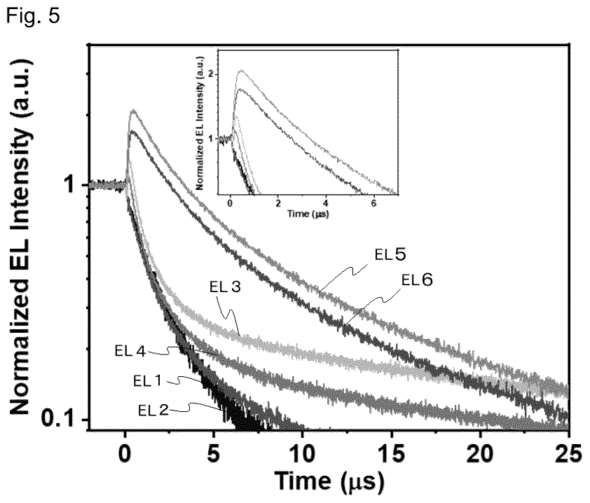

In order to verify the fact, EL devices 3 and 4 were driven at 6 V, then current was applied thereto under a reverse vias voltage of 0 to −10 V, and immediately after the current was cut off, the transient decay curve of emission intensity was measured. The results are shown in FIGS. 3 and 4. Here, the reverse vias voltage was set at 0 V, −2 V, −5 V or −10 V. In addition, after EL devices 1 to 4 were driven at 6 V, current was applied thereto under a reverse vias voltage of −10 V, and immediately after the current was cut off, the transient decay curve of emission intensity was measured. The results are shown in FIG. 5. On the horizontal axis in FIGS. 3 to 5, “0” corresponds to the time at which the reverse vias current cut off. In FIG. 5, EL devices 1 to 6 are expressed as “EL1” to “EL6”, respectively.

FIGS. 3 and 4 are referred to. On the transient decay curve of each EL device, a spike-like emission peak (spike signal) is recognized immediately after current cut-off. The spike signal corresponds to light emission formed by recombination of the carriers that had been trapped in the light emitting layer and then de-trapped immediately after current cut-off. With that, the spike signal of EL device 3 was larger than the spike signal of EL device 4 where the concentration of the light emitting material was halved, and consequently, it is recognized that the spike signal was mainly derived from the carriers trapped in the light emitting material, and the light emission intensity of the spike signal reflects the number of carrier traps in the light emitting material. In addition, as shown in Table 6, EL device 4 had a lower roll-off value, a higher maximum luminance value Lₘₐₓ, and a larger value LT90 than EL device 3, and consequently, it is confirmed that a smaller number of carrier traps in a light emitting material realizes more excellent device performance.

On the other hand, FIG. 5 is referred to. From EL devices 1 and 2 in which the HOMO level of the delayed fluorescent material (second organic compound) is nearly the same as that of the light emitting material (third organic compound), spike signal was not almost recognized. In addition, the intensity of the spike signal from EL devices 3 and 4 in which the HOMO level of the light emitting material was shallower only by 0.17 eV than the HOMO level of the delayed fluorescent material was obviously smaller than the intensity of the spike signal from EL devices 5 and 6 in which the HOMO level of the light emitting material was greatly shallower by 0.35 eV. Namely, the intensity of the spike signal varied depending on the positional relationship of the HOMO level between the delayed fluorescent material and the light emitting material. From this, it is presumed that the spike signal is derived from the holes trapped in HOMO of the light emitting material. In addition, like the relationship between HDT-1 and Compound 1, it is confirmed that, by employing a preferred embodiment in which the delayed fluorescent material and the light emitting material are so combined that, based on the level shallower by 0.2 eV than the HOMO level of the delayed fluorescent material, the HOMO level of the light emitting material can be deeper than that HOMO level, the hole traps in the light emitting material can be reduced and, as a result, a light emitting device having a markedly lower roll-off and a higher luminance and a longer driving lifetime can be realized.

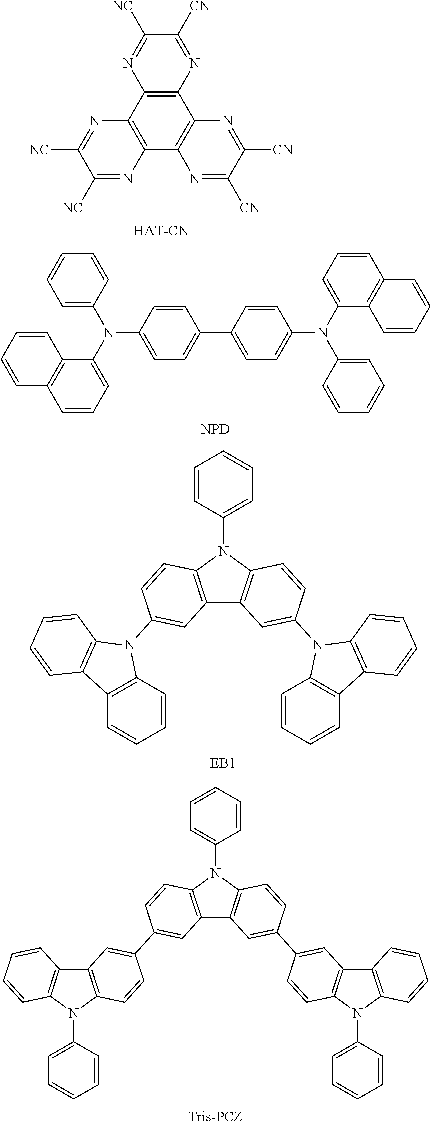 [SMILES: N#Cc1nc2c3nc(C#N)c(C#N)nc3c3nc(C#N)c(C#N)nc3c2nc1C#N ; c1ccc(N(c2ccc(-c3ccc(N(c4ccccc4)c4cccc5ccccc45)cc3)cc2)c2cccc3ccccc23)cc1 ; "NPD" ; c1ccc(-n2c3ccc(-n4c5ccccc5c5ccccc54)cc3c3cc(-n4c5ccccc5c5ccccc54)ccc32)cc1 ; c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1]

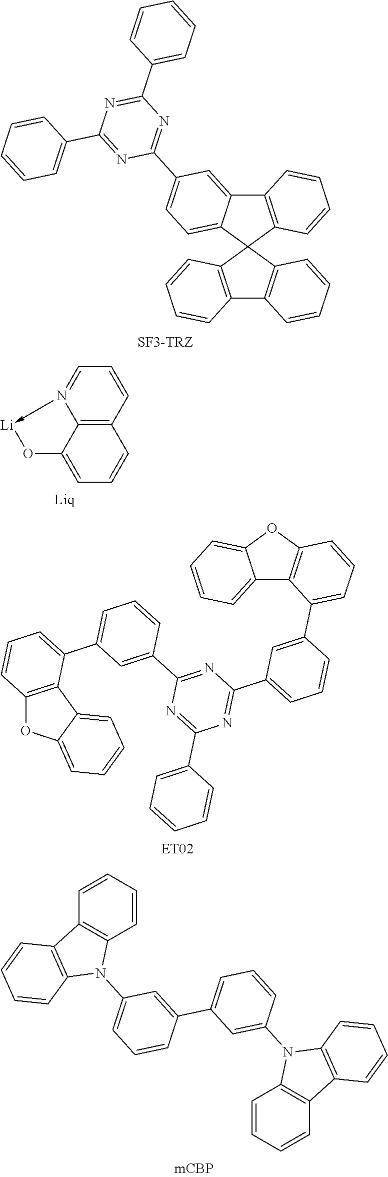

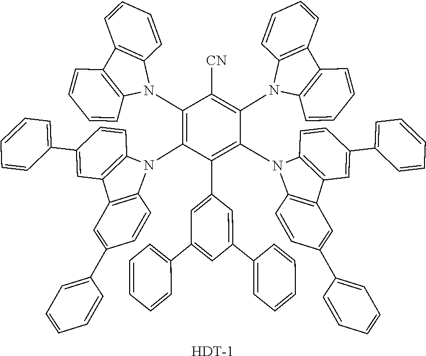 [SMILES: N#Cc1c(-n2c3ccccc3c3ccccc32)c(-n2c3ccc(-c4ccccc4)cc3c3cc(-c4ccccc4)ccc32)c(-c2cc(-c3ccccc3)cc(-c3ccccc3)c2)c(-n2c3ccc(-c4ccccc4)cc3c3cc(-c4ccccc4)ccc32)c1-n1c2ccccc2c2ccccc21 ; "HDT-1"]

### REFERENCE SIGNS LIST

1 Substrate
2 Anode
3 Hole Injection Layer
4 Hole Transporting Layer
5 Light Emitting Layer
6 Electron Transporting Layer
7 Cathode

1. An organic electroluminescent device having an anode, a cathode, and at least one organic layer containing a light emitting layer between the anode and the cathode, wherein:
the light emitting layer contains a first organic compound, a second organic compound and a third organic compound,
the second organic compound is a delayed fluorescent material,
the maximum component of light emission from the device is light emission from the third organic compound, and
the first organic compound, the second organic compound and the third organic compound satisfy the following formula (a) and the following formula (b):
E_{S1}(1)>E_{S1}(2)>E_{S1}(3) Formula (a)
0 eV<E_{HOMO}(3)-E_{HOMO}(2)<0.65 eV Formula(b)
wherein:
E_{S1}(1) represents the lowest excited singlet energy of the first organic compound,
E_{S1}(2) represents the lowest excited singlet energy of the second organic compound,
E_{S1}(3) represents the lowest excited singlet energy of the third organic compound,
E_{HOMO}(2) represents the HOMO energy of the second organic compound, and
E_{HOMO}(3) represents the HOMO energy of the third organic compound.

2. The organic electroluminescent device according to claim 1, wherein the lowest excited triplet energy of the third organic compound is larger than 1.90 eV.

3. The organic electroluminescent device according to claim 1, wherein the maximum emission wavelength of the device falls within a range of 380 to 780 nm.

4. The organic electroluminescent device according to claim 1, wherein the maximum emission wavelength of the third organic compound is shorter than the maximum emission wavelength of the second organic compound.

5. The organic electroluminescent device according to claim 1, wherein the concentration of the third organic compound in the light emitting layer falls within a range of 0.01 to 5% by weight.

6. The organic electroluminescent device according to claim 1, wherein the difference between the excited singlet energy and the excited triplet energy (ΔE_{ST}) of the second organic compound is less than 0.3 eV.

7. The organic electroluminescent device according to claim 1, wherein the ionization energy of the third organic compound is larger than the ionization energy of the second organic compound.

8. The organic electroluminescent device according to claim 1, wherein the third organic compound is a compound represented by the following general formula (15): 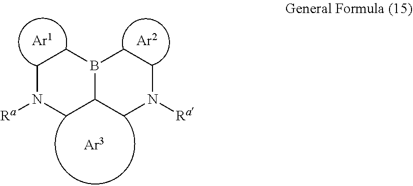
wherein Ar¹ to Ar^{a} each independently represent an aryl ring or a heteroaryl ring, at least one hydrogen atom in these rings can be substituted, or the ring can be condensed; R^{a} and R^{a}′ each independently represent a substituent; R^{a} and Ar¹ Ar¹ and Ar², Ar² and R^{a}′, R^{a}′ and Ar^{a}, and Ar^{a} and R^{a} each can bond to each other to form a cyclic structure.

9. The organic electroluminescent device according to claim 1, wherein the second organic compound has a structure such that one or two cyano groups and at least one donor group bond to the benzene ring.

10. The organic electroluminescent device according to claim 9, wherein the donor group is a substituted or unsubstituted carbazol-9-yl group.

11. The organic electroluminescent device according to claim 10, wherein three or more substituted or unsubstituted carbazol-9-yl groups bond to the benzene ring.

12. The organic electroluminescent device according to claim 10, wherein at least one of the two benzene rings constituting at least one carbazol-9-yl group existing in the second organic compound is condensed with the 5-membered ring that constitutes a substituted or unsubstituted benzofuran ring, a substituted or unsubstituted benzothiophene ring, a substituted or unsubstituted indole ring, a substituted or unsubstituted indene ring, or a substituted or unsubstituted silaindene ring.

13. The organic electroluminescent device according to claim 1, wherein the light emitting layer contains a carbon atom, a hydrogen atom, a nitrogen atom, a boron atom and an oxygen atom, and does not contain any other element.

14. A method for designing a light emitting composition, comprising:
<1> evaluating the emission lifetime of a composition containing a first organic compound, a second organic compound of a delayed fluorescent material and a third organic compound, and satisfying the following formula (a) and formula (b),
<2> carrying out at least once evaluating the emission lifetime of a composition prepared by changing at least one of the first organic compound, the second organic compound of a delayed fluorescent material and the third organic compound within the range satisfying the following formula (a) and formula (b), and
<3> selecting a combination of compounds providing the best emission lifetime evaluated,
E_{S1}(1)>E_{S1}(2)>E_{S1}(3) Formula (a)
0 eV<E_{HOMO}(3)-E_{HOMO}(2)<0.65 eV Formula (b)
wherein:
E_{S1}(1) represents the lowest excited singlet energy of the first organic compound,
E_{S1}(2) represents the lowest excited singlet energy of the second organic compound,
E_{S1}(3) represents the lowest excited singlet energy of the third organic compound,
E_{HOMO}(2) represents the HOMO energy of the second organic compound, and
E_{HOMO}(3) represents the HOMO energy of the third organic compound.

15. A non-transitory computer-readable recording medium which records a program for making a computer perform the method of claim 14.
